(19) United States
(12) Patent Application Publication
(10) Pub. No.: US 2009/0025966 A1
(43) Pub. Date: Jan. 29, 2009

(54) Fiber-resin composite, laminate, printed wiring board, and method for manufacturing printed wiring board

(76) Inventors: Kanji Shimoosako, Kyoto (JP); Takashi Ito, Shiga (JP); Shigeru Tanaka, Osaka (JP); Masaru Nishinaka, Shiga (JP); Mutsuaki Murakami, Osaka (JP)

Correspondence Address: BIRCH STEWART KOLASCH & BIRCH, PO BOX 747, FALLS CHURCH, VA, 22040-0747, US

(21) Appl. No.: 11/918,722

(22) PCT Filed: Apr. 19, 2006
(86) PCT No.: PCT/JP2006/308210

§ 371 Date: Oct. 18, 2007

(30) Foreign Application Priority Data
Apr. 19, 2005 (JP) 2005-121610
May 16, 2005 (JP) 2005-142422
Jul. 15, 2005 (JP) 2005-206949
Jul. 15, 2005 (JP) 2005-207762
Dec. 2, 2005 (JP) 2005-350031

(51) Int. Cl. B32B 27/04; B32B 27/00; B05D 1/18; H05K 1/09

(52) U.S. Cl. 174/256; 428/411.1; 428/473.5; 428/447; 428/457; 428/412; 428/480; 427/443.1

(57) ABSTRACT

The present invention provides: a copper-clad laminate, facilitating the formation of highly reliable fine wires, in which copper foil has been formed firmly on a flat and smooth surface; a laminate; an electroless plating material; a fiber-resin composite; and a printed wiring board obtained with use of them. Further, the present invention provides a method for manufacturing a multilayer printed wiring board on which fine wires can be formed with high accuracy and a multilayer printed wiring board that is obtained by the method. A copper-clad laminate of the present invention includes a plated copper layer (1), a resin layer (2), and a fiber-resin composite layer (3), and is arranged at least such that the plated copper layer (1) and the resin layer (2) are laminated so as to make contact with each other. The copper-clad laminate (10) is arranged such that a plated copper layer is formed on a resin layer having good adhesive properties with respect to copper foil. This makes it possible to cause copper foil adhere firmly to a resin layer even when the resin layer has a flat and smooth surface. Therefore, as compared with a conventional laminate, highly reliable fine wires can be formed.

### TECHNICAL FIELD

The present invention relates to copper-clad laminates and printed wiring boards obtained with use of the copper-clad laminates. Particularly, the present invention relates to a copper-clad laminate obtained with use of a technique for forming plated copper firmly on a flat and smooth surface, and to a printed wiring board obtained with use of the copper-clad laminate.

The present invention also relates to a laminate and a printed wiring board that exhibit excellent fine wiring formability.

The present invention also relates to electroless plating materials that can be suitably used in performing electroless plating. Particularly, the present invention relates to an electroless plating material that can be suitably used, for example, for manufacturing a printed wiring board, and to a printed wiring board obtained with use of the electroless plating material.

The present invention also relates to fiber-resin composites that can be suitably used in performing electroless plating. Particularly, the present invention relates to a fiber-resin composite that can be suitably used, for example, for manufacturing a printed wiring board, to a method for manufacturing the fiber-resin composite, and to a printed wiring board obtained with use of the fiber-resin composite.

The present invention also relates to a method for manufacturing a multilayer printed wiring board that exhibits excellent fine wiring formability, and to a multilayer printed wiring board obtained with use of the manufacturing method.

### BACKGROUND ART

Conventionally, copper-clad laminates have been used as materials for printed wiring boards. A known example of such a copper-clad laminate is obtained by bonding a fiber-resin composite layer and copper foil to each other by thermocompression. Examples of the fiber-resin composite layer include (i) a glass epoxy substrate obtained by impregnating glass cloth with an epoxy resin and (ii) a BT substrate obtained by impregnating glass cloth with a bismaleimide/triazine resin.

This type of copper-clad laminate has a copper covering layer, formed on a surface of an insulator, which is formed from electrolytic copper foil, and most of such copper covering layers generally have a thickness of 35 μm or 18 μm. However, in recent years, the development of electronic apparatuses has caused printed wiring boards to have finer wires. This has given rise to the availability of copper-clad laminates obtained with use of extremely thin electrolytic copper foil such as electrolytic copper foil having a thickness of 9 μm.

In cases where wires are formed with use of such a copper-clad laminate, it is usual to form the wires by dissolving and removing, by etching, that portion of the copper foil which does not correspond to the wires, i.e., to use a subtractive method. However, according to a typical copper-clad laminate, the surface roughness of a substrate on which electrolytic copper foil is to be formed is increased so that the adhesiveness between the copper foil and the substrate is increased. This causes the copper to penetrate into irregularities of the substrate. Therefore, in cases where the subtractive method is used, copper remaining in concave portions of the substrate cannot be completely removed unless sufficient etching is performed. This causes a problem. On the other hand, when excessive etching is performed, the wires are formed to be thinner than designed. This causes wiring defects. As described above, according to a conventional copper-clad laminate, the surface roughness of a substrate on which electrolytic copper foil is to be formed is great. Therefore, in cases where wires are formed with use of such a copper-clad laminate, it has been difficult to satisfactorily achieve the shape, width, and thickness of a circuit as designed.

In order to solve the foregoing problems, it is important for a copper-clad laminate to have a minimally irregular surface on which copper foil is to be formed. Examples of such a method for forming a copper layer on a flat and smooth surface include a method for forming plated copper by sputtering or electroless plating instead of thermocompression bonding performed with use of copper foil.

A known example of the technique for forming thin plated copper on a copper-clad laminate by the aforementioned electroless copper plating is disclosed in Patent Document 1. According to this technique, a copper-coated glass epoxy substrate necessary for forming a fine circuit with high accuracy is manufactured by forming an extremely thin copper coating layer on a surface of a composite of a glass epoxy resin fiber and a resin (on a surface of a base prepreg) by electroless copper plating. Specifically, according to this technique, a copper-clad laminate having an extremely thin copper film is manufactured by (i) subjecting a surface of a composite layer of a base fiber and a resin (a surface of a base prepreg) to etching with an organic solvent, (ii) forming a copper film layer by electroless plating, (iii) subjecting the resulting product to electrolytic plating as needed, and (iv) then curing the insulator by subjecting the substrate to heat and pressure treatment.

Further, according to another typical technique concerning a copper-clad laminate, for example, an addition cure polyimide resin comes to be used as a laminated material for a copper-clad laminate for the purpose of providing a copper-clad laminate, serving as a substrate, which has higher heat resistance and moisture resistance than ever (e.g., see Patent Document 2).

In recent years, as the size and weight of electronic apparatuses become smaller and lighter, there has been a demand for thinner multilayer printed wiring boards. Built-up type multilayer printed wiring boards have drawn attention as printed wiring boards that satisfy the demand. A known example of a method for manufacturing such a built-up type printed wiring board is a method by which the following steps are sequentially carried out.

(1) Form a first insulating resin layer on a surface of a core wiring substrate (including a multilayered substrate) on which surface wires have already been formed.

(2) Form a via hole in the first insulating resin layer.

(3) Form a circuit pattern on the first insulating resin layer by copper plating or the like. On this occasion, a surface of the via hole is also provided with a conductor, which electrically connects the circuit of the core circuit substrate to the circuit formed on the first insulating resin layer.

(4) Form a second insulating resin layer on a surface of the substrate thus obtained.

Subsequently, steps (2) to (4) are repeated.

Thus manufactured is a built-up type multilayer printed wiring board in which circuit layers are connected to each other via a via hole.

Such a built-up type multilayer printed wiring board has no through hole that interrupts the wiring. Therefore, as compared with a conventional multilayer printed wiring board in which conductor circuits respectively formed on layers are connected to each other via a through hole, the built-up type multilayer printed wiring board has a higher density of wires with the same wiring pitch, and makes it possible to form a thinner insulating resin layer. Accordingly, the built-up type multilayer printed wiring board enables a multilayer printed wiring board to be more highly dense and thinner.

With regard to a method for manufacturing such a built-up type multilayer printed wiring board, there have been proposed (i) a method for forming an insulating resin layer with use of a photosensitive resin and forming a via hole by a photolithographic method and (ii) a method for forming an insulating resin layer with use of a thermosetting resin and forming a via hole by laser processing. However, according to these methods, an insulating resin layer is formed with use of a photosensitive resin or a thermosetting resin. This causes a problem of nonuniformity in thickness of the insulating resin layer and a problem of uncertainty in flatness of the insulating resin layer.

Disclosed in order to solve the foregoing problems is a method for manufacturing a built-up type multilayer printed wiring board by using a prepreg of a glass cloth base material as an insulating resin layer (e.g., see Patent Document 3). Generally employed is a method including (i) integrally laminating a core wiring substrate, a prepreg, and copper foil, (ii) forming a via hole by a carbon dioxide gas laser after having removed, by etching, copper foil remaining on a connection pad, and (iii) forming a conductor in the via hole.

Meanwhile, a method for manufacturing a built-up type multilayer printed wiring substrate by lamination with copper foil, e.g., a method using electrolytic copper foil having a thickness of 18 μm or 35 μm requires a step of thinning or removing the copper by etching in order to form a via hole, thereby causing an increase in manufacturing cost. Further, the adhesiveness between the prepreg and the copper is expressed due to an anchor effect attributed to irregularities of the copper. However, since the copper penetrates into the irregularities, insulation is not secured unless sufficient etching is performed. For this reason, the method has such a problem that the interval between wires and the width of wires cannot be achieved as designed.

In recent years, there has been a case where extremely thin copper foil having a thickness of a few micrometers is used so that fine wires are formed. However, not only does the extremely thin copper foil cause a problem of cost increase and a problem of irregularities of a surface of the extremely thin copper foil, but also causes a problem of deterioration in reliability due to a pin hole that exists in the extremely thin copper foil.

In consideration of these circumstances, a method for forming a conductor layer by electroless plating or the like after having formed a via hole on a flat and smooth surface of a cured prepreg and then forming wires can be said to be preferable in terms of formation of fine wires. However, even such a method has a problem of low adhesiveness between the electroless plating and the cured prepreg. Therefore, such a method cannot be used in manufacturing a built-up type multilayer printed wiring board.

Patent Document 1: Japanese Unexamined Patent Application Publication No. 177534/1994 (Tokukaihei 6-177534; published on Jun. 24, 1994)

Patent Document 2: Japanese Unexamined Patent Application Publication No. 145348/1994 (Tokukaihei 6-145348; published on May 24, 1994)

Patent Document 3: Japanese Unexamined Patent Application Publication No. 279678/1996 (Tokukaihei 8-279678; published on Oct. 22, 1996)

### DISCLOSURE OF INVENTION

However, although the aforementioned technique disclosed in Patent Document 1 enables formation of thin copper foil, the technique achieves the adhesiveness between the copper foil and the fiber-resin composite by roughening the surface of the fiber-resin composite by etching. For this reason, the surface of the fiber-resin composite has great irregularities right under the copper foil. Therefore, the technique is not sufficient to form highly reliable fine wires. Furthermore, the technique has such a problem that the glass base material is partially exposed by etching.

Further, the technique disclosed in Patent Document 2 is designed to improve the heat resistance and moisture resistance of a copper-clad laminate serving as a substrate, and is not a technique concerning a copper-clad laminate on which fine wires can be formed with high accuracy.

Furthermore, a prepreg is usually obtained by a method for drying a base material impregnated with a resin solution. However, in this case, it has been difficult to uniformly control the thickness of the prepreg. Particularly, it has been difficult to manufacture a thin prepreg with high thickness accuracy.

As described above, in order to form highly reliable wires with use of a copper-clad laminate, it is desired that copper foil be formed firmly on a flat and smooth surface. However, such a technique has not been established yet. A technique for manufacturing a thin prepreg having uniform thickness has not been established, either. That is, a material (base prepreg) on which fine wires can be formed with high accuracy, a copper-clad laminate, a multilayer printed wiring board, and a method for manufacturing them have not been developed yet.

The present invention has been made in view of the foregoing problems, and it is an object of the present invention to provide a laminate that facilitates the formation of highly reliable fine wires, a copper-clad laminate in which copper foil has been formed firmly on a flat and smooth surface, a laminate, an electroless plating material, and a printed wiring board obtained with use of them.

Further, it is another object of the present invention to provide a fiber-resin composite, having high thickness accuracy, on which fine wires can be formed with high accuracy, a laminate obtained by subjecting a surface of the fiber-resin composite to electroless plating, a method for manufacturing the fiber-resin composite, and a printed wiring board obtained with use of the fiber-resin composite.

Furthermore, it is still another object of the present invention to provide a method for manufacturing a multilayer printed wiring board on which fine wires can be formed with high accuracy and a multilayer printed wiring board obtained with use of the manufacturing method.

As a result of making a diligent study in order to solve the foregoing problems, the inventors have found that: a copper-clad laminate (laminate) obtained by forming copper foil on a flat and smooth resin layer, containing a polyimide resin and the like, which has been formed on a fiber-resin composite is such that the copper layer firmly adheres to a surface of the flat and smooth resin layer which surface has small irregularities; therefore, fine wires can be formed on the copper-clad laminate with high accuracy. Thus, the inventors have finally completed the present invention. The present invention has been completed based on these new findings, and includes the following inventions.

(1) A laminate including a resin layer (b), provided on at least one surface of a fiber-resin composite (a), on which a metal plating layer is to be formed.

(2) The laminate as set forth in (1), including a resin layer (c) provided between the fiber-resin composite (a) and the resin layer (b) on which a metal plating layer is to be formed.

(3) The laminate as set forth in (1) or (2), wherein the fiber-resin composite (a) is in a B stage.

(4) The laminate as set forth in (1) or (2), wherein the fiber-resin composite (a) is in a C stage.

(5) The laminate as set forth in any one of (1) to (4), wherein the resin layer (b) on which a metal plating layer is to be formed contains a polyimide resin having one or more structures represented by any one of general formulae (1) to (6):

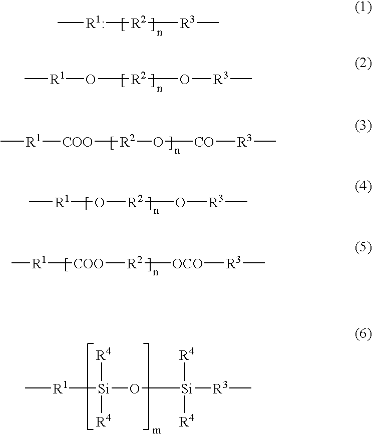

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.)

(6) The laminate as set forth in any one of (1) to (4), wherein the resin layer (b) on which a metal plating layer is to be formed contains a polyimide resin having a siloxane structure.

(7) The laminate as set forth in any one of (1) to (4), wherein the resin layer (b) on which a metal plating layer is to be formed contains a polyimide resin that is obtained by a reaction between an acid dianhydride component and a diamine component containing a diamine represented by general formula (7):

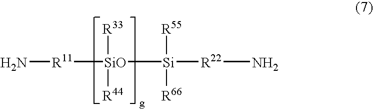

(where g is an integer of not less than 1; R¹¹ and R²² are each independently an alkylene group or a phenylene group; and R³³ to R⁶⁶ are each independently an alkyl group, a phenyl group, or a phenoxy group.)

(8) The laminate as set forth in any one of (1) to (7), wherein the resin layer (b) has a metal plating layer formed thereon.

(9) The laminate as set forth in (8), wherein the metal plating layer is a plated copper layer.

(10) The laminate as set forth in (9), wherein the plated copper layer contains an electroless plated copper layer.

(11) The laminate as set forth in any one of (1) to (10), wherein the surface roughness of the resin layer (b) on which a metal plating layer is to be formed is less than 0.5 μm in terms of arithmetic mean roughness Ra as measured at a cutoff value of 0.002 mm.

(12) The laminate as set forth in any one of (1) to (11), wherein the fiber-resin composite (a) is formed from at least one type of resin selected from the group consisting of an epoxy resin, a thermosetting polyimide resin, a cyanate ester resin, a hydrosilyl cured resin, a bismaleimide resin, a bisallylnadiimide resin, an acrylic resin, a methacrylic resin, an allyl resin, an unsaturated polyester resin, a polysulfone resin, a polyether sulfone resin, a thermoplastic polyimide resin, a polyphenylene ether resin, a polyolefin resin, a polycarbonate resin, and a polyester resin.

(13) A printed wiring board obtained with use of a laminate as set forth in any one of (1) to (12).

The laminate of the present invention makes it possible to form a copper layer firmly on a flat and smooth surface, and therefore has an advantage of excellent fine wiring formability. Therefore, the laminate of the present invention can be suitably used for manufacturing various printed wiring boards obtained with use of the laminate. Especially, the laminate of the present invention can be suitably used for a printed wiring board on which fine wires need to be formed.

Further, the present invention also encompasses the following inventions.

(14) A copper-clad laminate including a plated copper layer, a resin layer, and a fiber-resin composite, the copper-clad laminated being arranged at least such that the plated copper layer and the resin layer are laminated so as to make contact with each other.

(15) The copper-clad laminate as set forth in (14), wherein the plated copper layer contains an electroless plated copper layer.

(16) The copper-clad laminate as set forth in (14) or (15), wherein the resin layer exhibits good adhesive properties with respect to a plated copper layer.

(17) The copper-clad laminate as set forth in any one of (14) to (16), wherein the resin layer contains a polyimide resin.

(18) The copper-clad laminate as set forth in any one of (14) to (17), wherein the resin layer contains a polyimide resin having one or more structure represented by any one of general formulae (1) to (6):

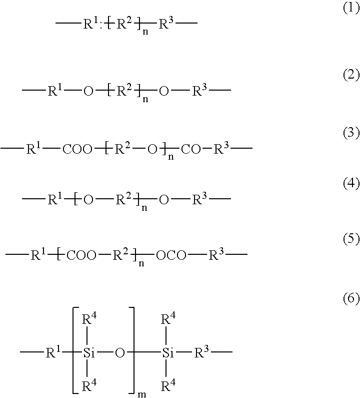

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.)

(19) The copper-clad laminate as set forth in any one of (14) to (17), wherein the resin layer contains a polyimide resin having a siloxane structure.

(20) The copper-clad laminate as set forth in any one of (14) to (19), wherein the resin layer contains a polyimide resin obtained by a reaction between an acid dianhydride component and a diamine component containing a diamine represented by general formula (7):

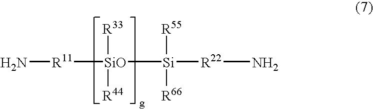

(where g is an integer of not less than 1; R¹¹ and R²² are each independently an alkylene group or a phenylene group; and R³³ to R⁶⁶ are each independently an alkyl group, a phenyl group, or a phenoxy group.)

(21) The copper-clad laminate as set forth in any one of (14) to (20), wherein the surface roughness of the resin layer is less than 0.5 μm in terms of arithmetic mean roughness Ra as measured at a cutoff value of 0.002 mm.

(22) The copper-clad laminate as set forth in any one of (14) to (21), wherein the fiber-resin composite is formed from at least one type of resin selected from the group consisting of an epoxy resin, a thermosetting polyimide resin, a cyanate ester resin, a hydrosilyl cured resin, a bismaleimide resin, a bisallylnadiimide resin, an acrylic resin, a methacrylic resin, an allyl resin, an unsaturated polyester resin, a polysulfone resin, a polyether sulfone resin, a thermoplastic polyimide resin, a polyphenylene ether resin, a polyolefin resin, a polycarbonate resin, and a polyester resin.

(23) A printed wiring board obtained with use of a copper-clad laminate as set forth in any one of (14) to (22).

The copper-clad laminate of according to the present invention is arranged such that a plated copper layer is formed on a resin layer having good adhesive properties with respect to copper foil, and therefore makes it possible to cause copper foil to adhere firmly to a resin layer even when the resin layer has a flat and smooth surface. Therefore, as compared with a conventional copper-clad laminate, the copper-clad laminate according to the present invention brings about such an effect that reliable fine wires can be formed.

Further, since the copper-clad laminate of according to the present invention brings about such a unique effect, the copper-clad laminate can be suitably used, for example, for a printed wiring board on which fine wires need to be formed.

Further, in order to solve the foregoing problems, the present invention may be arranged as follows.

(24) An electroless plating material having a surface that is subjected to electroless plating, including a resin composition that contains a composite of a fiber and a polyimide resin having one or more structures represented by any one of general formulae (1) to (6):

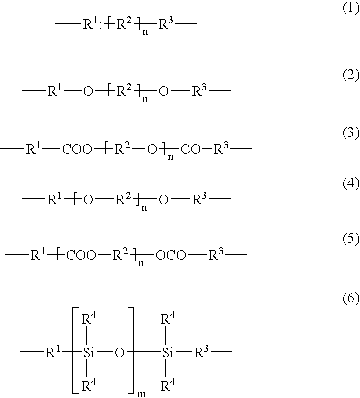

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.)

(25) An electroless plating material having a surface that is subjected to electroless plating, including a resin composition that contains a composite of a fiber and a polyimide resin having a siloxane structure.

(26) The electroless plating material as set forth in (25), wherein the polyimide resin having a siloxane structure is made from an acid dianhydride component and a diamine component containing a diamine represented by general formula (7):

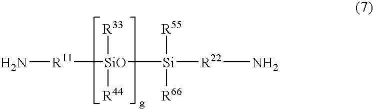

(where g is an integer of not less than 1; R¹¹ and R²² are each independently an alkylene group or a phenylene group; and R³³ are each independently an alkyl group, a phenyl group, or a phenoxy group.)

(27) The electroless plating material as set forth in any one of (24) to (26), wherein the fiber is made from at least one type selected from the group consisting of paper, glass, polyimide, aramid, polyarylate, and tetrafluoroethylene.

(28) The electroless plating material as set forth in any one of (24) to (27), wherein the electroless plating is electroless copper plating.

(29) The electroless plating material as set forth in any one of (24) to (28), wherein the composite is obtained by impregnating the fiber with a resin composition solution containing (i) the polyimide resin having a siloxane structure and (ii) a solvent.

(30) The electroless plating material as set forth in any one of (24) to (28), wherein the composite is obtained by impregnating the fiber with a resin composition solution containing (i) polyamic acid having a siloxane structure and (ii) a solvent.

(31) A laminate obtained by subjecting a surface of an electroless plating material as set forth in any one of (24) to (30) directly to electroless plating.

(32) A printed wiring board obtained with use of an electroless plating material as set forth in any one of (24) to (30).

(33) A method for manufacturing an electroless plating material, including forming, by impregnating a fiber with a resin composition solution containing (i) a polyimide resin having one or more structures represented by any one of general formulae (1) to (6) and (ii) a solvent, a layer whose surface is to be subjected to electroless plating:

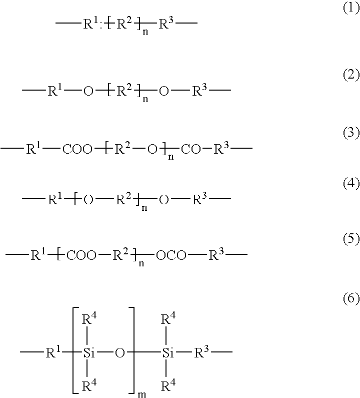

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X}; or a bivalent phenylene group is an integer of 3 to 100; and m is an integer of not less than 1.)

The electroless plating material of the present invention is obtained with use of a composite of a fiber and a specific resin, and makes it possible to form a copper layer firmly on a flat and smooth surface. Therefore, the electroless plating material of the present invention has an advantage of excellent fine wiring formability. Accordingly, the electroless plating material of the present invention can be suitably used for manufacturing various printed wiring boards obtained with use of the electroless plating material. Especially, the electroless plating material of the present invention can be suitably used for a printed wiring board on which fine wires need to be formed.

Further, in order to solve the foregoing problems, the present invention may be arranged as follows.

(34) A fiber-resin composite obtained by integrating (i) a sheet having a layer formed from a resin composition containing a thermoplastic resin with (ii) a fiber by thermocompression bonding.

(35) The fiber-resin composite as set forth in (34), wherein the sheet formed from a resin composition containing a thermoplastic resin is a single-layer sheet containing a polyimide resin having one or more structures represented by any one of general formulae (1) to (6):

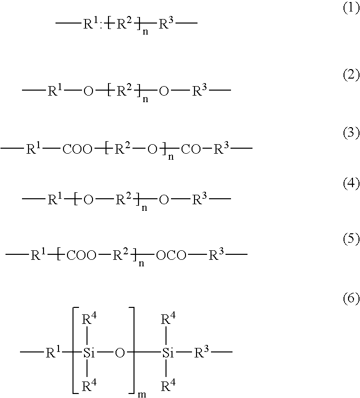

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.)

(36) The fiber-resin composite as set forth in (34), wherein the sheet formed from a resin composition containing a thermoplastic resin is a single-layer sheet containing a polyimide resin having a siloxane structure.

(37) The fiber-resin composite as set forth in (34), wherein the sheet formed from a resin composition containing a thermoplastic resin is a plural-layer sheet having two or more different resin layers and has a layer containing a polyimide resin having a siloxane structure.

(38) The fiber-resin composite as set forth in (37), wherein the sheet formed from a resin composition containing a thermoplastic resin has (i) a layer containing a polyimide resin having a siloxane structure and (ii) a resin layer containing a thermosetting component.

(39) A fiber-resin composite obtained by placing a fiber between sheets each having a layer formed from a resin composition containing a thermoplastic resin and then by integrating the sheets with the fiber by thermocompression bonding.

(40) A fiber-resin composite obtained by placing a fiber between resin sheets each having a surface on which a metal plating layer is to be formed and then by integrating the resin sheets with the fiber by thermocompression bonding.

(41) A fiber-resin composite obtained by placing a fiber between a resin sheet having a surface on which a metal plating layer is to be formed and a resin sheet in which a circuit is to be embedded and then by integrating the resin sheets with the fiber by thermocompression bonding.

(42) The fiber-resin composite as set forth in any one of (34) to (41), having an uppermost surface where there exists a polyimide resin containing a siloxane structure.

(43) The fiber-resin composite as set forth in any one of (34) to (42), wherein the thermocompression bonding is performed at a temperature of 70° C. to 300° C. under a pressure of 0.1 MPa to 10 MPa for a period of 1 second to 3 hours with at least one type of apparatus selected from the group consisting of a heat press, a vacuum press, a laminator, a vacuum laminator, a heat roller laminator, and a vacuum heat roller laminator.

(44) The fiber-resin composite as set forth in any one of (34) to (43), having an uppermost surface that is to be subjected to electroless plating.

(45) A laminate obtained by subjecting, to electroless plating, an uppermost surface of a fiber-resin composite as set forth in any one of (34) to (44).

(46) A printed wiring board obtained with use of a fiber-resin composite as set forth in any one of (34) to (44).

(47) A method for manufacturing a fiber-resin composite, including obtaining the fiber-resin composite by integrating (i) a sheet having a layer formed from a resin composition containing a thermoplastic resin with (ii) a fiber by thermocompression bonding.

The fiber-resin composite of the present invention is obtained through integration by thermocompression bonding, and therefore can be obtained with high thickness accuracy by controlling the flow properties of the resin composition. Furthermore, the fiber-resin composite of the present invention makes it possible to form a copper layer firmly on a flat and smooth surface, and therefore has an advantage of excellent fine wiring formability. Further, the fiber-resin composite of the present invention is obtained by integrating (i) a sheet having a layer made from a resin composition containing a thermoplastic resin with (ii) a fiber by thermocompression bonding. This causes the fiber and the resin composition to sufficiently adhere to each other, so that the fiber-resin composite of the present invention possesses excellent reliability. Therefore, the fiber-resin composite can be suitably used for manufacturing various printed wiring boards. The fiber-resin composite can be suitably used especially for a printed wiring board on which fine wires need to be formed.

In order to solve the foregoing problems, the present invention may be arranged as follows.

(48) A method for manufacturing a multilayer printed wiring board with use of a fiber-resin composite (a), including the steps (A) to (C) of:

(A) integrally laminating a laminate on a core wiring substrate by heat and pressure, the core wiring substrate having a surface that has a wire including a connection pad, the laminate having a resin layer (b), provided on at least one surface of a fiber-resin composite (a), on which metal plating is to be formed;

(B) exposing the connection pad by making via holes in respective parts of the fiber-resin composite (a) and the resin layer (b) on which metal plating is to be formed, the parts corresponding to the connection pad; and

(C) making an electrical connection between (i) a surface of the resin layer (b) on which metal plating is to be formed and (ii) the connection pad by forming metal plating on the surface of the resin layer (b) on which metal plating is to be formed and in the via holes.

(49) A method for manufacturing a multilayer printed wiring board with use of a fiber-resin composite (a), including the steps (A) to (C) of:

(A) integrally laminating a fiber-resin composite (a) and a resin layer (b) on which metal plating is to be formed on a core wiring substrate by heat and pressure so that the resin layer (b) serves as an outermost layer, the core wiring substrate having a surface that has a wire including a connection pad;

(B) exposing the connection pad by making via holes in respective parts of the fiber-resin composite (a) and the resin layer (b) on which metal plating is to be formed, the parts corresponding to the connection pad; and

(C) making an electrical connection between (i) a surface of the resin layer (b) on which metal plating is to be formed and (ii) the connection pad by forming metal plating on the surface of the resin layer (b) on which metal plating is to be formed and in the via holes.

(50) The method for manufacturing a multilayer printed wiring board as set forth in (48) or (49), wherein the resin layer (b) contains a polyimide resin having one or more structures represented by any one of general formulae (1) to (6):

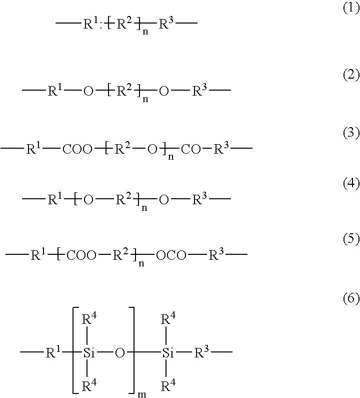

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.)

(51) The method as set forth in any one of (48) to (50), including forming a wire by a subtractive method after the steps (A) to (C).

(52) The method as set forth in any one of (48) to (50), including forming a wire by an additive method after the steps (A) to (C).

(53) A multilayer printed wiring board manufactured by a method as set forth in any one of claims (48) to (52), the surface roughness of a resin layer exposed after the wire has been formed being less than 0.5 μm in terms of arithmetic mean roughness Ra as measured at a cutoff value of 0.002 mm.

The method of the present invention for manufacturing a multilayer printed wiring board has an advantage of making it possible to obtain a multilayer printed wiring board that exhibits excellent fine wiring formability.

### BRIEF DESCRIPTION OF DRAWINGS

FIG. 1(a) is a diagram schematically showing a cross-sectional surface of an example of a copper-clad laminate according to an embodiment of the present invention.

FIG. 1(b) is a diagram schematically showing a cross-sectional surface of another example of the copper-clad laminate according to the embodiment of the present invention.

### REFERENCE NUMERALS

1 Plated copper layer
2 Resin layer
3 Fiber-resin composite layer
10 Copper-clad laminate
10′Copper-clad laminate

### BEST MODE FOR CARRYING OUT THE INVENTION

An embodiment of the present invention will be described below. Note that the present invention is not limited to the description of the embodiments below.

### Embodiment 1

<1-1. Copper-Clad Laminate>

A copper-clad laminate according to the present invention only needs to include a plated copper layer, a resin layer, and a fiber-resin composite, and to be arranged at least such that the plated copper layer and the resin layer are laminated so as to make contact with each other. The copper-clad laminate according to the present invention is not particularly limited in terms of other specific arrangements.

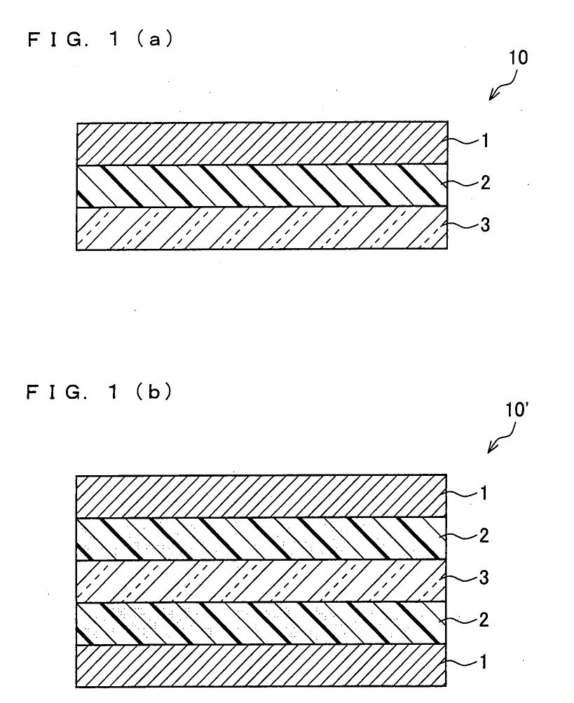

Each of FIGS. 1(a) and 1(b) is a cross-sectional view schematically showing a copper-clad laminated according to the present embodiment. As shown in FIG. 1(a), a copper-clad laminate 10 includes a plated copper layer 1, a resin layer 2, and a fiber-resin composite 3. The plated copper layer 1 is laminated on the resin layer 2 so as to make contact with the resin layer 2. The resin layer 2 is formed on the fiber-resin composite 3. The copper-clad laminate only needs to be arranged such that the plated copper layer 1 and the resin layer 2 are laminated so as to make contact with each other. For example, plated copper layers 1 and resin layers 2 may be formed on both surfaces of the fiber-resin composite 3. That is, as with a copper-clad laminate 10′ shown in FIG. 1(b), another plated copper layer 1 and another resin layer 2 may be provided in addition to the plated copper layer 1, the resin layer 2, and the fiber-resin composite 3. Also in this case, the plated copper layer 1 and the resin layer 2 are laminated so as to make contact with each other.

In other words, the copper-clad laminate only needs to include a plated copper layer 1, a resin layer 2 on which a plated copper layer is to be formed, and one or more fiber-resin composites 3, and to be arranged at least such that the plated copper layer 1, the resin layer 2, and the fiber-resin composite 3 are laminated in the order named. That is, examples of a specific structure include: (i) a structure, shown in FIG. 1(a), in which the plated copper layer 1, the resin layer 2, and the fiber-resin composite 3 are laminated in the order named; and (ii) a structure, shown in FIG. 1(b), in which the plated copper layer 1, the resin layer 2, the fiber-resin composite 3, the resin layer 2, and the plated copper layer 1 are laminated in the order named.

That is, the arrangement of the present invention is characterized in that a plated copper layer is formed on a resin layer that exhibits good adhesion properties with respect to copper foil even when having a flat and smooth surface with small irregularities. In order to cause the plated copper layer to firmly adhere, it is very preferable that the resin layer be placed right under the plated copper layer.

As described above, the copper-clad laminate according to the present invention is characterized in that a plated copper layer is formed on a flat and smooth resin layer, and that the two layers adhere firmly to each other. This is because the resin layer used for the copper-clad laminated according to the present invention has such properties as to adhere firmly to copper foil even when having a flat and smooth surface. Therefore, for example, even in cases where a subtractive method is employed, etching can be performed with high accuracy because that surface of the resin layer which is placed right under the copper foil is flat and smooth and has small irregularities. For this reason, as compared with a conventional copper-clad laminate, fine wires can be formed with high accuracy as designed.

That is, it is preferable that the resin layer have good adhesive properties with respect to the plated copper layer. The adhesiveness between the resin layer and the plated copper layer can be expressed by “adhesive strength under normal conditions” and “adhesive strength after PCT”. Specifically, it is preferable that the resin layer have an “adhesive strength under normal conditions” of not less than 5 N/cm with respect to the adhesiveness of the plated copper layer, and/or it is preferable that the resin layer have an “adhesive strength after PCT” of not less than 3 N/cm with respect to the adhesiveness of the plated copper layer. Note that the “adhesive strength under normal conditions” and the “adhesive strength after PCT” can be evaluated by a method shown in the embodiments described later.

Further, in order to attain the formation of highly fine wires, it is preferable that the surface roughness of the resin layer be less than 0.5 μm in terms of arithmetic mean roughness Ra as measured at a cutoff value of 0.002 mm. Furthermore, it is more preferable that the arithmetic mean roughness Ra be less than 0.1 μm, or even more preferably less than 0.05 μm. This is because as the surface roughness of the resin layer becomes smaller, more highly fine wires can be formed. Note that the term “arithmetic mean roughness Ra” used herein is defined in JIS B 0601 (revised on Feb. 1, 1994). Particularly, the numerical value of “arithmetic mean roughness Ra” used in this specification refers to a numerical value calculated by observing a surface with an optical interferotype surface structure analyzer. The detail of the measurement method and the like will be shown in the embodiments described later. Further, the term “cutoff value” used in the present invention is described in JIS B 0601 mentioned above, and refers to a wavelength that is to be set in obtaining a roughness curve from a profile curve (actual measurement data). That is, the “value Ra of arithmetic mean roughness as measured at a cutoff value of 0.002 mm” is an arithmetic mean roughness calculated from a roughness curve obtained by removing, from actual measurement data, irregularities having a wavelength longer than 0.002 m”. As explained with reference to FIGS. 1(a) and 1(b), that surface of the resin layer which is used for measuring the “surface roughness of the resin layer” refers to that surface of the resin layer 2 which makes contact with the plated copper layer 1.

Note that it is preferable that the resin layer of the present embodiment satisfy the “adhesiveness” and the “surface roughness” simultaneously. This is because a copper-clad laminate having a resin layer that simultaneously satisfies the two properties makes it possible to form very highly fine wires.

The copper-clad laminate according to the present invention is not particularly limited in terms of thickness. However, in consideration of its application to a high-density printed wiring board, it is preferable that the copper-clad laminate have a small thickness. Specifically, it is preferable that the copper-clad laminate have a thickness of not more than 2 mm, or more preferably not more than 1 mm. The following fully explains arrangements for use in the copper-clad laminate and a method for manufacturing the copper-clad laminate.

(1-1-1. Plated Copper Layer)

The plated copper layer of the present embodiment only needs to be a publicly-known plated copper layer that is used for a conventionally publicly-known copper-clad laminate, and is not limited in terms of its specific arrangement. For example, the plated copper layer can be formed from various types of dry plated copper such as those obtained by vapor deposition, sputtering, and CVD, or from wet plated copper such as electroless plated copper. Particularly, in consideration of adhesive properties with respect to the resin layer, manufacturing cost, and the like, it is preferable that the plated copper layer be a layer formed from electroless plated copper.

Further, the plated copper layer may be a layer formed solely from electroless plated copper, but may be a plated copper layer given a desired thickness by forming an electrolytic plated layer after having formed electroless plated copper. The plated copper layer can be formed so as to have the same thickness as in the conventionally publicly-known copper-clad laminate, and the plated copper layer is not particularly limited in terms of thickness. However, in consideration of the formation of fine wires and the like, it is preferable that the plated copper layer have a thickness of not more than 25 μm, or more preferably 20 μm.

(1-1-2. Resin Layer)

The resin layer of the present embodiment only needs to have good adhesive properties with respect to the plated copper layer. More specifically, the resin layer only needs to be made of a resin material capable of causing the plated copper layer to adhere firmly to the resin layer even when the resin layer has a flat and smooth surface with small irregularities, and is not particularly limited in terms of its specific arrangement. Specifically, in order to adhere firmly to the plated copper layer, it is preferable that the resin layer contain a polyimide resin. Particularly, it is preferable that the resin layer contain a polyimide resin having one or more structures represented by any one of general formulae (1) to (6):

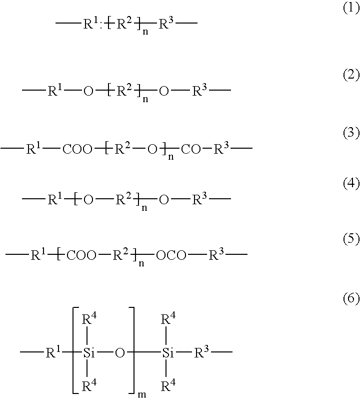

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of 1 not less than 1.)

In terms of excellence in adhesive strength under normal conditions and in adhesive strength before and after PCT treatment, it is more preferable that the resin layer contain a polyimide resin having a siloxane structure. Any polyimide resin may be used as long as it has one or more structures represented by any one of general formulae (1) to (6). For example, examples of a method for manufacturing such a polyimide resin include the following methods (1) to (3). According to method (1), polyamic acid serving as a polyimide resin precursor is manufactured with use of an acid dianhydride component having one or more structures represented by any one of general formulae (1) to (6) or a diamine component having one or more structures represented by any one of general formulae (1) to (6). Then, the polyamic acid thus manufactured is imidized, with the result that a polyimide resin is obtained. According to method (2), polyamic acid having a functional group is manufactured with use of an acid dianhydride component having a functional group or a diamine component having a functional group. Next, the polyamic acid thus manufactured is allowed to react with a compound having (i) a functional group capable of reacting with the functional group of the polyamic acid and (ii) one or more structures represented by any one of general formulae (1) to (6), with the result that polyamic acid into which a structure represented by any one of general formulae (1) to (6) has been introduced is obtained. Then, the polyamic acid thus manufactured is imidized, with the result that a polyimide resin is obtained. According to method (3), polyamic acid having a functional group is manufactured with use of an acid dianhydride component having a functional group or a diamine component having a functional group. Then, the polyamic acid thus manufactured is imidized, with the result that a polyimide having a functional group is obtained. Next, the polyimide thus obtained is allowed to react with a compound having (a) a functional group capable of reacting with the functional group of the polyimide and (b) one or more structures represented by any one of general formulae (1) to (6), with the result that a polyimide resin into which a structure represented by any one of general formulae (1) to (6) has been introduced is obtained. Note that it is relatively easy to obtain a diamine having one or more structures represented by any one of general formulae (1) to (6). Therefore, among the methods thus described, it is preferable that the target polyimide resin be manufactured by a reaction between an acid dianhydride component and a diamine component having one or more structures represented by any one of general formulae (1) to (6). Electroless plating often exhibits poor adhesive properties with respect to surfaces of various insulating materials. Therefore, in cases where a method for forming electroless plating is employed as a method for forming a metal layer directly on an insulating material, it has been very difficult to cause electroless plating to adhere firmly to an insulating material having a flat and smooth surface with small surface roughness. This is considered to be because electroless plating is formed so as to settle via a catalyst such as palladium. However, the use of a polyimide resin having one or more structures represented by any one of general formulae (1) to (6) causes electroless plating, which has conventionally been considered to exhibit poor adhesive properties, to exhibit very good adhesive properties.

Examples of a manufacturing method for obtaining the polyimide resin having a siloxane structure include the following methods (1) and (3). According to method (1), polyamic acid serving as a polyimide resin precursor is manufactured with use of an acid dianhydride component having a siloxane structure or a diamine component having a siloxane structure. Then, the polyamic acid thus manufactured is imidized, with the result that a polyimide resin is obtained. According to method (2), polyamic acid having a functional group is manufactured with use of an acid dianhydride component having a functional group or a diamine component having a functional group. Next, the polyamic acid thus manufactured is allowed to react with a compound having (i) a functional group capable of reacting with the functional group of the polyamic acid and (ii) a siloxane structure, with the result that polyamic acid into which a siloxane structure has been introduced is obtained. Then, the polyamic acid thus obtained is imidized, with the result that a polyimide resin is obtained. According to method (3), polyamic acid having a functional group is manufactured with use of an acid dianhydride component having a functional group or a diamine component having a functional group. Then, the polyamic acid thus manufactured is imidized, with the result that a polyimide having a functional group is obtained. Next, the polyimide thus obtained is allowed to react with a compound having (a) a functional group capable of reacting with the functional group of the polyimide and (b) a siloxane structure, with the result that a polyimide resin into which a siloxane structure has been introduced is obtained. Note that it is relatively easy to obtain a diamine having a siloxane structure. Therefore, among the methods thus described, it is preferable that the target polyimide resin be obtained by a reaction between an acid dianhydride component and a diamine having a siloxane structure.

Generally, a polyimide resin is obtained by a reaction between an acid dianhydride component and a diamine component. More specifically, the polyimide resin is obtained by subjecting, to dehydration ring closure, polyamic acid serving as a precursor corresponding to the polyimide resin. The polyamic acid is obtained by a substantially equimolar reaction between an acid dianhydride component and a diamine component, and can be obtained, for example, by any one of the following methods (1) to (5).

(1) A diamine component is dissolved in an organic polar solvent, and polymerization is performed by allowing the diamine component to react with a substantially equimolar amount of acid dianhydride component.

(2) An acid dianhydride component and an excessively smaller molar quantity of diamine component are allowed to react with each other in an organic polar solvent, with the result that a prepolymer having acid anhydride groups at both terminals thereof is obtained. Then, polymerization is performed in a single-stage or multistage manner with use of a diamine component so that an acid dianhydride and a diamine component that are used in all steps are present in substantially equimolar amounts.

(3) An acid dianhydride component and an excessively smaller molar quantity of diamine component are allowed to react with each other in an organic polar solvent, with the result that a prepolymer having amino groups at both terminals thereof is obtained. Then, after the addition of a diamine component to the organic polar solvent, polymerization is performed in a single-stage or multistage manner with use of an acid dianhydride component so that an acid dianhydride and a diamine component that are used in all steps are present in substantially equimolar amounts.

(4) After an acid dianhydride component has been dissolved and/or dispersed in an organic polar solvent, polymerization is performed with use of a diamine component so that the acid dianhydride component and the diamine component are present in substantially equimolar amounts.

(5) Polymerization is performed by allowing a mixture of substantially equimolar amounts of an acid dianhydride component and a diamine component to react in an organic polar solvent.

These methods are not particularly limited in terms of reaction time and reaction temperature. The term “substantially equimolar” used above is not particularly limited, but means, for example, that the molar ratio between an acid dianhydride component and a diamine component falls within a range of 100:99 to 100:102.

Further, the term “dissolution” used in this specification includes, in addition to a case where a solvent completely dissolves a solute, a case where a solute is uniformly dispersed in a solvent or dispersed so as to be seconds away from being substantially dissolved in the solution. The reaction time and reaction temperature during which or at which the polyamic acid polymer is prepared can be set in the usual manner, and are not particularly limited.

The organic polar solvent that is used for a polymerization reaction of polyamic acid can be suitably selected, in accordance with the aforementioned diamine component and acid dianhydride component, from solvents that are used for preparing conventionally publicly-known polyamic acid, and is not particularly limited. Examples of such organic polar solvents include: sulfoxide solvents such as dimethyl sulfoxide and diethyl sulfoxide; formamide solvents such as N,N-dimethyl formamide and N,N-diethyl formamide; acetoamide solvents such as N,N-dimethyl acetoamide and N,N-diethyl acetoamide; pyrrolidone solvents such as N-methyl-2-pyrrolidone and N-vinyl-2-pyrrolidone; phenol solvents such as phenol, o-m- or p-cresol, xylenol, halogenated phenols, and catechol; hexamethyl phosphoramide; and γ-butyrolactone. Furthermore, according to need, these organic polar solvents can be used in combination with an aromatic hydrocarbon such as xylene or toluene.

The following explains an acid dianhydride component that can be used for the resin layer of the present embodiment. The acid dianhydride component can be suitably selected from various acid dianhydride components that are used for preparing a conventionally publicly-known polyimide resin, and is not particularly limited in terms of its specific arrangement. Examples of such acid dianhydride components include: aromatic tetracarboxylic acid dianhydride such as pyromellitic acid dianhydride, 3,3′,4,4′-benzophenone tetracarboxylic acid dianhydride, 3,3′,4,4′-diphenylsulfone tetracarboxylic acid dianhydride, 1,4,5,8-naphthalene tetracarboxylic acid dianhydride, 2,3,6,7-naphthalene tetracarboxylic acid dianhydride, 3,3′,4,4′-dimethyldiphenylsilane tetracarboxylic acid dianhydride, 1,2,3,4-furan tetracarboxylic acid dianhydride, 4,4′-bis-(3,4-dicarboxyphenoxy) diphenylpropanoic acid dianhydride, 3,3′,4,4′-biphenyl tetracarboxylic acid dianhydride, 2,3,3′,4′-biphenyl tetracarboxylic acid dianhydride, and p-phenylenediphthalic acid anhydride; 4,4′-hexafluoroisopropylidene diphthalic acid anhydride; 4,4′-oxydiphthalic acid anhydride, 3,4′-oxydiphthalic acid anhydride; 3,3′-oxydiphthalic acid anhydride, 4,4′-(4,4′-isopropylidenediphenoxy)bis(phthalic anhydride) (also referred to as 4,4′-(4,4′-isopropylidenediphenoxy)bisphthalic acid anhydride); 4,4′-hydroquinonebis(phthalic anhydride); 2,2-bis(4-hydroxyphenyl)propanedibenzoate-3,3′4,4′-tetracarboxylic acid dianhydride; 1,2-ethylenebis(trimellitic acid monoester anhydride); and p-phenylenebis(trimellitic acid monoester anhydride). These acid dianhydride components may be used separately. Alternatively, a combination of two or more of them can be used. In such a case, conditions such as a mixture ratio can be appropriately set by a person skilled in the art.

The following explains a diamine component by illustrating a diamine component having one or more structures represented by any one of general formulae (1) to (6). Examples of a diamine having a structure represented by general formula (1) include hexamethylene diamine and octamethylene diamine. Examples of a diamine having a structure represented by general formula (2) include 1,3-bis(4-aminophenoxy)propane, 1,4-bis(4-aminophenoxy)butane, 1,5-bis(4-aminophenoxy)pentane. Examples of a diamine having a structure represented by general formula (3) include Elasmer-1000P, Elasmer-650P, and Elasmer-250P (manufactured by Ihara Chemical Industry, Co., Ltd.). Further, examples of a diamine having a structure represented by general formula (4) include polyetherpolyamines and polyoxyalkylenepolyamines such as JEFFAMINE D-2000 and JEFFAMINE D-400 (manufactured by Huntsman Corporation). In the present invention, it is preferable that the diamine component be a diamine component having a siloxane structure. A polyimide resin, having a siloxane structure, which is obtained with use of a diamine component having a siloxane structure has such a feature as to adhere firmly to an electroless plated copper layer even when having a flat and smooth surface with small irregularities.

Particularly, it is preferable that the diamine compound having a siloxane structure contain a diamine compound represented by general formula (7):

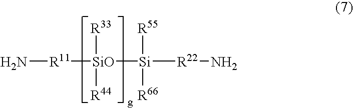

(where g is an integer of 1 or more; R¹¹ and R²² are each independently an alkylene group or a phenylene group; and R³³ to R⁶⁶ are each independently an alkyl group, a phenyl group, or a phenoxy group.)

The use of the diamine component represented by general formula (7) makes it possible to obtain a polyimide resin that can more effectively adhere firmly to an electroless plated copper layer.

Specific examples of the diamine represented by general formula (7) include 1,1,3,3-tetramethyl-1,3-bis(4-aminophenyl)disiloxane, 1,1,3,3-tetraphenoxy-1,3-bis(4-aminoethyl)disiloxane, 1,1,3,3,5,5-hexamethyl-1,5-bis(4-aminophenyl)trisiloxane, 1,1,3,3-tetraphenyl-1,3-bis(2-aminophenyl)disiloxane, 1,1,3,3-tetraphenyl-1,3-bis(3-aminopropyl)disiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(3-aminobutyl)trisiloxane, 1,1,5,5-tetraphenyl-3,3-dimethoxy-1,5-bis(3-aminopentyl)trisiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(4-aminobutyl)disiloxane, 1,3-dimethyl-1,3-dimethoxy-1,3-bis(4-aminobutyl)disiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane.

Note that examples of relatively easily-obtainable ones of the diamine components represented by general formula (7) include KF-8010, X-22-161A, X-22-161B, X-22-1660B-3, KF-8008, KF-8012, and X-22-9362 (manufactured by Shin-Etsu Chemical Co., Ltd.). These diamine components may be used separately. Alternatively, a combination of two or more of them may be used. In such a case, conditions such as a mixture ratio can be appropriately set by a person skilled in the art.

The diamines each having a structure represented by any one of general formulae (1) to (6) may be used separately. Alternatively, a combination of two or more of them may be used.

Further, for the purpose of improving heat resistance and moisture resistance, the aforementioned diamine components can be used in combination with other diamine components. As the other diamine components, all types of diamine can be used. For example, conventionally publicly-known diamines that are used for manufacturing a polyimide resin can be used. Specific examples of such diamines include m-phenylenediamine, o-phenylenediamine, p-phenylenediamine, m-aminobenzylamine, p-aminobenzylamine, bis(3-aminophenyl)sulfide, (3-aminophenyl) (4-aminophenyl) sulfide, bis(4-aminophenyl)sulfide, bis(3-aminophenyl)sulfoxide, (3-aminophenyl) (4-aminophenyl)sulfoxide, bis(3-aminophenyl)sulfone, (3-aminophenyl)(4-aminophenyl)sulfone, bis(4-aminophenyl)sulfone, 3,4′-diaminobenzophenone, 4,4′-diaminobenzophenone, 3,3′-diaminodiphenylmethane, 3,4′-diaminodiphenylmethane, 4,4′-diaminodiphenylmethane, 4,4′-diaminodiphenylether, 3,3′-diaminodiphenylether, 3,4′-diaminodiphenylether, bis[4-(3-aminophenoxy)phenyl]sulfoxide, bis[4-(aminophenoxy)phenyl]sulfoxide, 4,4′-diaminodiphenylether, 3,4′-diaminodiphenylether, 3,3′-diaminodiphenylether, 4,4′-diaminodiphenylthioether, 3,4′-diaminodiphenylthioether, 3,3′-diaminodiphenylthioether, 3,3′-diaminodiphenylmethane, 3,4′-diaminodiphenylmethane, 4,4′-diaminodiphenylmethane, 4,4′-diaminodiphenylsulfone, 3,4′-diaminodiphenylsulfone, 3,3′-diaminodiphenylsulfone, 4,4′-diaminobenzanilide, 3,4′-diaminobenzanilide, 3,3′-diaminobenzanilide, 4,4′-diaminobenzophenone, 3,4′-diaminobenzophenone, 3,3′-diaminobenzophenone, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[3-(3-aminophenoxy)phenyl]-1,1,1,3,3,3-hexafluoro propane, 2,2-bis[4-(4-aminophenoxy)phenyl]-1,1,1,3,3,3-hexafluoro propane, 1,3-bis(3-aminophenoxy)benzene, 1,4-bis(3-aminophenoxy)benzene, 1,4′-bis(4-aminophenoxy)benzene, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 1,4-bis[4-(3-aminophenoxy)benzoyl]benzen, 1,3-bis[4-(3-aminophenoxy)benzoyl]benzen, 4,4′-bis[3-(4-aminophenoxy)benzoyl]diphenylether, 4,4′-bis[3-(3-aminophenoxy)benzoyl]diphenylether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl]benzene, 1,3-bis[4-(4-aminophenoxy)-α,α-dimethylbenzyl]benzene, and 3,3′-dihydroxy-4,4′-diaminobiphenyl.

Note that it is preferable that the diamine represented by general formula (7) be contained by 2 mol % to 100 mol %, or more preferably 5 mol % to 100 mol %, with respect to the whole diamine component. Further, it is even more preferable that the diamine represented by general formula (7) be contained by 5 mol % to 98 mol %, or most preferably 8 mol % to 95 mol %, with respect to the whole diamine component. In cases where the diamine represented by general formula (7) is contained by less than 2 mol % (5 mol % in some cases) with respect to the whole diamine component, there may be a decrease in strength of adhesiveness between the resin layer and the electroless plating film. Further, in cases where the diamine represented by general formula (7) is contained by more than 98 mol % with respect to the whole diamine component, there is a possibility that the resulting polyimide resin has such a high viscosity that operationality is impaired. In such cases where the polyimide resin has viscosity, there is a possibility that foreign matter such as dirt adheres to the polyimide resin and causes defects during the formation of plated copper. For these reasons, it is preferable that the diamine represented by general formula (7) be contained by 5 mol % to 98 mol % with respect to the whole diamine component. However, in cases where the diamine represented by general formula (7) is contained by 8 mol % to 95 mol % with respect to the whole diamine component, the state of the resulting polyimide resin is improved.

A solution of the polyamic acid polymer obtained by the method is subjected to dehydration ring closure by a thermal or chemical method, with the result that a polyimide resin is obtained. The solution of the polyamic acid polymer can be subjected to dehydration ring closure appropriately in the usual manner, and a specific method therefor is not particularly limited. For example, a thermal method of dehydrating a polyamic acid solution by heat-treating it or a chemical method of performing dehydration with a dehydrating agent can be used. Further, a method of performing imidization by heating under reduced pressure can be used. The following explains each of the methods.

Examples of the thermal method for dehydration ring closure include a method of evaporating a solvent while accelerating an imidization reaction by heat-treating the polyamic acid solution. This method makes it possible to obtain a solid polyimide resin. The conditions for heating are not particularly limited. However, it is preferable that the heating be performed at a temperature of not more than 200° C. within a period of 1 second to 200 minutes.

Further, examples of the chemical method for dehydration ring closure include a method of evaporating an organic solvent and causing a dehydration reaction through the addition of not less than stoichiometric quantities of a dehydrating agent and a catalyst to the polyamic acid solution. This makes it possible to obtain a solid polyimide resin. Examples of the dehydrating agent include aliphatic acid anhydride such as anhydrous acetic acid and aromatic acid anhydride such as anhydrous benzoic acid. Further, examples of the catalyst include aliphatic tertiary amines such as triethylamine, aromatic tertiary amines such as dimethylaniline, and heterocyclic tertiary amines such as pyridine, α-picoline, β-picoline, γ-picoline, and isoquinoline. The conditions for chemical dehydration ring closure preferably include a temperature of not more than 100° C., and the organic solvent is preferably evaporated at a temperature of not more than 200° C. within a period of approximately 5 minutes to 120 minutes.

Further, there is another method for obtaining a polyimide resin. This method excludes the evaporation of a solvent from the aforementioned thermal or chemical method for dehydration ring closure. Specifically, first, a polyimide resin is deposited by pouring, into a poor solvent, a polyimide solution obtained by performing a thermal imidization process or a chemical imidization process with use of a dehydrating agent. Thereafter, a solid polyimide resin is obtained by removing an unreacted monomer from the polyimide resin thus deposited and then by purifying and drying the polyimide resin from which the unreacted monomer has been removed. The poor solvent preferably has such properties as to be mixed well with a solvent but unlikely to dissolve a polyimide resin. Examples of the poor solvent include, but are not limited to, acetone, methanol, ethanol, isopropanol, benzene, methyl cellosolve, and methyl ethyl ketone, and various types of conventionally publicly-known solvent that have such properties can be used.

The following explains a method for imidizing a polyamic acid polymer solution by heating it under reduced pressure. According to this method for imidization, water generated by imidization can be actively removed from a system. This makes it possible to inhibit hydrolysis of polyamic acid, thereby making it possible to obtain a high-molecular weight of polyimide. Further, according to this method, an opened-ring product, contained as impurities in an acid dianhydride serving as raw material, whose either or both rings are opened is subjected to ring closure again. Therefore, it can be expected that a higher-molecular weight of polyimide is obtained.

The heating conditions for the method for imidization by heating under reduced pressure preferably include a temperature range of 80° C. to 400° C., more preferably not less than 100° C., at which imidization is efficiently performed and water is efficiently removed, or even more preferably not less than 120° C. The maximum temperature is preferably not more than a temperature at which the target polyimide resin is thermally decomposed, and is usually a temperature at which normal imidization is completed, i.e., a temperature of approximately 250° C. to 350° C.

It is preferable that the pressure to be reduced be lower. Specifically, it is preferable that the pressure to be reduced be in a range of 9×10⁴ to 1×10² Pa, more preferably 8×10⁴ to 1×10² Pa, or even more preferably 7×10⁴ to 1×10² Pa. This is because in cases where the pressure to be reduced is low, a reduction in efficiency of removal of water generated by imidization may prevent the imidization from sufficiently progressing, or may cause a reduction in molecular weight of the resulting polyimide.

The foregoing has explained a polyimide resin. Examples of a relatively easily-obtainable polyimide resin, containing a siloxane structure, which can be used for the resin layer of the present embodiment include X-22-8917, X-22-8904, X-22-8951, X-22-8956, X-22-8984, and X-22-8985. Note that they are commercially available in the form of a polyimide solution.

The thus-obtained polyimide resin having a siloxane structure can be dissolved in a solvent, with the result that a solution containing the polyimide resin is obtained, from which solution the resin layer of the present embodiment is formed. Any solvent can be used as long as it can dissolve a resin component. However, in terms of inhibiting bubbles from being generated under dry conditions and reducing the residual solvent, it is preferable that the solvent have a boiling point of not more than 230° C. Examples of the solvent include tetrahydrofuran (hereinafter abbreviated as “THF”; boiling point: 66° C.), 1,4-dioxane (hereinafter abbreviated as “dioxane”; boiling point: 103° C.), monogryme (boiling point: 84° C.), dioxolane (boiling point: 76° C.), toluene (boiling point: 110° C.), tetrahydropyrane (boiling point: 88° C.), dimethoxyethane (boiling point 85° C.), N,N-dimethylformamide (boiling point: 153° C.), and N-methyl-2-pyrrolidone (boiling point: 205° C.). Any other solvents that boil at not more than 230° C. can be preferably used. These solvents may be used separately. Alternatively, a combination of two or more of them can be used. The term “dissolve” used herein means that the resin composition is dissolved by not less than 1 wt % with respect to the solvent.

Further, for example, the resin layer of the present embodiment can be formed with use of a solution obtained by thermally or chemically imidizing the polyamic acid solution.

Furthermore, the resin layer of the present embodiment can be formed with use of the polyamic acid solution. However, in this case, a step of performing an imidization process by a thermal or chemical method is required.

Further, for the purpose of improving various properties such as heat resistance and moisture resistance, it is possible that the resin layer of the present embodiment is allowed to contain other components in addition to the aforementioned polyimide resin. As the other components, various components can be added to such an extent that the foregoing purpose is achieved. Appropriate examples of the other components include, but are not particularly limited to, resins such as a thermoplastic resin and a thermosetting resin.

As the thermoplastic resin, conventionally publicly-known thermoplastic resins can be suitably used, and the thermoplastic resin is not particularly limited. Examples of the thermoplastic resin include a polysulfone resin, a polyethersulfone resin, a polyphenylene ether resin, a phenoxy resin, an acid dianhydride, and a thermoplastic polyimide resin. These thermoplastic resins can be used separately or in combination.

Further, as the thermosetting resin, conventionally publicly-known thermosetting resins can be suitably used, and the thermosetting resin is not particularly limited. Examples of the thermosetting resin include a bismaleimide resin, a bisallylnadiimide resin, a phenol resin, a cyanate resin, an epoxy resin, an acrylic resin, a methacrylic resin, a triazine resin, a hydrosilyl cured resin, an allyl cured resin, and an unsaturated polyester resin. These thermosetting resins can be used separately or in combination. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains.

Furthermore, for the purpose of improving adhesive properties with respect to the plated copper layer, it is possible that the resin layer is allowed to contain various additives through the addition of the additives to the resin layer, the application of the additives to a surface of the resin layer, or the like. As the various additives, conventionally publicly-known components can be suitably used to such an extent that the foregoing purpose is achieved, and the various additives are not particularly limited. Specific examples of the various additives include organic thiol compounds.

The resin layer can be allowed to contain conventionally publicly-known additives as needed in addition to the aforementioned components. Examples of such conventionally publicly-known additives include antioxidants, light stabilizers, fire retardants, antistatic agents, heat stabilizers, ultraviolet absorbers, conductive fillers (various organic fillers and inorganic fillers), inorganic fillers, and various reinforcing agents. These additives can be appropriately selected in accordance with the type of polyimide resin, and are not limited in terms of type. Further, these additives may be used separately or in combination. Note that the conductive fillers are those fillers which are obtained by giving conductivity to various base substances by coating the base substances with conductive substances such as carbon, graphite, metal particles, and indium tin oxide.

However, it is preferable that the aforementioned other various components be added to the resin layer in adherence with the objects of the present invention. That is, it is preferable that the other various components be added to the resin layer so as not to increase the surface roughness of the resin layer to such an extent that the formation of fine wires is adversely affected. Further, it is preferable that the other various components be added to the resin layer in such combination as not to cause a reduction in adhesiveness between the resin layer and the plated copper layer.

Note that, in order to obtain a resin layer having properties well balanced among heat resistance, adhesive properties, and the like, it is preferable that a polyimide resin, contained in a resin layer, which has a siloxane structure be in a range of 10 wt % to 100 wt % with respect to the whole resin.

The resin layer of the present invention preferably takes the form of a solution or a film. This is because such a form makes it possible to easily and accurately form a resin layer on an after-mentioned fiber-resin composite (i) by drying the fiber-resin composite onto which a solution containing the aforementioned polyimide resin has been applied, or (ii) by laminating a film on the fiber-resin composite. Note that the resin layer is not particularly limited in terms of thickness. However, in consideration of its application to a high-density printed wiring board, it is preferable that the resin layer have a small thickness. Specifically, it is preferable that the resin layer have a thickness of not more than 50 μm, or more preferably not more than 30 μm.

(1-1-3. Fiber-Resin Composite)

The following explains the fiber-resin composite of the present embodiment. The composite is not particularly limited in terms of the fiber used therefor. However, it is preferable that the fiber be at least one type of fiber selected from the group consisting of paper, glass woven fabric, glass unwoven fabric, aramid woven fabric, aramid unwoven fabric, and polytetrafluoroethylene. Examples of the paper include paper made from pulp such as paper pulp, dissolving pulp, and synthetic pulp prepared from raw material such as wood, bark, cotton, hemp, and synthetic resin. Examples of the glass woven fabric and glass unwoven fabric include glass woven fabric and glass unwoven fabric each formed from E glass, D glass, or other types of glass. Examples of the aramid woven fabric and aramid unwoven fabric include aramid woven fabric and aramid unwoven fabric each formed from aromatic polyamide or aromatic polyamide imide. The term “aromatic polyamide” used herein refers to conventionally publicly-known meta-aromatic polyamide, para-aromatic polyaimide, or copolymer aromatic polyamide thereof. Preferable examples of the polytetrafluoroethylene include polytetrafluoroethylene that has been drawn so as to have a fine continuous porous structure.

The composite is not particularly limited in terms of the resin used therefor. However, in terms of heat resistance and the like, it is preferable that the resin be at least one type of resin selected from the group consisting of an epoxy resin, a thermosetting polyimide resin, a cyanate ester resin, a hydrosilyl cured resin, a bismaleimide resin, a bisallylnadiimide resin, an acrylic resin, a methacrylic resin, an allyl resin, an unsaturated polyester resin, a polysulfone resin, a polyethersulfone resin, a thermoplastic polyimide resin, a polyphenylene ether resin, a polyolefin resin, a polycarbonate resin, and a polyester resin.

The fiber-resin composite of the present invention is not particularly limited in terms of thickness. However, in cases where the copper-clad laminate of the present invention is applied to a high-density printed wiring board, it is preferable that the fiber-resin composite have a small thickness. Specifically, it is preferable that the fiber-resin composite have a thickness of not more than 2 mm, or more preferably not more than 1 mm.

Examples of the fiber-resin composite include a prepreg layer.

(1-1-4. Method for Manufacturing a Copper-Clad Laminate)

As a method according to the present invention for manufacturing a copper-clad laminate, any method that can be imagined by a person skilled in the art may be used as long as it can be carried out in the usual manner with use of the aforementioned materials. For example, the copper-clad laminate of the present invention can be obtained by subjecting, to electroless plating, a laminate obtained by integrating the resin layer with a layer formed from the fiber-resin composite or a laminate obtained by layering such laminates. The following fully explains this method.

First, as described above, the resin layer preferably takes the form of a solution or a film. For example, in cases where the resin layer takes the form of a solution, a resin layer solution prepared by dissolving a component of the resin layer in an appropriate solvent is applied to a fiber-resin composite layer, and then the fiber-resin composite layer is dried. As a result, a laminate including a resin layer and a fiber-resin composite layer is obtained. Thereafter, the laminate can be layered on another fiber-resin composite layer or the laminate, and then integrally laminated thereon. As a result, a laminate is obtained. By subjecting these laminates to electroless plating, the copper-clad laminate of the present invention can be obtained. Note that, in case of a laminate, it is preferable that a surface of a resin layer formed on the outermost fiber-resin composite layer be subjected to electroless plating.

On this occasion, in cases where the resin layer is a resin layer containing a polyimide resin, the resin layer solution may solely contain an imidized polyimide resin, or may further contain polyamic acid serving as a polyimide resin precursor. Examples of a method for forming a resin layer on a fiber-resin composite layer include publicly-known methods such as dipping, coating by spraying, spin coating, curtain coating, and bar coating. This is an example of a case where a solution is used. The copper-clad laminate can be manufactured by another method that can be imagined by a person skilled in the art based on technical common sense of the time when the application is filed.

On the other hand, for example, in cases where the resin layer takes the form of a film, a laminate can be obtained by layering the film on a fiber-resin composite layer that serves as an outermost layer when one or more fiber-resin composite layers have been integrally laminated and then by integrally laminating the film on the fiber-resin layer. Note that, at the time of lamination, it is preferable that the film have some sort of slip sheet provided thereon. For example, in cases where the resin film is a film manufactured by drying a support onto which a resin solution has been applied by a casting method, the support can be used as such a slip sheet. That is, in cases where the resin film is integrally laminated together with a support and then the support is peeled away, the support can be used as a slip sheet. Examples of such a support include various resin films such as PET and metal foil such as aluminum foil and copper foil.

Further, the lamination can be made possible by another method. According to this method, only the film is laminated on the outermost fiber-resin composite layer after having been peeled away from the support, and a resin sheet such as Teflon® is used as a slip paper instead of the support. In either case, it is preferable that the slip sheet be able to be peeled away from the resin layer and that the slip sheet be so flat and smooth as not to give a surface of the resin layer such irregularities and blemishes that formation of fine wires is prevented.

In addition to the aforementioned methods, there are various methods each of which can be applied as a method for forming a resin layer on a fiber-resin composite layer (the outermost fiber-resin composite layer in cases where a plurality of fiber-resin composite layers have been laminated). The timing of the formation of a resin layer is not particularly limited. For example, a resin layer may be formed in advance on a fiber-resin composite layer (the outermost fiber-resin composite layer in cases where a plurality of fiber-resin composite layers have been laminated). Alternatively, a resin layer may be formed on a fiber-resin composite layer (the outermost fiber-resin composite layer in cases where a plurality of fiber-resin composite layers have been laminated) at the time of lamination.

As a method for lamination, a publicly-known method can be used in the usual manner. Specific examples of the method for lamination include thermocompression bonding such as heat pressing, vacuum pressing, lamination (heat lamination), vacuum lamination, heat roller lamination, or vacuum heat roller lamination. In order for the resulting copper-clad laminate to sufficiently exhibit its properties, it is preferable that the lamination be performed at such a temperature and for such a period that the fiber-resin composite layer used is sufficiently cured. Further, after the lamination has been completed by thermocompression bonding according to the method, complete curing is performed. Then, an after curing process may be performed with a hot-air oven or the like for the purpose of improving the adhesivity between the resin layer and the fiber-resin composite layer.

Further, the copper-clad laminate according to the present invention can be obtained by a method other than the aforementioned methods, i.e., by first obtaining a laminate whose resin layer has a surface subjected to electroless plating and then by laminating the laminate on a fiber-resin composite layer. This method can also be put into operation appropriately in the usual manner by a person skilled in the art.

The copper-clad laminate can be obtained by subjecting, to electroless copper plating, the laminate thus obtained by laminating the resin layer and the fiber-resin laminate. In order to adjust the thickness of copper foil, electrolytic copper plating may be performed in addition to the electroless copper plating. Further, in order to activate a surface of the resin layer and improve the adhesivity between the plated copper layer and the resin layer, it is very preferable that a process, such as a desmear process, in which an alkaline aqueous solution is used be performed before the electroless copper plating.

<1-2. Printed Wiring Board>

As described above, the copper-clad laminate according to the present invention has a copper layer adhering firmly to a flat and smooth resin layer. For this reason, the copper-clad laminate of the present invention excels in fine wiring formability, and can be used, for example, as a printed wiring board. Examples of a printed wiring board obtained with use of the copper-clad laminate include various high-density printed wiring boards such as a single- or double-sided printed wiring board obtained by forming wires on the copper-clad laminate and a built-up wiring board obtained by using the copper-clad laminate as a core substrate.

The following shows an example of how a single- or double-sided printed wiring board is manufactured with use of the copper-clad laminated of the present invention.

(1) Forming a Plating Resist

First, a plating resist is formed on the copper-clad laminate. Examples of the plating resist include a photosensitive plating resist. The photosensitive plating resist can be made of a publicly-known material that is widely commercially available. According to a method of the present invention for manufacturing a printed wiring board, it is preferable that a photosensitive plating resist having a resolution pitch of not more than 50 μm be used so that finer wires can be formed. Note that a printed wiring board of the present invention may contain both a circuit having a wiring pitch of not more than 50 μm and a circuit having a wiring pitch of not more than 50 μm.

(2) Performing Pattern Plating by Electrolytic Copper Plating

Next, that portion of the copper-clad laminate on which no resist has been formed is subjected to electrolytic copper pattern plating in the usual manner. This can be carried out by a person skilled in the art by application of a large number of publicly-known methods.

(3) Peeling Away the Resist

Then, the resist is peeled away. A material suitable for peeling the plating resist thus used can be suitably used in the usual manner for peeling away the resist, and is not particularly limited. Examples of such a material include an aqueous solution of sodium hydroxide and an aqueous solution of potassium hydroxide.

(4) Forming Wires by Quick-Etching the Electroless Plating Layer

Moreover, wires are formed by quick-etching the electroless plating layer. The quick etching can be performed with use of a publicly-known quick etchant. Examples of such a quick etchant include a sulfuric acid/hydrogen peroxide etchant, an ammonium persulfate etchant, a sodium persulfate etchant, a diluted ferric chloride etchant, and a diluted cupric chloride etchant.

The method is a so-called semi-additive method that is applied to formation of fine wires, and the semi-additive method can be suitably used for the copper-clad laminate of the present invention. Meanwhile, since the copper-clad laminate of the present invention is such that plated copper can be formed firmly on a flat and smooth surface, there will be no copper remaining in the irregularities of the resin after etching. This makes it possible to apply a subtractive method of forming wires by removing unnecessary copper by etching after having formed a resist. However, while the subtractive method has an advantage of having a fewer steps, the subtractive method has a problem such as a defect caused in the shape of wires due to side etching. Therefore, the subtractive method, the semi-additive method, or another usual method may be appropriately selected in consideration of the pitch of wires to be formed, productivity, cost, and the like.

Furthermore, it is possible to manufacture a built-up printed wiring board by using, as a core substrate, the printed wiring board thus manufactured. In this case, fine wires can be formed on the core substrate per se. This makes it possible to manufacture a higher-density built-up wiring board.

### Examples

The invention of the present embodiment will be described more in detail in accordance with Examples. However, the present invention is not limited to these. A person skilled in the art can make various changes, modifications, and alterations within the scope of the present invention. Note that such properties of copper-clad laminates of Examples and Comparative Examples as adhesive properties with respect to electroless plated copper, surface roughness Ra, and wiring formability were evaluated or calculated in the following manner.

[Evaluation of Adhesive Properties]

The obtained sample (copper-clad laminate) was subjected to electroless plating so that the thickness of a plated copper layer was 18 μm. Thereafter, the obtained sample was dried at 180° C. for 30 minutes. Then, the adhesive strength under normal conditions and the adhesive strength after a pressure cooker test (PCT) were measured in accordance with JPCA-BU01-1998 (issued by Japan Printed Circuits Association).

The term “adhesive strength under normal conditions” refers to adhesive strength measured after the copper-clad laminated is allowed to stand for 24 hours at a temperature of 25° C. with a humidity of 50%. Further, the term “adhesive strength after PCT” refers to adhesive strength measured after the copper-clad laminated is allowed to stand for 96 hours at a temperature of 121° C. with a humidity of 100%.

[Measurement of Surface Roughness Ra]

The plated copper layer was removed from the copper-clad laminate by etching, and the surface roughness Ra of the exposed surface was measured. Specifically, the arithmetic mean roughness of Surface A was measured with use of an optical interferotype surface roughness tester (New View 5030 System manufactured by Zygo Corporation) under the following condition.

### (Measurement Conditions);

Objective lens: 50-power Mirau Image zoom: 2

### FDA Res: Normal

Analysis conditions;

### Remove: Cylinder

### Filter: High Pass

### Filter Low Waven: 0.002 mm

[Wiring Formability]

A resist pattern was formed on the plated copper layer of the copper-clad laminate, and electroless copper pattern plating was performed so that the thickness of pattern copper was 10 μm. Then, the resist pattern was peeled away. Furthermore, the exposed plated copper was removed with a hydrochloric acid/ferric chloride etchant. This resulted in a double-sided printed wiring board having wires with a line-and-space (L/S) of 10 μm/10 μm. Wiring formability was evaluated such that the symbol “∘” represents a case where the wires of the printed wiring board had been manufactured satisfactorily without a breakage or a defect in shape and the symbol “x” represents a case where the wires of the printed wiring board had a breakage or a defect in shape.

### Example of how a Polyimide Resin is Synthesized 1

62 g (0.075 mol) of KF8010 manufactured by Shin-Etsu Chemical Co., Ltd., 15 g (0.075 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bisphthalic acid anhydride was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 1 was obtained.

### Example of How a Polyimide Resin is Synthesized 2

86 g (0.10 mol) of KF8010 manufactured by Shin-Etsu Chemical Co., Ltd., 9 g (0.05 mol) of 4,4′-diaminodiphenylether, and DMF were poured into a glass flask having a capacity of 2000 ml, and then were stirred for dissolution. Then, 78 g (0.15 mol) of 4,4-(4,4′-isopropylidendiphenoxy)bisphthalic acid anhydride was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 2 was obtained.

### Example of how a Solution for Forming a Resin Layer is Prepared 1

Polyimide Resin 1 was dissolved in dioxolan, with the result that Solution (A) for forming a resin layer was obtained with a solid content concentration of 5 wt %.

### Example of how a Solution for Forming a Resin Layer is Prepared 2

Polyimide Resin 2 was dissolved in dioxolan, with the result that Solution (B) for forming a resin layer was obtained with a solid content concentration of 5 wt %.

### Example of how a Solution for Forming a Resin Layer is Prepared 3

32.1 g of YX4000H (i.e., a biphenyl epoxy resin manufactured by Japan Epoxy Resin Co., Ltd.), 17.9 g of bis[4-(3-aminophenoxy)phenyl]sulfone (i.e., a diamine manufactured by Wakayama Seika Kogyo Co., Ltd.), 0.2 g of 2,4-diamino-6-[2′-undecylimidazolyl-(1′)]-ethyl-s-triazine (i.e., an epoxy curing agent manufactured by Shikoku Chemicals Co., Ltd.) were dissolved in dioxolan, with the result that Epoxy Resin Composition Solution (C) was obtained with a solid content concentration of 5 wt %. 90 g of Solution (B) and 10 g of Solution (C) were mixed, with the result that Solution (D) for forming a resin layer was obtained.

### Example of how a Solution for Forming a Fiber-Resin Composite Layer is Prepared 1

3 g of dicyandiamide, 0.1 g of 2-ethyl-4-methylimidazol, and 60 g of acetone were added to 100 g of bisphenol A epoxy resin (having an epoxy equivalent weight of 480), and the resulting mixture were stirred for dissolution, with the result that Solution (E) for forming a fiber-resin composite was obtained.

### Example of how a Solution for Forming a Fiber-Resin Composite Layer is Prepared 2

90 g of 2,2-bis(4-cyanatephenyl)propane and 10 g of bis(4-maleimidephenyl)methane were brought into a preparatory reaction with each other at 150° C. for 100 minutes, and the resulting product was dissolved in a mixed solvent of methyl ethyl ketone and DMF. Furthermore, 1.8 parts of zinc octylate were added to the mixture, and the resulting mixture was stirred to combine. This resulted in Solution (F) for forming a fiber-resin composite.

### Example 1

Solution (A) for forming a resin layer was applied onto a surface of a support film (marketed as “Cellapeel HP”; manufactured by Toyo Metallizing Co., Ltd.) by a casting method. Thereafter, the support film was dried by heating at 60° C. with a hot-air oven, with the result that Resin Layer Film (G) having a thickness of 10 μm was obtained.

Meanwhile, Solution (E) for forming a fiber-resin composite was applied to glass woven fabric having a thickness of 100 μm, and the glass woven fabric was impregnated with Solution (E). Thereafter, the glass woven fabric was dried at a temperature of 160° C., with the result that a fiber-resin composite having a resin content of 45 wt % was obtained. Four such fiber-resin composites were layered. On both surfaces of the resulting product, such Films (G) as obtained above were layered after having been peeled away from the support film. The resulting product was subjected to vacuum press lamination at 170° C. under 3 MPa for 90 minutes. In so doing, a resin film (marketed as “AFLEX”; manufactured by Asahi Glass Co., Ltd.) was used as a slip sheet. As a result, a laminate was obtained. The laminate thus obtained was subjected to a desmear process under conditions shown below in Table 1, and then was subjected to electroless plating under conditions shown below in Table 2. As a result, a copper-clad laminate was obtained.

TABLE 1

| | | | Processing | Processing |
|---|---|---|---|---|
| Step | Liquid composition | | temperature | time |
| Swelling | Swelling Dip | 500 ml/l | 60° C. | 5 minutes |
| | Securiganth P | | | |
| | Sodium hydroxide | 3 g/l | | |
| Water washing | | | | |
| Micro etching | Concentrate | 550 ml/l | 80° C. | 5 minutes |
| | Compact CP | | | |
| | Sodium hydroxide | 40 g/l | | |
| Water washing | | | | |
| Neutralization | Reduction Solution | 50 ml/l | 40° C. | 5 minutes |
| | Securiganth P | | | |
| | Sulfuric acid | 70 ml/l | | |

TABLE 2

| | | | Processing | Processing |
|---|---|---|---|---|
| Step name | Liquid composition | | temperature | time |
| Cleaner conditioner | Cleaner Securiganth 902 | 40 ml/l | 60° C. | 5 minutes |
| | Cleaner Additive 902 | 3 ml/l | | |
| | Sodium hydroxide | 20 g/l | | |
| Water Washing | | | | |
| Predip | Predip Neoganth-B | 20 ml/l | at RT | 1 minute |
| | Sulfuric acid | 1 ml/l | | |
| Catalyst supply | Activator Neoganth 834 conc | 40 ml/l | 40° C. | 5 minutes |
| | Sodium hydroxide | 4 g/l | | |
| | Boric acid | 5 g/l | | |
| Water washing | | | | |
| Activation | Reducer Neoganth | 1 g/l | at RT | 2 minutes |
| | Sodium hydroxide | 5 g/l | | |
| Water washing | | | | |
| Electroless copper | Basic Solution Printoganth MSKDK | 80 ml/l | 32° C. | 15 minutes |
| plating | Copper Solution Printoganth MSK | 40 ml/l | | |
| | Reducer Cu | 14 ml/l | | |
| | Stabilizer Printoganth MSKDK | 3 ml/l | | |

The copper-clad laminate thus obtained was evaluated in accordance with procedures for evaluating various evaluation items. The evaluation results are shown in Table 3. Note that the wiring formability was evaluated by, after having formed a resist, forming wires by etching according to a subtractive method.

### Example 2

A copper-clad laminate was obtained in the same manner as in Example 1 except that Solution (B) for forming a resin layer was used. The copper-clad laminate thus obtained was evaluated in accordance with procedures for evaluating various evaluation items. The evaluation results are shown in Table 3.

### Example 3

A copper-clad laminate was obtained in the same manner as in Example 1 except that Solution (D) for forming a resin layer was used. The copper-clad laminate thus obtained was evaluated in accordance with procedures for evaluating various evaluation items. The evaluation results are shown in Table 3.

### Example 4

Solution (F) for forming a fiber-resin composite was applied to glass woven fabric having a thickness of 100 μm, and the glass woven fabric was impregnated with Solution (F). Thereafter, the glass woven fabric was dried at a temperature of 160° C., with the result that a fiber-resin composite having a resin content of 45 wt % was obtained. Four such fiber-resin composites were layered. On both surfaces of the resulting product, such Films (G) as obtained above in Example 2 were layered after having been peeled away from the support film. The resulting product was subjected to vacuum press lamination at 200° C. under 2 MPa for 120 minutes. Except that, a copper-clad laminate was obtained in the same manner as in Example 1. The copper-clad laminate thus obtained was evaluated in accordance with procedures for evaluating various evaluation items. The evaluation results are shown in Table 3.

### Example 5

Solution (B) for forming a resin layer was applied by a spin coat method onto two of such four fiber-resin composites as obtained in Example 1, and then the two fiber-resin composites were dried at a temperature of 60° C. with a hot-air oven, with the result that two fiber-resin composites each having a 2-μm-thick resin layer were obtained. The two fiber-resin composites thus treated were layered on the two untreated fiber-resin composites so that the untreated fiber-resin composites were sandwiched between the two treated fiber-resin composites and that the respective resin layers of the two treated fiber-resin composites face outward. Except that, a copper-clad laminate was obtained in the same manner as in Example 1. The copper-clad laminate thus obtained was evaluated in accordance with procedures for evaluating various evaluation items. The evaluation results are shown in Table 3.

### Example 6

Films (G), obtained as described in Example 2, which have not been peeled away from their respective support films were respectively layered on two of such four fiber-resin composites as obtained in Example 1. The resulting product was subjected to vacuum press lamination at 150° C. under 1 MPa for 6 minutes, and then the support films were peeled away, with the result that two fiber-resin composites each having a 10-μm-thick resin layer were obtained. The two fiber-resin composites thus treated were layered on the two untreated fiber-resin composites so as to sandwich the untreated fiber-resin composites therebetween. Except that, a copper-clad laminate was obtained in the same manner as in Example 1. The copper-clad laminate thus obtained was evaluated in accordance with procedures for evaluating various evaluation items. The evaluation results are shown in Table 3.

### Comparative Example 1

A copper-clad laminate was obtained in the same manner as in Example 1 except that four such fiber-resin composites as obtained in Example 1 was so laminated on two 18-μm-thick pieces of electrolytic copper foil as to be sandwiched between the two pieces of copper foil. The copper-clad laminate thus obtained was evaluated in accordance with procedures for evaluating various evaluation items. The evaluation results are shown in Table 4. Note that the wiring formability was evaluated by, after having formed a resist, forming wires by etching according to a subtractive method.

### Comparative Example 2

A copper-clad laminate was obtained in the same manner as in Example 1 except that four such fiber-resin composites as used in Example 4 was so laminated on two 18-μm-thick pieces of electrolytic copper foil as to be sandwiched between the two pieces of copper foil. The copper-clad laminate thus obtained was evaluated in accordance with procedures for evaluating various evaluation items. The evaluation results are shown in Table 4. Note that the wiring formability was evaluated by, after having formed a resist, forming wires by etching according to a subtractive method.

TABLE 3

| | Example 1 | Example 2 | Example 3 | Example 4 | Example 5 | Example 6 |
|---|---|---|---|---|---|---|
| Solution for forming a resin layer | (A) | (B) | (D) | (A) | (B) | (A) |
| Solution for forming a fiber-resin | (E) | (E) | (E) | (F) | (E) | (E) |
| composite | | | | | | |
| Adhesive strength under normal | 11 N/cm | 11 N/cm | 9 N/cm | 10 N/cm | 11 N/cm | 11 N/cm |
| conditions | | | | | | |
| Adhesive strength after PCT | 8 N/cm | 6 N/cm | 5 N/cm | 6 N/cm | 6 N/cm | 6 N/cm |
| Surface roughness Ra | 0.02 μm | 0.01 μm | 0.02 μm | 0.01 μm | 0.01 μm | 0.01 μm |
| Fine wiring formability | ∘ | ∘ | ∘ | ∘ | ∘ | ∘ |
| L/S = 10 μm/10 μm | | | | | | |

TABLE 4

| | Comparative | Comparative |
|---|---|---|
| | Example 1 | Example 2 |
| Solution for forming a resin layer | NA | NA |
| Adhesive strength under normal conditions | 14 N/cm | 12 N/cm |
| Adhesive strength after PCT | 10 N/cm | 9 N/cm |
| Surface roughness Ra | 0.89 μm | 0.84 μm |
| Fine wiring formability | x | x |
| L/S = 10 μm/10 μm | | |

### Embodiment 2

<2-1. Arrangement of a Laminate of the Present Embodiment>

A laminate of the present embodiment is characterized by having a resin layer (b), provided on at least one surface of a fiber-resin composite (a), on which a metal plating layer is to be formed. The laminate may be arranged such that a fiber-resin composite (a) and a resin layer (b) on which a metal plating layer is to be formed are laminated in the order named, that a resin layer (b) on which a metal plating layer is to be formed, a fiber-resin composite (a), and a resin layer (b) on which a metal plating layer is to be formed are laminated in the order named, or that a fiber-resin composite (a), a resin layer (c), and a resin layer (b) on which a metal plating layer is to be formed are laminated in the order named. Further, the laminate may be arranged such that a fiber-resin composite (a), a resin layer (c), a polymer film, a resin layer (b) on which a metal plating layer is to be formed are laminated in the order named. That is, the laminate may be arranged in any manner as long as it includes a fiber-resin composite (a) and a resin layer (b) on which a metal plating layer is to be formed.

The formation of wires on the laminate of the present invention makes it possible to obtain a single- or double-sided printed wiring board. Further, the use of the single- or double-sided printed wiring board as a core substrate makes it possible to obtain a built-up wiring board. Furthermore, the use of the laminate of the present invention as a built-up material makes it possible to obtain a built-up wiring board. The laminate of the present invention excels in fine wiring formability, and therefore can be suitably applied to other various high-density printed wiring boards.

The resin-fiber composite (a) serving as one of the components of the laminate of the present invention may be in a B stage or in a C stage.

In the present embodiment, in terms of adhesive properties with respect to a metal plating layer, it is preferable that the resin layer (b), serving as a component of the laminate, on which a metal plating layer is to be formed contain a polyimide resin having a siloxane structure.

In either case, it is preferable that the laminate according to the present embodiment be arranged such that a metal plating layer is formed on the resin layer (b).

(2-1-1. Fiber-Resin Composite (a))

The fiber-resin composite (a) of the present embodiment can be any kind of combination of a fiber and a resin. For example, the resin may be a resin formed solely from a thermoplastic resin, may be a resin formed solely from a thermosetting component, or may be a resin formed from a thermoplastic resin and a thermosetting component. Among these, in order to obtain a fiber-resin composite (a) that is in a B stage or in a C stage, it is preferable that the composite (a) of the present invention be formed from a resin containing a thermosetting component.

The term “B stage” used herein refers to an intermediate stage in a reaction of a thermosetting component that is used for the fiber-resin composite (a), and is also referred to as “half-cured state”. In a B stage, although the fiber-resin composite (a) is softened by heating, the fiber-resin composite (a) is not completely melted or dissolved even in contact with a certain type of liquid. Therefore, in cases where the fiber-resin composite (a) is in a B stage, the laminate of the present invention is softened by heat processing, so that an inner-layer circuit can be embedded. This makes it possible to use the laminate suitably as a built-up material.

Further, the term “C stage” used herein refers to a stage in which a thermosetting component that is used for the fiber-resin composite (a) is substantially cured to be in an insoluble state. Therefore, in cases where the fiber-resin composite (a) is in a C stage, a printed wiring board can be obtained by forming a metal layer directly on the fiber-resin composite (a) and then by subjecting the fiber-resin composite (a) to patterning.

The resin is not particularly limited. However, in consideration of the application to a printed wiring board, it is preferable that the fiber be at least one type selected from the group consisting of paper, glass woven fabric, glass unwoven fabric, aramid woven fabric, aramid unwoven fabric, and polytetrafluoroethylene.

Examples of the paper include paper made from pulp such as paper pulp, dissolving pulp, and synthetic pulp prepared from raw material such as wood, bark, cotton, hemp, and synthetic resin. Examples of the glass woven fabric and glass unwoven fabric include glass woven fabric and glass unwoven fabric each formed from E glass, D glass, or other types of glass. Examples of the aramid woven fabric and aramid unwoven fabric include unwoven fabric each formed from aromatic polyamide or aromatic polyamide imide. The term “aromatic polyamide” used herein refers to conventionally publicly-known meta-aromatic polyamide, para-aromatic polyaimide, or copolymer aromatic polyamide thereof. Preferable examples of the polytetrafluoroethylene include polytetrafluoroethylene that has been drawn so as to have a fine continuous porous structure.

The following explains the fiber-resin composite (a) of the present embodiment. The resin is not particularly limited. The resin may be a resin formed solely from a thermoplastic resin, may be a resin formed solely from a thermosetting component, or may be a resin formed from a thermoplastic resin and a thermosetting component. Examples of the thermoplastic resin include a polysulfone resin, a polyethersulfone resin, a thermoplastic polyimide resin, a polyphenylene ether resin, a polyolefin resin, a polycarbonate resin, and a polyester resin. Further, examples of the thermosetting component include an epoxy resin, a thermosetting polyimide resin, a cyanate ester resin, a hydrosilyl cured resin, a bismaleimide resin, bisallylnadiimide resin, an acrylic resin, a methacrylic resin, an allyl resin, and an unsaturated polyester resin. Further, the thermoplastic resin and the thermosetting component may be used in combination.

For the purpose of improving the adhesive properties of the fiber-resin composite (a) with respect to a resin layer (b) and a resin layer (c), various coupling agents such as a silane coupling agent may be used together in manufacturing the fiber-resin composite (a).

The fiber-resin composite (a) of the present embodiment includes a fiber, and therefore has such an advantage that a low thermal expansivity is obtained. In terms of obtaining a lower thermal expansivity, various organic fillers or inorganic fillers may be added to the resin.

The fiber-resin composite (a) of the present embodiment is obtained (i) by impregnating the aforementioned fiber with a resin solution obtained by dissolving the aforementioned resin in an appropriate solvent, and then (ii) by drying by heating the resin thus impregnated with the resin solution. Note that the drying by heating may be stopped in a B stage, or may be allowed to further proceed to a C stage.

The fiber-resin composite (a) of the present embodiment is not particularly limited in terms of thickness. However, in cases where the laminate of the present invention is applied to a high-density printed wiring board, it is preferable that the fiber-resin composite (a) have a small thickness. Specifically, it is preferable that the fiber-resin composite (a) have a thickness of not more than 2 mm, or more preferably not more than 1 mm. Further, in cases where the laminate of the present invention is used as a built-up material, it is preferable, in terms of thinning the resulting built-up wiring board, that the fiber-resin composite (a) be as thin as possible and have a resin content sufficient for an inner-layer circuit to be embedded. The thinnest glass woven fabric in existence has a thickness of 40 μm, and the use of such glass woven fabric makes it possible to thin the fiber-resin composite (a) of the laminate according to the present invention. Further, if technological advances bring about a fiber such as thinner glass woven fabric, the use of such a fiber makes it possible to further thin the fiber-resin composite (a) of the laminate according to the present invention.

(2-1-2. Resin Layer (b) on which a Metal Plating Layer is to be Formed)

The “resin layer (b) on which a metal plating layer is to be formed” of the present embodiment refers to a resin layer, having a flat and smooth surface on which a metal plating layer can be firmly formed, which can also adhere firmly to the fiber-resin composite (a). That is, the “resin layer (b) on which a metal plating layer is to be formed” can be said to be a resin layer functioning as an adhesive formed between the fiber-resin composite (a) and the metal plating layer.

As the “resin layer (b) on which a metal plating layer is to be formed”, any resin may be used as long as it satisfies the above conditions. However, in terms of adhesive properties with respect to a metal plating layer, it is preferable that the “resin layer (b) on which a metal plating layer is to be formed” contain a polyimide resin, more preferably a polyimide resin having one or more structures represented by any one of general formulae (1) to (6), or even more preferably a polyimide resin having a siloxane structure. Note that the “resin layer (b) on which a metal plating layer is to be formed” of the present embodiment can be explained appropriately with the aid of the description of (1-1-2. Resin Layer) of Embodiment 1.

(2-1-3. Resin Layer (c))

The laminate according to the present embodiment can provided with a resin layer (c) for the purpose of, for example, improving adhesiveness between the fiber-resin composite (a) and the resin layer (b) on which a metal plating layer is to be formed. In order to express good adhesive properties with respect to each of the fiber-resin composite (a) and the resin layer (b) on which a metal plating layer is to be formed, it is preferable that the resin layer (c) contain a thermosetting component. Examples of a thermosetting resin that is suitably used for the resin layer (c) include a bismaleimide resin, a bisallylnadiimide resin, a phenol resin, a cyanate resin, an epoxy resin, an acrylic resin, a methacrylic resin, a triazine resin, a hydrosilyl cured resin, an allyl resin, and an unsaturated polyester resin. There resins can be used separately or in combination. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains. Further, in order to express good adhesive properties with respect to each of the fiber-resin composite (a) and the resin layer (b) on which a metal plating layer is to be formed, it is preferable that the resin layer (c) contain a thermoplastic resin. Examples of the thermoplastic resin include a polysulfone resin, a polyethersulfone resin, a polyphenylene ether resin, a phenoxy resin, and a thermoplastic polyimide resin. These resins can be used separately or in combination.

According to a method for providing the resin layer (c), the resin layer (c) is provided by (i) preparing a resin solution by dissolving, in an appropriate solvent, a resin for forming the resin layer (c), (ii) applying the resin solution onto the fiber-resin composite (a) by a publicly-known method such as dipping, coating by spraying, spin coating, curtain coating, or bar coating, and then (iii) drying the fiber-resin composite (a).

According to another method for providing the resin layer (c), the resin layer (c) is provided by shaping the resin layer (c) into a film and then by integrally laminating the film on the fiber-resin composite (a) by thermocompression bonding such as heat pressing, vacuum pressing, lamination (heat lamination), vacuum lamination, heat roller lamination, or vacuum heat roller lamination.

Further, according to still another method for providing the resin layer (c), the resin layer (c) is provided by (i) shaping, into a film, the resin layer (b) on which a metal plating layer is to be formed, (ii) preparing a resin solution by dissolving, in an appropriate solvent, a resin for forming the resin layer (c), (iii) applying the resin solution onto the film by a publicly-known method such as dipping, coating by spraying, spin coating, curtain coating, or bar coating, and then (iv) drying the resin layer (b). The resin layer (c) can be formed by any method that can be imagined by a person skilled in the art.

For the purpose of, for example, improving the rigidity of the laminate, a polymer film may be provided between the resin layer (b) on which a metal plating layer is to be formed and the resin layer (c). On this occasion, in terms of heat resistance, rigidity, and the like, it is preferable that the polymer film be a non-thermoplastic polyimide film.

The resin layer (c) is not particularly limited in terms of thickness. However, in consideration of its application to a high-density printed wiring board, it is preferable that the resin layer (c) have a small thickness. Specifically, it is preferable that the resin layer (c) have a thickness of not more than 50 μm, or more preferably not more than 30 μm.

Further, the polymer film is not particularly limited in terms of thickness, either. However, in terms of its application to a high-density printed wiring board, it is preferable that the polymer film have a small thickness. Specifically, it is preferable that the polymer film have a thickness of not more than 50 μm, or more preferably not more than 30 μm.

(2-1-4. Metal Plating Layer)

On the resin layer (b) on which a metal plating layer is to be formed, a metal plating layer can be formed by dry plating such as vapor deposition, sputtering, and CVD, or by wet plating such as electroless plating. However, in terms of exploitation of such a feature of the laminate of the present embodiment that electroless plating adheres satisfactorily even to a flat and smooth surface, it is preferable that the metal plating layer be a layer formed from electroless plating. Examples of the type of electroless plating include electroless copper plating, electroless nickel plating, electroless gold plating, electroless silver plating, and electroless tin plating. Any one of the types of electroless plating can be used for the present invention. However, from an industrial point of view and in terms of electrical characteristics such as migration resistance, electroless copper plating and electroless nickel plating are preferred, or electroless copper plating is preferred in particular. Further, the metal plating layer may be a layer formed solely from electroless plating, or may be a layer obtained by shaping a formed electroless plating layer into a desired thickness by electrolytic plating.

The metal plating layer is not particularly limited in terms of thickness. However, in consideration of fine wiring formability, it is preferable that the metal plating layer have a thickness of not more than 25 μm, or more preferably not more than 20 μm.

(2-1-5. Laminate)

The laminate of the present embodiment is characterized by having a resin layer (b), provided on at least one surface of a fiber-resin composite (a), on which a metal plating layer is to be formed. The laminate may be arranged such that a fiber-resin composite (a) and a resin layer (b) on which a metal plating layer is to be formed are laminated in the order named, that a resin layer (b) on which a metal plating layer is to be formed, a fiber-resin composite (a), and a resin layer (b) on which a metal plating layer is to be formed are laminated in the order named, or that a fiber-resin composite (a), a resin layer (c), and a resin layer (b) on which a metal plating layer is to be formed are laminated in the order named. Further, the laminate may be arranged such that a fiber-resin composite (a), a resin layer (c), a polymer film, a resin layer (b) on which a metal plating layer is to be formed are laminated in the order named. That is, the laminate may be arranged in any manner as long as it includes a fiber-resin composite (a) and a resin layer (b) on which a metal plating layer is to be formed.

Examples of a printed wiring board obtained with use of a laminate according to the present embodiment include a single- or double-sided printed wiring board obtained by forming wires on the laminate according to the present embodiment. Further, the use of the single- or double-sided printed wiring board as a core substrate makes it possible to obtain a built-up wiring board. Furthermore, the use of the laminate of the present invention as a built-up material makes it possible to obtain a built-up wiring board. The laminate of the present invention excels in fine wiring formability, and therefore can be suitably applied to other various high-density printed wiring boards.

The laminate may be such that a metal plating layer is formed on the resin layer (b) on which a metal plating layer is to be formed. That is, the laminate according to the present embodiment can be such that a metal plating layer is formed firmly on a flat and smooth resin layer (b) on which a metal layer surface is to be formed. This makes it possible to form fine wires as designed. In order to achieve good fine wiring formability, it is preferable that the surface roughness of the resin layer (b) on which a metal plating layer is to be formed be less than 0.5 μm in terms of arithmetic mean roughness Ra as measured at a cutoff value of 0.002 mm. See Embodiment 1 for an explanation of the “arithmetic mean roughness Ra as measured at a cutoff value of 0.002 mm”.

The laminate according to the present embodiment on which the metal plating layer has been formed is not particularly limited in terms of thickness. However, in consideration of its application to a high-density printed wiring board, it is preferable that the laminate on which the metal plating layer has been formed have a small thickness. Specifically, it is preferable that the laminate on which the metal plating layer has been formed have a thickness of not more than 2 mm, or more preferably not more than 1 mm.

<2-2. Method for Manufacturing a Laminate>

As a method according to the present embodiment for manufacturing a laminate, any method that can be imagined by a person skilled in the art may be used. The following illustrates a method for manufacturing a laminate of the present invention in cases where a fiber-resin composite (a) serving as one component of the laminate is in a B stage.

In such a case, the laminate of the present invention can be obtained in the following manner. First, a resin solution is prepared by dissolving, in an appropriate solvent, a resin for forming a fiber-resin composite (a). Next, a fiber is impregnated with the resin solution thus prepared, and then is dried by heating, with the result that a fiber-resin composite (a) that is in a B stage is obtained. Further, another resin solution is prepared by dissolving, in an appropriate solvent, a resin for forming a resin layer (b) on which a metal plating layer is to be formed. Next, the resin solution thus prepared is applied onto the fiber-resin composite (a) by a publicly-known method such as dipping, coating by spraying, spin coating, curtain coating, or bar coating, and then the fiber-resin composite (a) is dried. Note that it is necessary that the drying be performed under such conditions that the B stage is maintained.

Alternatively, the laminate of the present invention can be obtained in the following manner: A film-like resin layer (b) on which a metal plating layer is to be formed and a fiber-resin composite (a) that is in a B stage are layered, and then are integrally laminated by thermocompression bonding such as heat pressing, vacuum pressing, lamination (heat lamination), vacuum lamination, heat roller lamination, or vacuum heat roller lamination. Also in this case, it is necessary that the lamination be performed under such conditions that the B stage is maintained.

The following illustrates a method for manufacturing a laminate of the present invention in cases where a fiber-resin composite (a) serving as one component of the laminate is in a C stage.

In such a case, the laminate of the present invention can be obtained in the following manner. First, a resin solution is prepared by dissolving, in an appropriate solvent, a resin for forming a fiber-resin composite (a). Next, a fiber is impregnated with the resin solution thus prepared, and then is dried by heating, with the result that a fiber-resin composite that is in a B stage is obtained. Further, another resin solution is prepared by dissolving, in an appropriate solvent, a resin for forming a resin layer (b) on which a metal plating layer is to be formed. Next, the resin solution thus prepared is applied onto the fiber-resin composite (a) by a publicly-known method such as dipping, coating by spraying, spin coating, curtain coating, or bar coating, and then the fiber-resin composite is dried. Note that it is necessary that the drying be performed under such conditions that the curing proceeds to a C stage. Note that a fiber-resin composite (a) that is already in a C stage can be used above.

Alternatively, the laminate of the present invention can be obtained in the following manner: A film-like resin layer (b) on which a metal plating layer is to be formed and a fiber-resin composite (a) that is in a B stage are layered, and then are integrally laminated by thermocompression bonding such as heat pressing, vacuum pressing, lamination (heat lamination), vacuum lamination, heat roller lamination, or vacuum heat roller lamination. Also in this case, it is necessary that the drying be performed under such conditions that the curing proceeds to a C stage. Note that a fiber-resin composite (a) that is already in a C stage can be used above.

Note that it is only necessary that the lamination be performed by selecting such conditions that a B stage or a C stage is attained. However, it is impossible to make generalizations because such lamination conditions that a B stage is maintained or such lamination conditions that curing proceeds to a C stage vary depending on the type of resin used. On this occasion, it is only necessary that whether a B stage or a C stage is attained be judged by using cure extent as an index. Cure extent can be measured by a method such as (i) a method for measuring a cure calorific value and a residual cure calorific value with a DSC (Differential Scanning Calorimetry), (ii) a method for determining cure extent by the absorption peak of a functional group with an infrared absorption spectrum, or (iii) a technique (e.g., Di Benedetto method) using a value of glass transition temperature. In addition, a laminate including a resin layer (b) on which a metal plating layer is to be formed and a fiber-resin composite (a) that is in a B stage can be obtained by removing, by etching, copper foil provided on both surfaces of a commercially available copper-clad laminate and then by forming thereon the resin layer (b) on which a metal plating layer is to be formed.

The following provides an explanation of the lamination. At the time of the lamination, the film-like resin layer (b) on which a metal plating layer is to be formed needs some sort of slip sheet. For example, if the film is a film manufactured by applying a resin solution onto a support by a casting method and then by drying the support, the support can be used as a slip sheet by integrally laminating the film and the support and then by peeling away the support from the film. Examples of the support include various resin films such as PET and metal foil such as aluminum foil and copper foil. The lamination can be made possible by another method. According to this method, the lamination can be performed by peeling away the film from the support and then by layering a slip sheet such as a fluororesin film on the fiber-resin composite (a). In either case, it is important that the slip sheet be able to be peeled away from the resin layer (b) on which a metal plating layer is to be formed and that the slip sheet be so flat and smooth as not to cause such irregularities that formation of fine wires is prevented. Further, after the lamination has been completed by thermocompression bonding according to the method, a heat treatment may be performed with a hot-air oven for the purpose of improving the adhesivity of an interface between the resin layer (b) on which a metal plating layer is to be formed and the fiber-resin composite (a).

In any one of the methods described above, a resin layer (c) may be provided for the purpose of improving the adhesiveness between the fiber-resin composite (a) and the resin layer (b) on which a metal plating layer is to be formed. The resin layer (c) is provided by a method such as (i) a method for forming a resin layer (c) by applying a solution onto a resin layer (b) on which a metal plating layer is to be formed and then by drying the resin layer (b) or (ii) a method for inserting a film-like resin layer (c) between a fiber-resin composite (a) and a resin layer (b) on which a metal plating layer is to be formed.

The formation of a metal plating layer on the thus obtained laminate by electroless plating or the like makes it possible to obtain a laminate including a metal plating layer, a resin layer (b) on which a metal layer is to be formed, and a fiber-resin composite (a). In order to adjust the thickness of the metal plating layer, electrolytic plating may be performed in addition to the electroless plating. Further, in order to activate a surface of the resin layer (b) on which a metal plating layer is to be formed and improve the adhesivity between the metal plating layer and the resin layer (b) on which a metal plating layer is to be formed, it is very preferable that a process, such as a desmear process, in which an alkaline aqueous solution is used be performed before the electroless plating.

<2-3. Printed Wiring Board>

Examples of a printed wiring board obtained with use of a laminate according to the present embodiment include a single- or double-sided printed wiring board obtained by forming wires on the laminate according to the present embodiment. Further, the use of the single- or double-sided printed wiring board as a core substrate makes it possible to obtain a built-up wiring board. Furthermore, the use of the laminate of the present invention as a built-up material makes it possible to obtain a built-up wiring board. The laminate of the present invention excels in fine wiring formability, and therefore can be suitably applied to other various high-density printed wiring boards.

The following shows an example of how a single- or double-sided printed wiring board is manufactured with use of a laminate of the present invention including a resin layer (b) on which a metal plating layer is to be formed and a C-staged fiber-resin composite (a).

(1) Forming a Via Hole in the Laminate as Need

A via hole can be formed by using a publicly-known drill machine, dry plasma apparatus, carbon dioxide gas laser, UV laser, excimer laser, or the like. A UV-YAG laser or an excimer laser is suitably used for forming a via hole having a small diameter (especially not more than 50 μm, or preferably not more than 30 μm). Further, a UV-YAG laser or an excimer laser is preferred because of its capability to form a via hole having a good shape. It goes without saying that panel plating may be performed by electroless plating after the formation of a through hole by a drill machine. Further, after the hole-making process, it is also possible that the laminate is subjected to a desmear process by using a publicly-known technique such as a wet process in which permanganate is used or dry desmear (e.g., plasma).

(2) Subjecting the Laminate to Electroless Plating

Examples of the type of electroless plating include electroless copper plating, electroless nickel plating, electroless gold plating, electroless silver plating, and electroless tin plating. However, from an industrial point of view and in terms of electrical characteristics such as migration resistance, electroless copper plating and electroless nickel plating are preferred, or electroless copper plating is preferred in particular.

(3) Forming a Plating Resist

The photosensitive plating resist can be made of a publicly-known material that is widely commercially available. According to a method according to the present embodiment for manufacturing a printed wiring board, it is preferable that a photosensitive plating resist having a resolution pitch of not more than 50 μm be used so that finer wires can be formed. Note that a printed wiring board of the present invention may contain both a circuit having a wiring pitch of not more than 50 μm and a circuit having a wiring pitch of not less than 50 μm.

(4) Performing Pattern Plating by Electrolytic Copper Plating

That portion of the laminate on which no resist has been formed is subjected to electrolytic copper pattern plating by applying a large number of publicly-known methods. Specific examples of such electrolytic copper pattern plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(5) Peeling Away the Resist

The resist can be peeled away by appropriately using a material suitable for peeling the resist thus used, and the material is not particularly limited. Examples of the material include an aqueous solution of sodium hydroxide and an aqueous solution of potassium hydroxide.

(6) Forming Wires by Quick-Etching the Electroless Plating Layer

The quick etching can be performed with use of a publicly-known quick etchant. Examples of such a quick etchant include a sulfuric acid/hydrogen peroxide etchant, an ammonium persulfate etchant, a sodium persulfate etchant, a diluted ferric chloride etchant, and a diluted cupric chloride etchant.

The method is a so-called semi-additive method that is applied to formation of fine wires, and the semi-additive method can be suitably used for the laminate of the present embodiment. Meanwhile, since the laminate of the present embodiment is such that plated copper can be formed firmly on a flat and smooth surface, there will be no copper remaining in the irregularities of the resin after etching. This makes it possible that a subtractive method of forming wires by removing unnecessary copper by etching after having formed a resist is applied to the laminate of the present embodiment. However, while the subtractive method has an advantage of having a fewer steps, the subtractive method has a problem such as a defect caused in the shape of wires due to side etching. Therefore, the subtractive method or the semi-additive method may be appropriately selected in consideration of the pitch of wires to be formed, productivity, cost, and the like.

It is possible to manufacture a built-up printed wiring board by using, as a core substrate, the printed wiring board thus manufactured. In this case, fine wires can be formed on the core substrate per se. This makes it possible to manufacture a higher-density built-up wiring board.

The following shows an example of how a built-up printed wiring board is manufactured by using, as a built-up material, a laminate of the present invention including a resin layer (b) on which a metal plating layer is to be formed and (a) a B-staged fiber-resin composite (a).

(A) Laminating the Laminate on a Core Substrate

A slip sheet, the laminate, a core substrate on which wires have been formed are laminated in this order so that the core substrate faces the fiber-resin composite (a). In this step, it is important that a space between wiring patterns formed on the core substrate be sufficiently filled, and it is necessary that a thermosetting component of the fiber-resin composite (a) that is used for the laminate of the present embodiment be in a B stage. The lamination can be performed by various thermocompression bonding methods such as heat pressing, vacuum pressing, lamination (heat lamination), vacuum lamination, heat roller lamination, and vacuum heat roller lamination. Among these methods, processing under vacuum, i.e., vacuum pressing, vacuum lamination, or vacuum heat roller lamination is preferred because a space between circuits can be more satisfactorily filled without void. For the purpose of allowing the thermosetting component of the fiber-resin composite (a) to be cured to be in a C stage, drying by heating can be performed with a hot-air oven or the like after the lamination has been completed.

Note that the C stage may be attained at any stage in process of manufacturing the built-up wiring board.

(B) Forming a Via Hole in the Laminate

A publicly-known drill machine, dry plasma apparatus, carbon dioxide gas laser, UV laser, excimer laser, or the like can be used. A UV-YAG laser or an excimer laser is suitably used for forming a via hole having a small diameter (especially not more than 50 μm, or preferably not more than 30 μm). Further, a UV-YAG laser or an excimer laser is preferred because of its capability to form a via hole having a good shape. It goes without saying that panel plating may be performed by electroless plating after the formation of a through hole by a drill machine. Further, after the hole-making process, it is also possible that the laminate is subjected to a desmear process by using a publicly-known technique such as a wet process in which permanganate is used or dry desmear (e.g., plasma).

(C) Subjecting the Laminate to Electroless Plating

Examples of the type of electroless plating include electroless copper plating, electroless nickel plating, electroless gold plating, electroless silver plating, and electroless tin plating. However, from an industrial point of view and in terms of electrical characteristics such as migration resistance, electroless copper plating and electroless nickel plating are preferred, or electroless copper plating is preferred in particular.

(D) Forming a Plating Resist

The photosensitive plating resist can be made of a publicly-known material that is widely commercially available. According to a method according to the present embodiment for manufacturing a printed wiring board, it is preferable that a photosensitive plating resist having a resolution pitch of not more than 50 μm be used so that finer wires can be formed. Note that a printed wiring board of the present invention may contain both a circuit having a wiring pitch of not more than 50 μm and a circuit having a wiring pitch of not less than 50 μm.

(E) Performing Pattern Plating by Electrolytic Copper Plating

That portion of the laminate on which no resist has been formed is subjected to electrolytic copper pattern plating by applying a large number of publicly-known methods. Specific examples of such electrolytic copper pattern plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(F) Peeling Away the Resist

The resist can be peeled away by appropriately using a material suitable for peeling the resist thus used, and the material is not particularly limited. Examples of the material include an aqueous solution of sodium hydroxide and an aqueous solution of potassium hydroxide.

(G) Forming Wires by Quick-Etching the Electroless Plating Layer

The quick etching can be performed with use of a publicly-known quick etchant. Examples of such a quick etchant include a sulfuric acid/hydrogen peroxide etchant, an ammonium persulfate etchant, a sodium persulfate etchant, a diluted ferric chloride etchant, and a diluted cupric chloride etchant.

Then, a built-up wiring board having a desired number of layers can be obtained by further laminating a laminate of the present embodiment on an outermost surface of the built-up wiring board thus obtained and then by forming wires according to the aforementioned steps (B) to (G).

Further, it is possible to preferably apply such a technique that, while a laminate including a resin layer (b) on which a metal plating layer is to be formed and a fiber-resin composite (a) is obtained by sequentially laminating a slip sheet, a film-like resin layer (b) on which a metal plating layer is to be formed, a B-staged fiber-resin composite (a), and a core substrate on which wires have been formed, a built-up wiring board, including a resin layer (b) on which a metal plating layer is to be formed and a fiber-resin composite (a), on which no wires have been formed is obtained.

### Examples

The invention of the present embodiment will be described more in detail in accordance with Examples. However, the present invention is not limited to these. A person skilled in the art can make various changes, modifications, and alterations within the scope of the present invention. Note that such properties of laminates of Examples and Comparative Examples as adhesive properties with respect to electroless plated copper, surface roughness Ra, and wiring formability were evaluated or calculated in the following manner.

[Evaluation of Adhesive Properties]

A surface of the resin layer, on which a metal plating layer is to be formed, of the laminate thus obtained was subjected to desmear and electroless copper plating under conditions shown in Tables 1 and 2. Furthermore, electrolytic copper plating was performed so that a total copper thickness of 18 μm was attained.

The adhesive strength of a sample obtained as described above was measured in accordance with a method described in “Examples of Embodiment 1”.

[Measurement of Surface Roughness Ra]

The electroless plated copper layer of the same sample as used above in the evaluation of adhesive strength was removed by etching, and the surface roughness of the exposed surface was measured. The measurement was carried out in accordance with a method described in “Examples of Embodiment 1”.

[Wiring Formability]

The same sample as used above in the evaluation of adhesive strength was used. The evaluation was carried out in accordance with a method described in “Examples of Embodiment 1”.

### Example of how a Polyimide Resin is Synthesized 3

37 g (0.045 mol) of KF-8010 manufactured by Shin-Etsu Chemical Co., Ltd., 21 g (0.105 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 3 was obtained.

### Example of how a Solution for Forming a Resin Layer (b) on which a Metal Plating Layer is to be Formed is Prepared 1

Polyimide Resin 3 was dissolved in dioxolan, with the result that Solution (A2) for forming a resin layer (b) on which a metal plating layer is to be formed was obtained with a solid content concentration of 5 wt %.

### Example of how a Solution for Forming a Resin Layer (b) on which a Metal Plating Layer is to be Formed is Prepared 2

Polyimide Resin 3 was dissolved in dioxolan, with the result that Solution (B2) for forming a resin layer (b) on which a metal plating layer is to be formed was obtained with a solid content concentration of 20 wt %.

### Example of how a Solution for Forming a Resin Layer (b) on which a Metal Plating Layer is to be Formed is Prepared 3

32.1 g of YX4000H (i.e., a biphenyl epoxy resin manufactured by Japan Epoxy Resin Co., Ltd.), 17.9 g of bis[4-(3-aminophenoxy)phenyl]sulfone (i.e., a diamine manufactured by Wakayama Seika Kogyo Co., Ltd.), 0.2 g of 2,4-diamino-6-[2′-undecylimidazolyl-(1′)]-ethyl-s-triazine (i.e., an epoxy curing agent manufactured by Shikoku Chemicals Co., Ltd.) were dissolved in dioxolan, with the result that Epoxy Resin Composition Solution (C2) was obtained with a solid content concentration of 5 wt %. 90 g of Solution (A2) and 10 g of Solution (C2) were mixed, with the result that Solution (D2) for forming a resin layer (b) on which a metal plating layer is to be formed was obtained.

### Example of how a Resin Solution for a Fiber-Resin Composite (a) is Prepared 1

90 g of 2,2-bis(4-cyanatephenyl)propane and 10 g of bis(4-maleimidephenyl)methane were brought into a preparatory reaction with each other at 150° C. for 100 minutes, and the resulting product was dissolved in a mixed solvent of methyl ethyl ketone and DMF. Furthermore, 1.8 parts of zinc octylate were added to the mixture, and the resulting mixture was stirred to combine. This resulted in Solution (E2) that is used for a fiber-resin composite (a).

### Example of how a Resin Solution for a Resin Layer (c) is Prepared

41 g (0.143 mol) of 1,3-bis(3-aminophenoxy)benzene, 1.6 g (0.007 mol) of 3,3′-dihydroxy-4,4′-diaminobiphenyl, and DMF were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 180 minutes with a vacuum oven. As a result, Polyimide Resin 4 was obtained. Polyimide Resin 4 was dissolved in dioxolan, with the result that Polyimide Resin Solution (F2) was obtained with a solid content concentration of 20 wt %. Meanwhile, 32.1 g of YX4000H (i.e., a biphenyl epoxy resin manufactured by Japan Epoxy Resin Co., Ltd.), 17.9 g of bis[4-(3-aminophenoxy)phenyl]sulfone (i.e., a diamine manufactured by Wakayama Seika Kogyo Co., Ltd.), 0.2 g of 2,4-diamino-6-[2′-undecylimidazolyl-(1′)]-ethyl-s-triazine (i.e., an epoxy curing agent manufactured by Shikoku Chemicals Co., Ltd.) were dissolved in dioxolan, with the result that Epoxy Resin Composition Solution (G2) was obtained with a solid content concentration of 50 wt %. 20 g of Solution (F2) and 8 g of Solution (G2) were mixed, with the result that Solution (H2) that is used for a resin layer (c) was obtained.

### Example 7

Solution (E2) that is used for a fiber-resin composite (a) was applied to glass woven fabric having a thickness of 100 μm, and the glass woven fabric was impregnated with Solution (E2). Thereafter, the glass woven fabric was dried at a temperature of 160° C., and then was further dried at 170° C. for 90 minutes, with the result that a C-staged fiber-resin composite (a) was obtained with a resin content of 45 wt %. Solution (A2) for forming a resin layer (b) on which a metal plating layer is to be formed was applied onto one surface of the fiber-resin composite (a) by a spin coat method. Thereafter, the fiber-resin composite (a) was further dried at temperatures of 60° C. and 150° C., with the result that a laminate including a 5-μm-thick resin layer (b) on which a metal plating layer is to be formed and a C-staged fiber-resin composite (a) was obtained. The laminate thus obtained was evaluated in accordance with procedures for evaluating various evaluation items. The evaluation results are shown in Table 5.

### Example 8

Resin Solution (E2) that is used for a fiber-resin composite (a) was applied to glass woven fabric having a thickness of 100 μm, and the glass woven fabric was impregnated with Resin Solution (E2). Thereafter, the glass woven fabric was dried at a temperature of 160° C., with the result that a B-staged fiber-resin composite (a) was obtained.

Meanwhile, Solution (A2) for forming a resin layer (b) on which a metal plating layer is to be formed was applied onto a surface of a support film (marketed as “Cellapeel HP”; manufactured by Toyo Metallizing Co., Ltd.) by a casting method. Thereafter, the support film was dried by heating at 60° C. with a hot-air oven, with the result that a 2-μm-thick film-like resin layer (b) on which a metal plating layer is to be formed was obtained with a support attached thereto. Such film-like resin layers (b) were layered on both surfaces of the fiber-resin composite (a) with their respective supports attached to the resin layers (b), and then were laminated on the fiber-resin composite (a) at 170° C. under 1 MPa for 6 minutes by vacuum pressing. Note that the lamination was performed so that the resin layer (b) on which a metal plating layer is to be formed made contact with the fiber-resin composite (a). Thereafter, the supports were peeled away, and the resulting product was dried at 170° C. for 90 minutes, with the result that a laminate including a resin layer (b) on which a metal plating layer is to be formed, a C-staged fiber-resin composite (a), and a resin layer (b) on which a metal plating layer is to be formed was obtained. The laminate thus obtained was evaluated in accordance with procedures for evaluating various evaluation items. The evaluation results are shown in Table 5.

### Example 9

Solution (B2) for forming a resin layer (b) on which a metal plating layer is to be formed was used, with the result that a 25-μm-thick film-like resin layer (b) on which a metal plating layer is to be formed was obtained with a support attached thereto. A laminate was obtained in the same manner as in Example 8 except that such a resin layer (b) was used. The laminate thus obtained was evaluated in accordance with procedures for evaluating various evaluation items. The evaluation results are shown in Table 5.

### Example 10

A laminate was obtained in the same manner as in Example 8 except that Solution (D2) for forming a resin layer (b) on which a metal plating layer is to be formed was used. The laminate thus obtained was evaluated in accordance with procedures for evaluating various evaluation items. The evaluation results are shown in Table 5.

### Example 11

Resin Solution (E2) that is used for a fiber-resin composite (a) was applied to glass woven fabric having a thickness of 100 μm, and the glass woven fabric was impregnated with Resin Solution (E2). Thereafter, the glass woven fabric was dried at a temperature of 160° C., and then was further dried at 170° C. for 90 minutes, with the result that a C-staged fiber-resin composite (a) was obtained with a resin content of 45 wt %.

Meanwhile, Solution (A2) for forming a resin layer (b) on which a metal plating layer is to be formed was applied onto a surface of a support film (marketed as “Cellapeel HP”; manufactured by Toyo Metallizing Co., Ltd.) by a casting method. Thereafter, the support film was dried by heating at 60° C. with a hot-air oven, with the result that a 2-μm-thick film-like resin layer (b) on which a metal plating layer is to be formed was obtained with a support attached thereto. Further, Resin Solution (H2) that is used for a resin layer (c) was applied by a casting method onto the resin layer (b) on which a metal plating layer is to be formed. Thereafter, the resin layer (b) was dried at temperatures of 60° C., 80° C., 100° C., 120° C., 140° C., and 150° C., with the result that a film including a support, a 2-μm-thick resin layer on which a metal plating layer is to be formed, and a 40-μm-thick resin layer (c) was obtained.

The film thus obtained was layered on one surface of the fiber-resin composite (a) with the support attached to the film, and then was laminated on the fiber-resin composite (a) at 170° C. under 1 MPa for 6 minutes by vacuum pressing. Note that the lamination was performed so that the resin layer (c) made contact with the fiber-resin composite (a). Thereafter, the support was peeled away, and the resulting product was further dried at 170° C. for 60 minutes, with the result that a laminate including a resin layer (b) on which a metal plating layer is to be formed, a resin layer (c), and a C-staged fiber-resin composite (a) was obtained. The laminate thus obtained was evaluated in accordance with procedures for evaluating various evaluation items. The evaluation results are shown in Table 5.

### Example 12

Resin Solution (E2) that is used for a fiber-resin composite (a) was applied to glass woven fabric having a thickness of 100 μm, and the glass woven fabric was impregnated with Resin Solution (E2). Thereafter, the glass woven fabric was dried at a temperature of 160° C., and then was further dried at 170° C. for 90 minutes, with the result that a C-staged fiber-resin composite (a) was obtained with a resin content of 45 wt %.

Meanwhile, Solution (A2) for forming a resin layer (b) on which a metal plating layer is to be formed was applied onto a surface of a 25-μm-thick non-thermoplastic polyimide film (marketed as “Apical NPI”; manufactured by Kaneka Corporation) by a casting method. Thereafter, the film was dried by heating at 60° C. with a hot-air oven, with the result that a film including a 2-μm-thick resin layer (b) on which a metal plating layer is to be formed and a non-thermoplastic polyimide was obtained. Resin Solution (H2) that is used for a resin layer (c) was further applied by a casting method onto that polyimide film of the film which faces away from the resin layer (b) on which a metal plating layer is to be formed. Thereafter, the film was dried at temperatures of 60° C., 80° C., 100° C., 120° C., 140° C., and 150° C., with the result that a film including a support, a 2-μm-thick resin layer (b) on which a metal plating layer is to be formed, a non-thermoplastic polyimide, and a 40-μm-thick resin layer (c) was obtained. The film thus obtained was layered on one surface of the fiber-resin composite (a) with the support attached to the film, and then was laminated on the fiber-resin composite (a) at 170° C. under 1 MPa for 6 minutes by vacuum pressing. Note that the lamination was performed so that the resin layer (c) made contact with the fiber-resin composite (a). Thereafter, the support was peeled away, and the resulting product was further dried at 170° C. for 60 minutes, with the result that a laminate including a resin layer (b) on which a metal plating layer is to be formed, a non-thermoplastic polyimide, a resin layer (c), and a C-staged fiber-resin composite (a) was obtained. The laminate thus obtained was evaluated in accordance with procedures for evaluating various evaluation items. The evaluation results are shown in Table 5.

### Example 13

Resin Solution (E2) that is used for a fiber-resin composite (a) was applied to glass woven fabric having a thickness of 50 μm, and the glass woven fabric was impregnated with Resin Solution (E2). Thereafter, the glass woven fabric was dried at a temperature of 160° C., with the result that a B-staged fiber-resin composite (a) was obtained with a resin content of 45 wt %. Solution (A2) for forming a resin layer (b) on which a metal plating layer is to be formed was applied onto one surface of the fiber-resin composite (a) by a spin coat method. Thereafter, the fiber-resin composite (a) was further dried at temperatures of 60° C. and 150° C., with the result that a laminate including a resin layer (b) on which a metal plating layer is to be formed and a B-staged fiber-resin composite (a) was obtained.

A copper-clad laminate (CCL-HL950K Type SK; manufactured by Mitsubishi Gas Chemical Company, Inc.) was processed, layered on that surface of a wiring board on which wires having a height of 18 μm and a line-and-space (L/S) of 50 μm and 50 μm had been formed, and then heated at a temperature of 170° C. under a pressure of 1 MPa for 90 minutes under vacuum. Thereafter, the resulting product was dried at 170° C. for 90 minutes with a hot-air oven, with the result that a laminate including a resin layer (b) on which a metal plating layer is to be formed, a fiber-resin composite (a), and a wiring board was obtained. Note that a fluororesin film (AFLEX; manufactured by Asahi Glass Co., Ltd.) was used as a slip sheet at the time of the heating under pressure.

The laminate thus obtained was evaluated in accordance with procedures for evaluating various evaluation items. The evaluation results are shown in Table 5.

### Example 14

Resin Solution (E2) that is used for a fiber-resin composite (a) was applied to glass woven fabric having a thickness of 50 μm, and the glass woven fabric was impregnated with Resin Solution (E2). Thereafter, the glass woven fabric was dried at a temperature of 160° C., with the result that a B-staged fiber-resin composite (a) was obtained with a resin content of 45 wt %.

Meanwhile, Solution (A2) for forming a resin layer (b) on which a metal plating layer is to be formed was applied onto a surface of a support film (marketed as “Cellapeel HP”; manufactured by Toyo Metallizing Co., Ltd.) by a casting method. Thereafter, the support film was dried at a temperature of 60° C. with a hot-air oven, with the result that a 2-μm-thick film-like resin layer (b) on which a metal plating layer is to be formed was obtained with a support attached thereto. The film with a support, the fiber-resin composite (a), and a copper-clad laminate (CCL-HL950K Type SK; manufactured by Mitsubishi Gas Chemical Company, Inc.) was processed. The processed product was layered on a wiring board having wires formed so as to have a height of 18 μm and a line-and-space (L/S) of 50 μm and 50 μm, and then was laminated on the wiring board at 170° C. under 1 MPa for 6 minutes by vacuum pressing. Thereafter, the support was peeled away, and the resulting product was further dried at 170° C. for 90 minutes with a hot-air oven, with the result that a laminate including a resin layer (b) on which a metal plating layer is to be formed, a fiber-resin composite (a), and a wiring board was obtained.

The laminate thus obtained was evaluated in accordance with procedures for evaluating various evaluation items. The evaluation results are shown in Table 5.

### Comparative Example 3

Resin Solution (E2) that is used for a fiber-resin composite (a) was applied to glass woven fabric having a thickness of 50 μm, and the glass woven fabric was impregnated with Resin Solution (E2). Thereafter, the glass woven fabric was dried at a temperature of 160° C., with the result that a B-staged fiber-resin composite (a) was obtained with a resin content of 45 wt %. A laminate was obtained in the same manner as in Example 8 except that lamination was performed such that the fiber-resin composite (a) was sandwiched between two pieces of electrolytic copper foil having a thickness of 18 μm. The laminate thus obtained was evaluated as described below. With regard to adhesive strength, the adhesive strength under normal conditions and adhesive strength after PCT between the electrolytic copper foil and the fiber-resin composite (a) were evaluated. With regard to surface roughness Ra, the surface roughness Ra of that surface of the fiber-resin composite (a) which had been exposed by removing the electrolytic copper foil by etching was evaluated. Further, the wiring formability was evaluated by, after having formed a resist on the electrolytic copper foil, forming wires by etching according to a subtractive method. The evaluation results are shown in Table 6. As evidenced by Table 6, the copper layer formed by laminating the electrolytic copper foil exhibits good adhesiveness between the electrolytic copper foil and the fiber-resin composite (a). However, the electrolytic copper foil causes great irregularities to be formed on a surface of the fiber-resin composite (a). Therefore, in cases where wires are formed by a subtractive method, there occur wire tilt and wire collapse. This makes it impossible to satisfactorily form fine wires.

TABLE 5

| | | | | Example | Example | Example | Example | Example |
|---|---|---|---|---|---|---|---|---|
| | Example 7 | Example 8 | Example 9 | 10 | 11 | 12 | 13 | 14 |
| Solution for forming a resin layer (b) | (A2) | (A2) | (B2) | (D2) | (A2) | (A2) | (A2) | (A2) |
| Resin solution that is used for a | (E2) | (E2) | (E2) | (E2) | (E2) | (E2) | (E2) | (E2) |
| fiber-resin composite (a) | | | | | | | | |
| Solution for forming a resin layer (c) | — | — | — | — | (H2) | (H2) | — | — |
| Arrangement of the laminate | (b)/(a) | (b)/(a)/ | (b)/(a)/ | (b)/(a)/(b) | (b)/(c)/ | (b)/ | (b)/(a)/ | (b)/(a)/ |
| | | (b) | (b) | | (a) | Apical | Wiring | Wiring |
| | | | | | | NPI/(c)/ | Board | Board |
| | | | | | | (a) | | |
| Adhesive strength under normal | 11 N/cm | 11 N/cm | 10 N/cm | 9 N/cm | 12 N/cm | 10 N/cm | 10 N/cm | 10 N/cm |
| conditions | | | | | | | | |
| Adhesive strength after PCT | 8 N/cm | 8 N/cm | 8 N/cm | 5 N/cm | 9 N/cm | 6 N/cm | 7 N/cm | 7 N/cm |
| Surface Roughness Ra | 0.02 μm | 0.01 μm | 0.02 μm | 0.01 μm | 0.01 μm | 0.01 μm | 0.01 μm | 0.01 μm |
| Fine wiring formability L/S = 10 μm/ | ∘ | ∘ | ∘ | ∘ | ∘ | ∘ | ∘ | ∘ |
| 10 μm | | | | | | | | |

TABLE 6

| | Example 3 |
|---|---|
| Solution for forming a resin layer (b) | — |
| Resin solution that is used for a | (E2) |
| fiber-resin composite (a) | |
| Solution for forming a resin layer (c) | — |
| Arrangement of the laminate | Copper Foil/(a)/ |
| | Copper Foil |
| Adhesive strength under normal conditions | 14 N/cm |
| Adhesive strength after PCT | 10 N/cm |
| Surface Roughness Ra | 0.89 μm |
| Fine wiring formability | x |
| L/S = 10 μm/10 μm | |

### Embodiment 3

<3-1. Arrangement of an Electroless Plating Material of the Present Embodiment>

An electroless plating material of the present embodiment is an electroless plating material having a surface that is to be subjected to electroless plating, and is characterized by including a composite of a fiber and a polyimide resin having a siloxane structure. According to a conventionally-used substrate of this sort, used for a printed wiring board, which is made of a composite of a fiber such as glass and a resin such as an epoxy resin, it is usual that electroless plating is performed after having formed irregularities on a surface of the substrate by subjecting the surface to some sort of processing. That is, according to a conventionally-known substrate obtained with use of a resin-fiber composite, electroless plating cannot be firmly formed directly on a flat and smooth surface. The inventors found that electroless plating can be caused to adhere firmly even to a flat and smooth surface by selecting a resin that is to be compounded in such a substrate as obtained with use of a fiber-resin composite. It is first found by the inventors that electroless plating can be formed firmly even on a flat and smooth surface of a material obtained with use of a composite formed from a fiber and a polyimide resin having a siloxane structure.

The electroless plating material of the present embodiment may be arranged in any manner as long as it includes a composite of a fiber and a polyimide resin having a siloxane structure (such a composite being appropriately referred to as “fiber-resin composite” in the present embodiment). For example, if necessary, the electroless plating material of the present embodiment may contain a thermosetting component in addition to the fiber-resin composite. In cases where the electroless plating material of the present embodiment contains a thermosetting component, the electroless plating material can also contain a composite of the thermosetting component and a fiber. This makes it possible to reduce the coefficient of thermal expansion. In cases where the electroless plating material of the present embodiment contains a thermosetting component, the electroless plating material may be in a B stage or in a C stage, and either one of the stages can be appropriately selected in accordance with the applications of the electroless plating material. Further, the electroless plating material of the present embodiment may contain various additives such as fillers. In order to exhibit necessary properties, the electroless plating material of the present embodiment can be arranged in any manner that can be imagined by a person skilled in the art. Furthermore, the electroless plating material of the present embodiment may be a material obtained by forming another resin layer on an electroless plating material formed from a resin composition containing a composite of a fiber and a polyimide resin having a siloxane structure.

It is preferable that the electroless plating material of the present embodiment be either (A) a material obtained by impregnating a fiber with a resin composition solution containing (i) a polyimide resin having a siloxane structure and (ii) a solvent, or (B) a material obtained by impregnating a fiber with a resin composition solution containing (a) polyamic acid having a siloxane structure and (b) a solvent. The manufacturing method has such advantages that a resin composition can be formed so as to be flat and smooth and that a good composite can be formed while preventing bubbles from being generated. It is necessary that the resin composition solution with which the fiber is impregnated contain either a polyimide resin having a siloxane structure, or polyamic acid serving as a precursor of the polyimide resin. The resin composition solution with which the fiber is impregnated may be mixed in advance with an additive such as a thermosetting component or a filler. Further, in cases where polyamic acid is contained, it is preferable, in terms of heat resistance and adhesive properties with respect to an electroless plating film, that the polyamic acid be finally converted into a polyimide resin by heat imidization or chemical imidization.

(3-1-1. Fiber that is Used for the Electroless Plating Material of the Present Embodiment)

The fiber that is used for the electroless plating material of the present embodiment is not particularly limited, and various inorganic fibers and organic fibers can be used as such. However, in consideration of the application of the electroless plating material to a printed wiring board, it is preferable, in terms of reducing the coefficient of thermal expansion, that the fiber be made from at least one type selected from the group consisting of paper, glass, polyimide, aramid, polyarylate, and tetrafluoroethylene. These fibers can be used in various forms in accordance with uses such as woven fabric, unwoven fabric, roving, chopped strand mats, and surfacing mats.

(3-1-2. Polyimide Resin, Having a Siloxane Structure, which is Used for the Electroless Plating Material of the Present Embodiment)

In terms of adhesive properties with respect to an electroless plating film, availability of raw materials, and the like, it is preferable that the polyimide resin, having a siloxane structure, which is used for the electroless plating material of the present embodiment be a polyimide resin made from an acid dianhydride component and a diamine component containing a diamine represented by general formula (7):

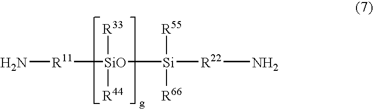

(where g is an integer of 1 or more; R¹¹ and R²² are each independently an alkylene group or a phenylene group; and R³³ to R⁶⁶ are each independently an alkyl group, a phenyl group, or a phenoxy group.)

Since the present invention contains the polyimide resin having a siloxane structure, the present invention exhibits good adhesive properties even with respect to a flat and smooth surface, and excels in fine wiring formability. Note that the “polyimide resin having a siloxane structure” of the present embodiment can be explained appropriately with the aid of the description of (1-1-2. Resin Layer) of Embodiment 1.

(3-1-3. Example of how the Electroless Plating Material of the Present Embodiment is Manufactured)

It is preferable that the polyimide resin, having a siloxane structure, which is used for the electroless plating material of the present embodiment be dissolved in a solvent so as to be used as a resin composition solution containing a polyimide resin. The solvent may be any solvent as long as it can dissolve a resin component. However, in terms of inhibiting bubbles from being generated under dry conditions and reducing the residual solvent, it is preferable that the solvent have a boiling point of not more than 230° C. Examples of the solvent include tetrahydrofuran (hereinafter abbreviated as “THF”; boiling point: 66° C.), 1,4-dioxane (hereinafter abbreviated as “dioxane”; boiling point: 103° C.), monogryme (boiling point: 84° C.), dioxolane (boiling point: 76° C.), toluene (boiling point: 110° C.), tetrahydropyrane (boiling point: 88° C.), dimethoxyethane (boiling point 85° C.), N,N-dimethylformamide (boiling point: 153° C.), and N-methyl-2-pyrrolidone (boiling point: 205° C.). Any other solvents that boil at not more than 230° C. can be preferably used. These solvents may be used separately. Alternatively, a combination of two or more of them can be used. The term “dissolve” used herein means that the resin component is dissolved by not less than 1 wt % with respect to the solvent.

Further, for example, a solution obtained by thermally or chemically imidizing the polyamic acid solution may be used. Furthermore, a fiber-resin composite can be obtained with use of the polyamic acid solution. However, in this case, it is preferable that the imidization be substantially completed by performing an imidization process by a thermal or chemical method.

A resin composition solution containing a polyimide resin or a resin composition solution containing polyamic acid is obtained by thus dissolving, in an appropriated solvent, a resin composition containing a polyimide resin or polyamic acid as described above. A fiber-resin composite can be obtained by impregnating a fiber with the solution thus obtained and then by appropriately drying the fiber as needed. The drying condition is not particularly limited. However, in cases where a polyamide solution is used, it is preferable that the imidization be performed thermally at the same time as the drying. In this case, in order to perform the imidization substantially completely, it is preferable that the drying be performed at a final drying temperature of 100° C. to 400° C. for a period of 10 seconds to 10 hours, or more preferably at a final drying temperature of 150° C. to 350° C. for a period of 10 seconds to 3 hours.

In cases where the resin composition is formed solely from a polyimide resin having a siloxane structure, the drying may be performed for a shorter time at a lower temperature or for a longer time at a higher temperature for the purpose of adjusting the residual solvent.

Further, in cases where the resin composition contains a thermosetting component, the drying can be performed under such conditions that a B stage is maintained, or can be preformed until a C stage is attained. The drying can be performed by heating with an oven such as a hot-air oven. Alternatively, the drying can be performed by heating under pressure with an apparatus such as a vacuum press. However, in cases where the drying is performed by heating under pressure with an apparatus such as a vacuum press, it is necessary that a resin film or the like having a sufficiently flat and smooth surface be used as a slip sheet so that the composite obtains a sufficiently flat and smooth surface.

A material obtained by impregnating a fiber with a resin composition solution containing (i) a polyimide resin having a siloxane structure and (ii) a solvent or a material obtained by impregnating a fiber with a resin composition solution containing (a) polyamic acid having a siloxane structure and (b) a solvent makes it possible that a good fiber-resin composite having a flat and smooth surface is formed while preventing bubbles from being generated.

It is preferable that the surface roughness of the electroless plating material of the present embodiment be less than 0.5 μm in terms of arithmetic mean roughness Ra as measured at a cutoff value of 0.002 mm. Especially in cases where an electroless plating material satisfies this condition, the electroless plating material exhibits good fine wiring formability when used for a printed wiring board.

In order to obtain an electroless plating material having properties well balanced among heat resistance, adhesive properties, and the like, it is preferable that a polyimide resin, contained in a resin composition, which has a siloxane structure be in a range of 10 wt % to 100 wt % with respect to the whole resin.

Further, in cases where a thermosetting component is blended into a polyimide resin having a siloxane structure, it is preferable, in terms of low-thermal expansivity and resin flow properties, that the blending quantity of the thermosetting component be in a range of 5 wt % to 90 wt % with respect to the whole resin.

The electroless plating material of the present embodiment is not particularly limited in terms of thickness. However, in consideration of its application to a high-density printed wiring board, it is preferable that the electroless plating material have a small thickness. Specifically, it is preferable that the electroless plating material have a thickness of not more than 1 mm.

As described above, the electroless plating material of the present embodiment may be in a B stage or in a C stage, and either one of the stages can be appropriately selected in accordance with the applications of the electroless plating material. Further, the electroless plating material of the present embodiment may be a material obtained by forming another resin layer on an electroless plating material. That is, on a resin layer, obtained as described above, which contains a fiber-resin composite, a resin layer, shaped for example into a sheet, which exhibits good adhesive properties with respect to both the fiber-resin composite and electroless plating are further laminated by vacuum pressing, so that an electroless plating material including another resin layer, a resin layer containing a fiber-resin composite, and another resin layer can be obtained.

<3-2. Laminate Obtained by Subjecting the Electroless Plating Material to Electroless Plating>

A laminate can be arranged by subjecting the electroless plating material according to the present embodiment to electroless plating. Examples of the electroless plating to which the electroless plating material according to the present embodiment can be subjected include electroless copper plating, electroless nickel plating, electroless gold plating, electroless silver plating, and electroless tin plating. From an industrial point of view and in terms of electrical characteristics such as migration resistance, electroless copper plating and electroless nickel plating are preferred, or electroless copper plating is preferred in particular. In cases where the electroless plating material of the present invention is subjected to electroless plating, various types of surface treatment such as a desmear process can be performed. The electroless plating film is not particularly limited in terms of thickness. However, in consideration of productivity and the like, it is preferable that the electroless plating film have a thickness of 1 nm to 50 μm.

<3-3. Printed Wiring Board>

Examples of a printed wiring board obtained with use of the electroless plating material of the present embodiment include a single- or double-sided printed wiring board obtained by forming wires on the electroless plating material of the present embodiment. For example, a single- or double-sided printed wiring board can be obtained by subjecting the electroless plating material of the present embodiment to electroless plating and then by forming wires on the electroless plating material by a semi-additive method or a subtractive method. Further, a built-up wiring board can be obtained by using the printed wiring board as a core substrate. Further, a built-up wiring board can be obtained by using the electroless plating material of the present embodiment as a built-up material. The electroless plating material of the present embodiment excels in fine wiring formability, and therefore can be suitably applied to other various high-density printed wiring boards.

The following shows an example of how a single- or double-sided printed wiring board is manufactured with use of an electroless plating material formed from a resin composition containing a composite of a fiber and a polyimide resin having a siloxane structure.

(1) Forming a Via Hole in the Electroless Plating Material of the Present Embodiment as Needed

A via hole can be formed by using a publicly-known drill machine, dry plasma apparatus, carbon dioxide gas laser, UV laser, excimer laser, or the like. A UV-YAG laser or an excimer laser is suitably used for forming a via hole having a small diameter (especially not more than 50 μm, or preferably not more than 30 μm). Further, a UV-YAG laser or an excimer laser is preferred because of its capability to form a via hole having a good shape. It goes without saying that panel plating may be performed by electroless plating after the formation of a through hole by a drill machine. Further, after the hole-making process, it is also possible that the electroless plating material is subjected to a desmear process by using a publicly-known technique such as a wet process in which permanganate is used or dry desmear (e.g., plasma).

(2) Subjecting the Electroless Plating Material to Electroless Plating

Examples of the type of electroless plating include electroless copper plating, electroless nickel plating, electroless gold plating, electroless silver plating, and electroless tin plating. However, from an industrial point of view and in terms of electrical characteristics such as migration resistance, electroless copper plating and electroless nickel plating are preferred, or electroless copper plating is preferred in particular.

(3) Forming a Plating Resist

The photosensitive plating resist can be made of a publicly-known material that is widely commercially available. According to a method according to the present embodiment for manufacturing a printed wiring board, it is preferable that a photosensitive plating resist having a resolution pitch of not more than 50 μm be used so that finer wires can be formed. Note that a printed wiring board of the present invention may contain both a circuit having a wiring pitch of not more than 50 μm and a circuit having a wiring pitch of not less than 50 μm.

(4) Performing Pattern Plating by Electrolytic Copper Plating

That portion of the laminate on which no resist has been formed is subjected to electrolytic copper pattern plating by applying a large number of publicly-known methods. Specific examples of such electrolytic copper pattern plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(5) Peeling Away the Resist

The resist can be peeled away by appropriately using a material suitable for peeling the resist thus used, and the material 1 is not particularly limited. Examples of the material include an aqueous solution of sodium hydroxide and an aqueous solution of potassium hydroxide.

(6) Forming Wires by Quick-Etching the Electroless Plating Layer

The quick etching can be performed with use of a publicly-known quick etchant. Examples of such a quick etchant include a sulfuric acid/hydrogen peroxide etchant, an ammonium persulfate etchant, a sodium persulfate etchant, a diluted ferric chloride etchant, and a diluted cupric chloride etchant.

The method is a so-called semi-additive method that is applied to formation of fine wires, and the semi-additive method can be suitably used for the electroless plating material of the present embodiment. Meanwhile, since the electroless plating material of the present embodiment is such that plated copper can be formed firmly on a flat and smooth surface, there will be no copper remaining in the irregularities of the resin after etching. This makes it possible that a subtractive method of forming wires by removing unnecessary copper by etching after having formed a resist is applied to the electroless plating material of the present embodiment. However, while the subtractive method has an advantage of having a fewer steps, the subtractive method has a problem such as a defect caused in the shape of wires due to side etching. Therefore, the subtractive method or the semi-additive method may be appropriately selected in consideration of the pitch of wires to be formed, productivity, cost, and the like.

It is possible to manufacture a built-up printed wiring board by using, as a core substrate, the printed wiring board thus manufactured. In this case, fine wires can be formed on the core substrate per se. This makes it possible to manufacture a higher-density built-up wiring board.

The following shows an example of how a built-up wiring board is manufactured by using, as a built-up material, an electroless plating material formed from a fiber-resin composite.

(A) Laminating the Electroless Plating Material and the Core Substrate

A slip sheet, a B-staged electroless plating material, a core substrate on which wires have been formed are laminated in this order so as to face one another. In this step, it is important that a space between wiring patterns formed on the core substrate be sufficiently filled, and it is preferably that the electroless plating material of the present embodiment be formed from a B-staged fiber-resin composite containing a thermosetting component. The lamination can be performed by various thermocompression bonding methods such as heat pressing, vacuum pressing, lamination (heat lamination), vacuum lamination, heat roller lamination, and vacuum heat roller lamination. Among these methods, processing under vacuum, i.e., vacuum pressing, vacuum lamination, or vacuum heat roller lamination is preferred because a space between circuits can be more satisfactorily filled without void. For the purpose of allowing the thermosetting component of the fiber-resin composite to be cured to be in a C stage, drying by heating can be performed with a hot-air oven or the like after the lamination has been completed.

(B) Forming a Via Hole in the Laminate

A publicly-known drill machine, dry plasma apparatus, carbon dioxide gas laser, UV laser, excimer laser, or the like can be used. A UV-YAG laser or an excimer laser is suitably used for forming a via hole having a small diameter (especially not more than 50 μm, or preferably not more than 30 μm). Further, a UV-YAG laser or an excimer laser is preferred because of its capability to form a via hole having a good shape. It goes without saying that panel plating may be performed by electroless plating after the formation of a through hole by a drill machine. Further, after the hole-making process, it is also possible that the laminate is subjected to a desmear process by using a publicly-known technique such as a wet process in which permanganate is used or dry desmear (e.g., plasma).

(C) Subjecting the Laminate to Electroless Plating

Examples of the type of electroless plating include electroless copper plating, electroless nickel plating, electroless gold plating, electroless silver plating, and electroless tin plating. However, from an industrial point of view and in terms of electrical characteristics such as migration resistance, electroless copper plating and electroless nickel plating are preferred, or electroless copper plating is preferred in particular.

(D) Forming a Plating Resist

The photosensitive plating resist can be made of a publicly-known material that is widely commercially available. According to a method according to the present embodiment for manufacturing a printed wiring board, it is preferable that a photosensitive plating resist having a resolution pitch of not more than 50 μm be used so that finer wires can be formed. Note that a printed wiring board of the present invention may contain both a circuit having a wiring pitch of not more than 50 μm and a circuit having a wiring pitch of not less than 50 μm.

(E) Performing Pattern Plating by Electrolytic Copper Plating

That portion of the laminate on which no resist has been formed is subjected to electrolytic copper pattern plating by applying a large number of publicly-known methods. Specific examples of such electrolytic copper pattern plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(F) Peeling Away the Resist

The resist can be peeled away by appropriately using a material suitable for peeling the resist thus used, and the material is not particularly limited. Examples of the material include an aqueous solution of sodium hydroxide and an aqueous solution of potassium hydroxide.

(G) Forming Wires by Quick-Etching the Electroless Plating Layer

The quick etching can be performed with use of a publicly-known quick etchant. Examples of such a quick etchant include a sulfuric acid/hydrogen peroxide etchant, an ammonium persulfate etchant, a sodium persulfate etchant, a diluted ferric chloride etchant, and a diluted cupric chloride etchant.

Then, a built-up wiring board having a desired number of layers can be obtained by further laminating a B-staged electroless plating material on an outermost surface of the built-up wiring board thus obtained and then by forming wires according to the aforementioned steps (B) to (G).

When the electroless plating material of the present embodiment is applied as a built-up material, excellent processability and fine wiring formability are both achieved. Further, since a fiber is contained, there is such an advantage that the coefficient of thermal expansion is reduced.

### Examples

The invention of the present embodiment will be described more in detail in accordance with Examples.

However, the present invention is not limited to these. A person skilled in the art can make various changes, modifications, and alterations within the scope of the present invention. Note that such properties of laminates of Examples and Comparative Examples as adhesive properties with respect to electroless plated copper, surface roughness Ra, and wiring formability were evaluated or calculated in the following manner.

[Evaluation of Adhesive Properties]

A surface of the electroless plating material thus obtained was subjected to desmear and electroless copper plating under conditions shown in Tables 1 and 2. Furthermore, electrolytic copper plating was performed so that a total copper thickness of 18 μm was attained.

The adhesive strength of a sample obtained as described above was measured in accordance with a method described in “Examples of Embodiment 1”.

[Measurement of Surface Roughness Ra]

The electroless plated copper layer of the same sample as used above in the evaluation of adhesive strength was removed by etching, and the surface roughness of the exposed surface was measured. The measurement was carried out in accordance with a method described in “Examples of Embodiment 1”.

[Wiring Formability]

The same sample as used above in the evaluation of adhesive strength was used. The evaluation was carried out in accordance with a method described in “Examples of Embodiment 1”.

### Example of how a Polyimide Resin is Synthesized 4

37 g (0.045 mol) of KF-8010 manufactured by Shin-Etsu Chemical Co., Ltd., 21 g (0.105 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for approximately one hour. As a result, DMF Solution 1 of Polyamic Acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 5 was obtained.

### Example of how a Polyimide Resin is Synthesized 5

62 g (0.075 mol) of KF8010 manufactured by Shin-Etsu Chemical Co., Ltd., 15 g (0.075 mol) of 4,4′-diaminodiphenylether, and DMF were poured into a glass flask having a capacity of 2000 ml, and then were stirred for dissolution. Then, 78 g (0.15 mol) of 4,4-(4,4′-isopropylidendiphenoxy)bisphthalic acid anhydride was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 6 was obtained.

### Example of how a Resin Composition Solution is Prepared 1

DMF Solution 1 of Polyamic Acid was diluted with DMF so that a solid content concentration of 25% was attained. As a result, Resin Composition Solution (a) was obtained.

### Example of how a Resin Composition Solution is Prepared 2

Polyimide Resin 5 was dissolved in dioxolan, with the result that Resin Composition Solution (b) was obtained with a solid content concentration of 25 wt %.

### Example of how a Resin Composition Solution is Prepared 3

Polyimide Resin 6 was dissolved in dioxolan, with the result that Resin Composition Solution (b) was obtained with a solid content concentration of 25 wt %.

### Example of how a Resin Composition Solution is Prepared 4

32.1 g of YX4000H (i.e., a biphenyl epoxy resin manufactured by Japan Epoxy Resin Co., Ltd.), 17.9 g of bis[4-(3-aminophenoxy)phenyl]sulfone (i.e., a diamine manufactured by Wakayama Seika Kogyo Co., Ltd.), 0.2 g of 2,4-diamino-6-[2′-undecylimidazolyl-(1′)]-ethyl-s-triazine (i.e., an epoxy curing agent manufactured by Shikoku Chemicals Co., Ltd.) were dissolved in dioxolan, with the result that Epoxy Resin Composition Solution (d) was obtained with a solid content concentration of 50 wt %. 140 g of Solution (b) and 30 g of Solution (d) were mixed, with the result that Resin Composition Solution (e) was obtained.

### Example 15

Glass woven fabric having a thickness of 40 μm was impregnated with Resin Composition Solution (a), and then was dried and imidized at 100° C. for 10 minutes, at 180° C. for 60 minutes, and at 250° C. for 10 minutes, with the result that an electroless plating material was obtained. The electroless plating material thus obtained was evaluated in accordance with procedures for evaluating various evaluation items. The evaluation results are shown in Table 7.

### Example 16

Glass woven fabric having a thickness of 40 μm was impregnated with Resin Composition Solution (b), and then was dried at 100° C. for 10 minutes and at 180° C. for 60 minutes, with the result that an electroless plating material was obtained. The electroless plating material thus obtained was evaluated in accordance with procedures for evaluating various evaluation items. The evaluation results are shown in Table 7.

### Example 17

Glass woven fabric having a thickness of 40 μm was impregnated with Resin Composition Solution (e), and then was dried at 100° C. for 10 minutes and at 180° C. for 60 minutes, with the result that a C-staged electroless plating material was obtained. The electroless plating material thus obtained was evaluated in accordance with procedures for evaluating various evaluation items. The evaluation results are shown in Table 7.

### Example 18

Glass woven fabric having a thickness of 40 μm was impregnated with Resin Composition Solution (c), and then was dried at 100° C. for 10 minutes and at 180° C. for 60 minutes, with the result that an electroless plating material was obtained. The electroless plating material thus obtained was evaluated in accordance with procedures for evaluating various evaluation items. The evaluation results are shown in Table 7.

### Example 19

An electroless plating material was obtained in the same manner as in Example 15 except that aramid unwoven fabric having a thickness of 50 μm was used instead of glass woven fabric having a thickness of 40 μm. The electroless plating material thus obtained was evaluated in accordance with procedures for evaluating various evaluation items. The evaluation results are shown in Table 7.

### Example 20

Glass woven fabric having a thickness of 40 μm was impregnated with Resin Composition Solution (e), and then was dried at 60° C. for 5 minutes, 100° C. for 5 minutes, and at 150° C. for 5 minutes, with the result that a B-staged electroless plating material was obtained. Meanwhile, such electroless plating materials were laminated on both sides of the printed wiring board obtained at the time of the evaluation of wiring formability in Example 1. The lamination was performed by vacuum pressing at 180° C. under 3 MPa for 60 minutes. At the time of the lamination, a resin film (AFLEX; manufactured by Asahi Glass Co., Ltd.) was used as a slip sheet. Thus obtained was a laminate including an electroless plating material, a double-sided wiring board, and an electroless plating material. Thereafter, the laminate thus obtained was evaluated in the same manner as in Example 1 in accordance with procedures for evaluating various evaluation items. The evaluation results are shown in Table 3. Note that the double-sided wiring board and the electroless plating materials adhered firmly to one another and that the double-sided wiring board had a wiring portion, having a line-and-space (L/S) of 10 μm/10 μm, which was satisfactorily embedded.

### Comparative Example 4

By using a copper-clad laminate obtained by laminating (i) a 50-μm-thick prepreg (ES-3306S; manufactured by Risho Kogyo Co., Ltd.) serving as a composite and (ii) a 9-μm-thick electrolytic copper foil, the strength of adhesiveness between the composite and the copper foil was measured. The surface nature of a resin surface exposed by etching out the copper foil was also evaluated. Thereafter, the wire formability with which wires having a line-and-space (L/S) of 10 μm/10 μm were formed by a subtractive method of performing etching after having formed a resist was evaluated. The evaluation results are shown in Table 8.

### Comparative Example 5

90 g of 2,2-bis(4-cyanatephenyl)propane and 10 g of bis(4-maleimidephenyl)methane were brought into a preparatory reaction at 150° C. for 100 minutes, and the resulting product was dissolved in a mixed solvent of methyl ethyl ketone and DMF. Furthermore, 1.8 parts of zinc octylate were added to the mixture, and the resulting mixture was stirred to combine, with the result that a resin solution was obtained. Glass woven fabric having a thickness of 40 μm was impregnated with the resin solution, and then was dried at 160° C. for 10 minutes and at 170° C. for 90 minutes, with the result that an electroless plating material was obtained. The electroless plating material thus obtained was evaluated in accordance with procedures for evaluating various evaluation items. The evaluation results are shown in Table 8.

TABLE 7

| | Example 15 | Example 16 | Example 17 | Example 18 | Example 19 | Example 20 |
|---|---|---|---|---|---|---|
| Resin composition solution | (a) | (b) | (e) | (c) | (a) | (e) |
| Arrangement | Resin-glass | Resin-glass | Resin-glass | Resin-glass | Resin-aramid | Resin-glass woven fabric |
| | woven | woven | woven | woven | unwoven | Composite/Double-sided |
| | fabric | fabric | fabric | fabric | fabric | wiring |
| | Composite | Composite | Composite | Composite | Composite | board/Resin-glass |
| | | | | | | woven fabric Composite |
| Adhesive strength under normal | 10 N/cm | 11 N/cm | 11 N/cm | 12 N/cm | 10 N/cm | 10 N/cm |
| conditions | | | | | | |
| Adhesive strength after PCT | 6 N/cm | 7 N/cm | 6 N/cm | 8 N/cm | 7 N/cm | 6 N/cm |
| Surface roughness Ra | 0.02 μm | 0.02 μm | 0.02 μm | 0.01 μm | 0.02 μm | 0.02 μm |
| Fine wiring formability | ∘ | ∘ | ∘ | ∘ | ∘ | ∘ |
| L/S = 10 μm/10 μm | | | | | | |

TABLE 8

| | Comparative | Comparative |
|---|---|---|
| | Example 4 | Example 5 |
| Resin composition solution | — | — |
| Arrangement | Copper-clad | Resin-glass |
| | Laminate | woven fabric |
| | | Composite |
| Adhesive strength under normal conditions | 17 N/cm | 0.2 N/cm |
| Adhesive strength after PCT | 12 N/cm | 0.1 N/cm |
| Surface roughness Ra | 0.82 μm | 0.02 μm |
| Fine wiring formability | x | x |
| L/S = 10 μm/10 μm | | |

### Embodiment 4

<4-1. Arrangement of a Fiber-Resin Composite of the Present Embodiment>

A composite of the present embodiment is a fiber-resin composite obtained by integrating (i) a sheet having a layer made of a resin composition containing a thermoplastic resin with (ii) a fiber by thermocompression bonding (such a composite being referred to as “fiber-resin composite” in the present embodiment).

A conventional composite of a fiber such as glass and a resin such as an epoxy resin, which composite has been used for a substrate for use in a printed wiring board or the like, is manufactured by impregnating the fiber with a solution of the resin composition. The present embodiment makes it possible to uniform the thickness of a fiber-resin composite by bonding (i) a sheet formed from a resin composition containing a thermoplastic resin to (ii) a fiber by thermocompression. Further, by selecting a resin that is used for a thermoplastic resin sheet, a metal plating layer can be formed satisfactorily even on a flat and smooth surface.

Therefore, in cases where a circuit is formed on a surface of the fiber-resin composite, there is no influence from irregularities, so that the fiber-resin composite can be suitably used as a substrate on which fine wires are to be formed.

Meanwhile, the fiber-resin composite can be used as a material for a built-up wiring board. However, in order to improve properties such as bendability, it is preferable that the substrate be as thin as possible. In this case, the substrate becomes more susceptible to influence by the unevenness of thickness of the fiber-resin composite. This causes problems such as a problem of coexistence of a part in which inner-layer wires are satisfactorily embedded and a part in which the inner-layer wires are not embedded and a problem of warpage of the resulting built-up wiring board. The fiber-resin composite of the present invention has a less uneven thickness than does a fiber-resin composite that is obtained by a conventional method, and therefore can be suitably used in cases where the thickness of a substrate needs to be reduced.

Furthermore, in manufacturing the fiber-resin composite of the present invention, firm adhesion can be attained by using, as the sheet formed from a resin composition containing a thermoplastic resin, a polyimide resin having one or more structures represented by any one of general formulae (1) to (6). Among these, it is preferable to use a polyimide resin having a siloxane structure, and it is more preferable to use a polyimide resin having a structure represented by general formula (1). It is particularly preferable that the resulting fiber-resin composite have an uppermost surface containing a polyimide resin having a siloxane structure.

Examples of the sheet, having a layer formed from a resin composition containing a thermoplastic resin, which is bonded to the fiber by thermocompression include a single-layer sheet containing a polyimide resin having a siloxane structure and a plural-layer sheet including a layer containing a polyimide resin having a siloxane structure.

In the following, Fiber, Sheet Having a Layer Formed from a Resin Composition Containing a Thermoplastic Resin, Manufacture of the Fiber-resin Composite, Laminate Obtained with Use of the Fiber-resin Composite, and Printed Wiring Board will be described in the order named.

(4-1-1. Fiber that is Used for the Fiber-Resin Composite of the Present Embodiment)

The fiber that is used for the present embodiment is not particularly limited, and various inorganic fibers and organic fibers can be used as such. However, in consideration of the application of the present embodiment to a printed wiring board, it is preferable, in terms of reducing the coefficient of thermal expansion, that the fiber be made from at least one type selected from the group consisting of paper, glass, polyimide, aramid, polyarylate, and tetrafluoroethylene. These fibers can be used in various forms in accordance with uses such as woven fabric, unwoven fabric, roving, chopped strand mats, and surfacing mats.

(4-1-2. Sheet Having a Layer Formed from a Resin Composition Containing a Thermoplastic Resin)

The sheet having a layer formed from a resin composition containing a thermoplastic resin may be a single-layer sheet, or may be a plural-layer sheet containing two or more different resin layers. Further, it is necessary that the sheet that is used for the present embodiment contain a thermoplastic resin; however, in case where the sheet is a plural-layer sheet, it is only necessary that the sheet have at least one layer that contains a thermoplastic resin. For example, in cases where the sheet is a two-layer sheet, the sheet may be constituted by a layer formed from a thermoplastic resin and a layer formed from a thermosetting component. The sheet that is used for the present embodiment exhibits self-bearing properties by containing a thermoplastic resin and enables control of flow properties. This makes it possible to obtain a fiber-resin composite with good thickness accuracy.

The fiber-resin composite of the present embodiment has such an advantage that even when the fiber-resin composite has a flat and smooth surface, the fiber-resin composite adheres satisfactorily to an electroless plating film. Therefore, the fiber-resin composite of the present embodiment is suitably used for subjecting the uppermost surface to electroless plating. In order for the fiber-resin composite to adhere satisfactorily to an electroless plating film, it is preferable that the fiber-resin composite contain a polyimide resin having a siloxane structure. Therefore, in cases where the sheet formed from a resin composition containing a thermoplastic resin is a single-layer sheet, it is preferable that the sheet contain a polyimide resin having a siloxane structure. Further, in cases where the sheet formed from a resin composition containing a thermoplastic resin is a plural-layer sheet, it is preferable that the uppermost resin layer that makes direct contact with the fiber contain a polyimide resin having a siloxane structure. Meanwhile, it is preferable that the sheet formed from a resin composition containing a thermoplastic resin have appropriate flow properties so that the sheet flows sufficiently into spaces in the fiber by thermocompression bonding so as to be integrated with the fiber. Therefore, in cases where the sheet is a single-layer sheet, it is preferable that the sheet contain (i) a polyimide resin having a siloxane structure and (ii) a thermoplastic resin. In cases where the sheet is a plural-layer sheet, it is preferable that the resin layer that makes direct contact with the fiber contain a thermoplastic resin and a thermosetting component. In the following, the sheet having a layer formed from a resin composition containing a thermoplastic resin will be explained by way of example.

(A) Single-Layer Sheet Formed from a Resin Composition Containing a Thermoplastic Resin

In order that the sheet that is used for the present embodiment expresses self-bearing properties and enables control of flow properties, it is necessary that the sheet contain a thermoplastic resin.

The single-layer sheet formed from a resin composition containing a thermoplastic resin only needs to contain a thermoplastic resin, and examples of the thermoplastic resin include thermoplastic polyimide resins such as a polysulfone resin, a polyethersulfone resin, a polyphenylene ether resin, a phenoxy resin, and a polyimide resin having a siloxane structure. These thermoplastic resins can be used separately or in combination. Among these, in order for electroless plating to adhere firmly to the surface, it is preferable that the single-layer sheet contain, as a thermoplastic resin, a polyimide resin having a siloxane structure. The use of a polyimide resin having a siloxane structure makes it possible to obtain a single-layer sheet that adheres satisfactorily to an electroless plating film and exhibits excellent thermocompressibility. Note that the “polyimide resin having a siloxane structure” of the present embodiment can be explained appropriately with the aid of the description of (1-1-2. Resin Layer) of Embodiment 1.

Further, for the purpose of, for example, improving the resin flow properties of the resulting sheet, the sheet can contain a thermosetting component. Examples of the thermosetting component include a bismaleimide resin, a bisallylnadiimide resin, a phenol resin, a cyanate resin, an epoxy resin, an acrylic resin, a methacrylic resin, a triazine resin, a hydrosilyl cured resin, an allyl cured resin, and an unsaturated polyester resin. These thermosetting components can be used separately or in combination. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains. In the present embodiment, it is important that the fiber and the sheet be integrated satisfactorily with each other by thermocompression bonding, and it is preferable that the sheet be formed from a resin having appropriate resin flow properties. Therefore, it is preferable that the sheet contain a thermosetting component as another component. For reasons such as the improvement of the resin flow properties of the sheet and the acquisition of a fiber-resin composite well balanced in terms of heat resistance and the like, it is preferable that the sheet contain an epoxy resin of all other thermosetting components. As the epoxy resin, any epoxy resin can be used in the present embodiment. Examples of the epoxy resin include a bisphenol epoxy resin, a halogenated bisphenol epoxy resin, a phenol novolak epoxy resin, a halogenated phenol novolak epoxy resin, an alkylphenol novolak epoxy resin, a polyphenol epoxy resin, a polyglycol epoxy resin, a cyclic aliphatic epoxy resin, a cresol novolak epoxy resin, a glycidylamine epoxy resin, a urethane modified epoxy resin, a rubber modified epoxy resin, and an epoxy modified polysiloxane.

In order to obtain a single-layer sheet having properties well balanced among heat resistance, adhesive properties, and the like, it is preferable that a polyimide resin, contained in a resin composition, which has a siloxane structure be in a range of 10 wt % to 100 wt % with respect to the whole resin.

Further, if necessary, the thermosetting resin can be used in combination with a curing agent and a curing catalyst.

As described above, such a single-layer sheet has an uppermost surface that makes direct contact with an electroless plating film. Therefore, in order for the electroless plating film to more firmly adhere, it is preferable that the single-layer sheet contain a polyimide resin having a siloxane structure.

The following explains an example of a method for manufacturing a single layer sheet, formed from a resin composition containing a thermoplastic resin, which is used for the present embodiment. However, the present invention is not limited to this. First, a resin used is added to an appropriate solvent, and the mixture is stirred for uniform dissolution and dispersion, with the result that a resin composition solution is obtained. Then, the resin composition solution is applied onto a support by a casting method, and the support is dried, with the result that a single-layer sheet is obtained. The support used above is not particularly limited, and examples of the support include a publicly-known resin film formed from polyethylene terephthalate, polypropylene, a fluororesin, or the like and metal foil such as copper foil, aluminum foil, or nickel foil. Further, for the purpose of improving peeling properties, a resin film that has been subjected to various peeling treatments can be used as the support. In cases where the sheet contains a thermosetting component, it is preferable that the sheet be in a half-cured state (B stage) so that the resin composition flows appropriately into spaces in the fiber at the time of thermocompression so as to be satisfactorily integrated with the fiber. In order to obtain a B-staged sheet, it is important that the drying temperature and time be appropriately controlled. Note that the method for manufacturing a single-layer sheet is an example, and the single-layer sheet can be manufactured by any method that can be imagined by a person skilled in the art.

(B) Plural-Layer Sheet Containing a Layer Formed from a Resin Composition Containing a Thermoplastic Resin

In cases where the sheet, formed from a resin composition containing a thermoplastic resin, which is used for the present invention is a plural-layer sheet, it is only necessary that the sheet contain at least one layer that is formed from a resin composition containing a thermoplastic resin. Examples of the thermoplastic resin include those resins which have been mentioned in “(A) Single-layer Sheet Formed from a Resin Composition Containing a Thermoplastic Resin”. However, it is preferable that a polyimide resin having a siloxane structure be contained as a layer formed from a resin composition containing a thermoplastic resin. Further, it is preferable that the sheet be a sheet including (i) a layer containing a polyimide resin having a siloxane structure and (ii) a layer having a resin layer containing a thermosetting component. It is more preferable that the sheet be a sheet including (i′) a layer containing a polyimide resin having a siloxane structure and (ii′) a layer containing a thermoplastic resin and a thermosetting component. It is even more preferable that the sheet be a sheet including (i″) a layer containing a polyimide resin having a siloxane structure and (ii″) a layer containing a thermoplastic polyimide resin and an epoxy resin. In terms of heat resistance and the like, it is preferable that the layer containing a thermoplastic resin and a thermosetting component be arranged such that the thermosetting component is contained by 10 wt % to 100 wt % with respect to the whole resin composition. As described above, in cases where the sheet is a plural-layer sheet, the plural layers can be allowed to respectively function as a layer that adheres satisfactorily to an electroless plating film and a layer that exhibits excellent thermocompressibility. However, in cases where the sheet is a plural-layer sheet, it is preferable, in consideration of adhesive properties with respect to an electroless plating film, that the uppermost exposed layer of the fiber-resin composite be a layer containing a polyimide resin having a siloxane structure.

Further, for the purpose of improving adhesive properties with respect to the electroless plating film, it is possible that the fiber-resin composite is allowed to contain additives through the addition of the additives to the fiber-resin composite, the application of the additives to a surface of the fiber-resin composite, or the like. Specific examples of the additives include, but are not limited to, organic thiol compounds. Further, various organic fillers and inorganic fillers can also be added.

It should be noted that it is important that the aforementioned other various components be combined so as not to increase the surface roughness of the fiber-resin composite to such an extent that the formation of fine wires is adversely affected, and so as not to cause a reduction in adhesiveness between the fiber-resin composite and the electroless plating film.

In cases where the sheet is a plural-layer sheet, the sheet can be obtained in the following manner. First, a single-layer sheet is obtained in the same manner as described above. Then, a solution of a resin composite that is to serve as a second layer is applied to the single-layer sheet by a casting method, and the single-layer sheet is dried, with the result that a plural-layer sheet formed on a support is obtained. A sheet including three layers, a sheet including four layers, and the like can be obtained in the same manner as described above.

In cases where the sheet contains a thermosetting component, it is preferable that the sheet is in a half-cured state (B stage) so that the resin composition flows appropriately into spaces in the fiber at the time of thermocompression bonding so as to be satisfactorily integrated with fiber. In order to obtain a B-staged sheet, it is important that the drying temperature and time be appropriately controlled.

Examples of the support used above include, but are not particularly limited to, a publicly-known resin film formed from polyethylene terephthalate, polypropylene, a fluororesin, or the like and metal foil such as copper foil, aluminum foil, or nickel foil. Further, for the purpose of improving peeling properties, a resin film that has been subjected to various peeling treatments can be used as the support.

(4-1-3. Method for Manufacturing the Fiber-Resin Composite of the Present Embodiment)

The fiber-resin composite of the present embodiment is characterized by being obtained by integrating (i) a sheet made of a resin composition containing a thermoplastic resin with (ii) a fiber by thermocompression bonding. The term “integration” refers to such a state that spaces in the fiber are completely filled with the resin and a surface of the fiber is also covered with the resin. The thermocompression bonding of the sheet formed from a resin composition containing a thermoplastic component makes it possible to obtain a fiber-resin composite having a flat and smooth surface and little unevenness of thickness. Further, the fiber-resin composite of the present embodiment brings about such an effect that when a surface of the fiber-resin composite is subjected to electroless plating, an electroless plating is allowed to adhere firmly to the surface.

The thermocompression bonding can be performed by various thermocompression bonding methods such as heat pressing, vacuum pressing, lamination (heat lamination), vacuum lamination, heat roller lamination, and vacuum heat roller lamination. Among these methods, processing under vacuum, i.e., vacuum pressing, vacuum lamination, or vacuum heat roller lamination is preferred because integration can be satisfactorily achieved without bubbles. For the purpose of allowing curing to proceed after the integration, drying by heating can be performed with a hot-air oven or the like.

The integration may be performed with use of an arrangement including a sheet and a fiber, or an arrangement including a sheet, a fiber, and a sheet with the fiber sandwiched between the sheets. In this case, the integration may be performed after having placed a fiber between resin sheets each having a surface on which a metal plating layer is to be formed. Alternatively, the integration may be performed after having placed a fiber between a resin sheet having a surface on which a metal plating layer is to be formed and a resin sheet in which a circuit is to be embedded. It is preferable that the resin sheet having a surface on which a metal plating layer is to be formed contain a polyimide resin having one or more structures represented by any one of general formulae (1) to (6). Further, it is preferable that the resin sheet in which a circuit is to be embedded contain an epoxy resin, or also preferably an epoxy resin and a thermoplastic polyimide resin. The thermoplastic polyimide resin that is used for the resin sheet in which a circuit is to be embedded does not need to contain a structure represented by any one of general formulae (1) to (6). In case of an arrangement including a sheet and a fiber, it is preferable, in order to form electroless plating films firmly on both surfaces, that the sheet be a single-layer sheet containing a polyimide resin containing a siloxane structure. In case of an arrangement including a sheet, a fiber, and a sheet, each of the sheet may be a single-layer sheet or a plural-layer sheet. In order to satisfactorily perform integration with high thickness accuracy, it is important to control the resin flow properties of a sheet formed from a resin composition containing a thermoplastic resin. The resin flow properties can be controlled in accordance with the molecular weight and blending quantity of the thermoplastic resin, the residual volatile portions of the sheet, thermocompression bonding conditions, and the like. It is preferable that the resin flow properties be such that the melting viscosity is not more than 5×10⁴ Pa·s at a laminating temperature, more preferably not more than 3×10⁴ Pa·s, or particularly preferably not more than 1×10⁴ Pa·s. It is preferable that the laminating temperature fall within a range of 100° C. to 250° C. as described later.

The thermocompression bonding conditions are not particularly limited as long as spaces in the fiber are sufficiently filled with the resin composition constituting the sheet and a surface of the fiber are also covered, i.e., as long as the “integration” defined above in the present embodiment is achieved. However, in order to manufacture a fiber-resin composite with high thickness accuracy, it is preferable that the thermocompression bonding be performed at a temperature of 70° C. to 300° C. under a pressure of 0.1 MPa to 10 MPa for a period of 1 second to 3 hours, or more preferably at a temperature of 100° C. to 250° C. under a pressure of 0.5 MPa to 5 MPa for a period of 10 seconds to 2 hours.

Further, in cases where the fiber-resin composite of the present embodiment is used as a built-up material, it is necessary that the fiber-resin composite be maintained in a B stage so that inner-layer wires can be satisfactorily embedded. Therefore, the fiber and the resin composition must be integrated by thermocompression bonding under such conditions that the fiber-resin composite is maintained in a B stage.

In some cases where the sheet is formed on a support, the sheet may be bonded to the fiber by thermocompression with the support attached to the sheet. Alternatively, the support may be peeled away, and another resin film or the like may be bonded as a slip sheet to the fiber by thermocompression. However, in cases where the sheet is bonded to the fiber with the support attached to the sheet, the support becomes a layer serving as an uppermost surface on which an electroless plating film is to be formed. Therefore, it is preferable that the layer be a layer containing a polyimide resin having a siloxane structure.

The fiber-resin composite of the present embodiment thus obtained has such an advantage as to adhere satisfactorily to an electroless plating film even in cases where the surface roughness of a flat and smooth surface of the fiber-resin composite is small, and therefore can be used for subjecting the uppermost surface to electroless plating. Further, the fiber-resin composite thus obtained has such an advantage as to have high thickness accuracy.

It is preferable that the surface roughness of the fiber-resin composite of the present embodiment be less than 0.5 μm in terms of arithmetic mean roughness Ra as measured as a cutoff value of 0.002 mm. In cases where such conditions are satisfied, the fiber-resin composite exhibits good fine wiring formability when used for a printed wiring board.

Note that the fiber-resin composite of the present embodiment may be in a B stage or in a C stage.

Further, the fiber-resin composite of the present embodiment is not particularly limited in terms of thickness. However, in consideration of its application to a high-density printed wiring board, it is preferable that the fiber-resin composite have a small thickness. Specifically, it is preferable that the fiber-resin composite have a thickness of not more than 1 mm, or more preferably not more than 0.5 mm. The fiber-resin composite can also be used as a material for a built-up wiring board. In this case, the built-up board becomes more susceptible to influence by the unevenness of thickness of the fiber-resin composite. This causes problems such as a problem of coexistence of a part in which inner-layer wires are satisfactorily embedded and a part in which inner-layer wires are not embedded and a problem of warpage of the resulting built-up wiring board.

With regard to the warpage of a substrate due to unevenness of thickness, the fiber-resin composite of the present invention has a less uneven thickness than does a fiber-resin composite that is obtained by a conventional method, and therefore can be suitably used in cases where the thickness of a substrate needs to be reduced.

The unevenness of thickness of the fiber-resin composite of the present embodiment can be examined, for example, by measuring the respective thicknesses of five randomly sampled parts of a 10 cm×10 cm piece cut out of the fiber-resin composite and then by calculating the difference between the thickness of the thickest part and the thickness of the thinnest part. In consideration of warpage and the like, it is preferable that the unevenness of thickness be not more than 6 μm, or more preferably not more than 4 μm.

<4-2. Laminate Obtained with Use of the Fiber-Resin Composite>

Although the fiber-resin composite of the present embodiment has a flat and smooth surface, it is possible to cause an electroless plating layer to adhere firmly to the surface. The fiber-resin composite of the present embodiment can be used as a laminate by forming an electroless plating layer on a surface thereof. Examples of the electroless plating to which the fiber-resin composite of the present embodiment can be subjected include electroless copper plating, electroless nickel plating, electroless gold plating, electroless silver plating, and electroless tin plating. From an industrial point of view and in terms of electrical characteristics such as migration resistance, electroless copper plating and electroless nickel plating are preferred, or electroless copper plating is preferred in particular. In cases where the fiber-resin composite of the present invention is subjected to electroless plating, the fiber-resin composite may be subjected to various types of surface treatment such as a desmear process.

<4-3. Printed Wiring Board>

Examples of a printed wiring board obtained with use of the fiber-resin composite of the present embodiment include a single- or double-sided printed wiring board obtained by subjecting the fiber-resin composite to electroless plating and then by forming wires on the fiber-resin composite by a semi-additive method or a subtractive method. Further, the use of the printed wiring board as a core substrate makes it possible to obtain a built-up wiring board. Further, the use of the fiber-resin composite of the present embodiment as a built-up material makes it possible to obtain a built-up wiring board. The fiber-resin composite of the present embodiment excels in fine wiring formability, and therefore can be suitably applied to other various high-density printed wiring boards.

Examples of a method according to the present embodiment for manufacturing a single- or double-sided printed wiring board with use of a fiber-resin composite include a method described in <3-3. Printed Wiring Board>. Note that the “electroless plating material” in <3-3. Printed Wiring Board> only needs to be read as “fiber-resin composite” in the present embodiment.

### Examples

The invention of the present embodiment will be described more in detail in accordance with Examples. However, the present invention is not limited to these. A person skilled in the art can make various changes, modifications, and alterations within the scope of the present invention. Note that such properties of laminates of Examples and Comparative Examples as adhesive properties with respect to electroless plated copper, surface roughness Ra, and wiring formability were evaluated or calculated in the following manner.

[Evaluation of Adhesive Properties]

A surface of the fiber-resin composite thus obtained was subjected to desmear and electroless copper plating under conditions shown in Tables 1 and 2. Furthermore, electrolytic copper plating was performed so that a total copper thickness of 18 μm was attained.

The adhesive strength of a sample obtained as described above was measured in accordance with a method described in “Examples of Embodiment 1”.

[Measurement of Surface Roughness Ra]

The electroless plated copper layer of the same sample as used above in the evaluation of adhesive strength was removed by etching, and the surface roughness of the exposed surface was measured. The measurement was carried out in accordance with a method described in “Examples of Embodiment 1”.

[Unevenness of Thickness]

The respective thicknesses of five randomly sampled parts of a 10 cm×10 cm piece cut out of the fiber-resin composite thus obtained were measured. The difference between the thickness of the thickest part and the thickness of the thinnest part was calculated. As a result, the unevenness of thickness was obtained.

[Wiring Formability]

The same sample as used above in the evaluation of adhesive strength was used. The evaluation was carried out in accordance with a method described in “Examples of Embodiment 1”.

### Example of how a Polyimide Resin is Synthesized 6

37 g (0.045 mol) of KF-8010 manufactured by Shin-Etsu Chemical Co., Ltd., 21 g (0.105 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for approximately one hour. As a result, a DMF solution 1 of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 7 was obtained.

### Example of how a Polyimide Resin is Synthesized 7

62 g (0.075 mol) of KF8010 manufactured by Shin-Etsu Chemical Co., Ltd., 15 g (0.075 mol) of 4,4′-diaminodiphenylether, and DMF were poured into a glass flask having a capacity of 2000 ml, and then were stirred for dissolution. Then, 78 g (0.15 mol) of 4,4-(4,4′-isopropylidendiphenoxy)bisphthalic acid anhydride was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 8 was obtained.

### Example of how a Polyimide Resin is Synthesized 8

41 g (0.143 mol) of 1,3-bis(3-aminophenoxy)benzene, 1.6 g (0.007 mol) of 3,3′-dihydroxy-4,4′-diaminobiphenyl, and DMF were poured into a glass flask having a capacity of 2000 ml, and then were stirred for dissolution. Then, 78 g (0.15 mol) of 4,4-(4,4′-isopropylidendiphenoxy)bisphthalic acid anhydride was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 1820 minutes with a vacuum oven. As a result, Polyimide Resin 9 was obtained.

### Example of how a Polyimide Resin Solution is Prepared 1

Polyimide Resin 7 was dissolved in dioxolan, with the result that Polyimide Resin Solution (a4) was obtained with a solid content concentration of 25 wt %.

### Example of how a Polyimide Resin Solution is Prepared 2

Polyimide Resin 0.8 was dissolved in dioxolan, with the result that Polyimide Resin Solution (b4) was obtained with a solid content concentration of 25 wt %.

### Example of how a Polyimide Resin Solution is Prepared 3

Polyimide Resin 9 was dissolved in dioxolan, with the result that Polyimide Resin Solution (c4) was obtained with a solid content concentration of 25 wt %.

### Example of how a Thermosetting Component Solution is Prepared 1

32.1 g of YX4000H (i.e., a biphenyl epoxy resin manufactured by Japan Epoxy Resin Co., Ltd.), 17.9 g of bis[4-(3-aminophenoxy)phenyl]sulfone (i.e., a diamine manufactured by Wakayama Seika Kogyo Co., Ltd.), 0.2 g of 2,4-diamino-6-[2′-undecylimidazolyl-(1′)]-ethyl-s-triazine (i.e., an epoxy curing agent manufactured by Shikoku Chemicals Co., Ltd.) were dissolved in dioxolan, with the result that Thermosetting Component Solution (d4) was obtained with a solid content concentration of 50 wt %.

### Example of how a Resin Composition Solution is Prepared 1

60 g of Solution (a4) and 9 g of Solution (d4) were mixed, with the result that Resin Composition Solution (e4) was obtained.

### Example of How a Resin Composition Solution is Prepared 2

60 g of Solution (b4) and 9 g of Solution (d4) were mixed, with the result that Resin Composition Solution (f4) was obtained.

### Example of how a Resin Composition Solution is Prepared 3

60 g of Solution (c4) and 30 g of Solution (d4) were mixed, with the result that Resin Composition Solution (g4) was obtained.

### Example 21

Resin Composition Solution (e4) was applied by a casting method onto a film (marketed as “Cellapeel HP”; manufactured by Toyo Metallizing Co., Ltd.) serving as a support, and then the film was dried at temperatures of 60° C., 80° C., 100° C., 120° C., 140° C., and 150° C. for one minute each, with the result that a 70-μm-thick B-staged resin composition sheet was obtained with a support attached thereto. The support was peeled away from the sheet. Then, the sheet was layered on 40-μm-thick glass woven fabric so that the sheet and the glass woven fabric were layered in this order, and then was bonded to the glass woven fabric by thermocompression at 180° C. under 3 MPa for 60 minutes with a vacuum press, with the result that a 70-μm-thick fiber-resin composite was obtained. The unevenness of thickness was 2.5 μm. Note that a resin film (marketed as “AFLEX”, manufactured by Asahi Glass Co., Ltd.) was used as a slip sheet at the time of the lamination. The fiber-resin composite thus obtained was evaluated in various respects. The evaluation results are shown in Table 9.

### Example 22

Resin Composition Solution (e4) was applied by a casting method onto a film (marketed as “Cellapeel HP”; manufactured by Toyo Metallizing Co., Ltd.) serving as a support, and then the film was dried at temperatures of 60° C., 80° C., 100° C.-120° C., 140° C., and 150° C. for one minute each, with the result that a 30-μm-thick B-stage resin composition sheet was obtained with a support attached thereto. The support was peeled away from the sheet. Then, the sheet was layered on 40-μm-thick glass woven fabric so that the sheet, the glass woven fabric, and the sheet were layered in this order, and then was bonded to the glass woven fabric by thermocompression at 180° C. under 3 MPa for 60 minutes with a vacuum press, with the result that a 60-μm-thick fiber-resin composite was obtained. The unevenness of thickness was 2 μm. Note that a resin film (marketed as “AFLEX”, manufactured by Asahi Glass Co., Ltd.) was used as a slip sheet at the time of the lamination. The fiber-resin composite thus obtained was evaluated in various respects. The evaluation results are shown in Table 9.

### Example 23

Resin Composition Solution (a4) was applied by a casting method onto a film (marketed as “Cellapeel HP”; manufactured by Toyo Metallizing Co., Ltd.) serving as a support, and then the film was dried at 60° C. for one minute, with the result that a 2-μm-thick resin layer (a) was obtained. Furthermore, Resin Composition Solution (g4) was applied by a casting method onto the resin layer (a) thus formed, and then the resin layer (a) was dried at temperatures of 60° C., 80° C., 100° C., 120° C., 140° C., and 150° C. for one minute each, with the result that a B-stage resin composition sheet (two-layer sheet; total thickness: 30 μm) was obtained with a support attached thereto. The support was peeled away from the sheet. Then, the sheet was layered on 40-μm-thick glass woven fabric so that the sheet, the glass woven fabric, and the sheet were layered in this order, and then was bonded to the glass woven fabric by thermocompression at 180° C. under 3 MPa for 60 minutes with a vacuum press, with the result that a 60-μm-thick fiber-resin composite was obtained. The unevenness of thickness was 2 μm. Note that the layering was performed so that the glass woven fabric and the resin layer (a) face each other. Further, a resin film (marketed as “AFLEX”, manufactured by Asahi Glass Co., Ltd.) was used as a slip sheet at the time of the lamination. The fiber-resin composite thus obtained was evaluated in various respects. The evaluation results are shown in Table 9.

### Example 24

A 60-μm-thick fiber-resin composite was obtained in the same manner as in Example 22 except that Resin Composition Solution (f4) was used instead of Resin Composition Solution (e4). The unevenness of thickness was 1.5 μm. The fiber-resin composite thus obtained was evaluated in various respects. The evaluation results are shown in Table 9.

### Example 25

A 60-μm-thick fiber-resin composite was obtained in the same manner as in Example 22 except that 50-μm-thick aramid unwoven fabric was used instead of 40-μm-thick glass woven fabric. The unevenness of thickness was 2 μm. The fiber-resin composite thus obtained was evaluated in accordance with procedures for evaluating various evaluation items. The evaluation results are shown in Table 9.

### Example 26

Resin Composition Solution (a4) was applied by a casting method onto a film (marketed as “Cellapeel HP”; manufactured by Toyo Metallizing Co., Ltd.) serving as a support, and then the film was dried at 60° C. for one minute, with the result that a 2-μm-thick resin layer (a) was obtained. Furthermore, Resin Composition Solution (g4) was applied by a casting method onto the resin layer (a) thus formed, and then the resin layer (a) was dried at temperatures of 60° C., 80° C., 100° C., 120° C., 140° C., and 150° C. for one minute each, with the result that a B-staged resin composition sheet (two-layer sheet; total thickness: 30 μm) was obtained with a support attached thereto. Then, with the support attached to the sheet, the sheet was layered on 40-μm-thick glass woven fabric so that the sheet, the glass woven fabric, and the sheet were layered in this order, and then was bonded to the glass woven fabric by thermocompression at 130° C. under 2 MPa for 5 minutes with a vacuum press, with the result that a 60-μm-thick fiber-resin composite was obtained. The unevenness of thickness was 2 μm. Note that the layering was performed so that the support faces outward, and the support was used as a slip sheet.

Such B-staged fiber-resin composites as obtained above were placed respectively on both surfaces of the double-sided wiring board obtained by evaluation of wiring formability of Example 21, and then lamination was performed at 180° C. under 3 MPa for 60 minutes with a vacuum press. Note that the support had been peeled away before the lamination, and a resin film (marketed as “AFLEX”, manufactured by Asahi Glass Co., Ltd.) was used as a slip sheet at the time of the lamination. Thus obtained was a laminate including a fiber-resin composite, a double-sided wiring board, and a fiber-resin composite. Thereafter, the laminate thus obtained was evaluated in the same manner as in Example 21 in accordance with procedures for evaluating various evaluation items. The evaluation results are shown in Table 9. Note that the double-sided wiring board and the fiber-resin composites adhered firmly to one another and that the double-sided wiring board had a wiring portion, having a line-and-space (L/S) of 10 μm/10 μm, which was satisfactorily embedded.

### Comparative Example 6

By using a copper-clad laminate obtained by laminating (i) a 50-μm-thick prepreg (ES-3306S; manufactured by Risho Kogyo Co., Ltd.) serving as a composite and (ii) 9-μm-thick electrolytic copper foil, the strength of adhesiveness between the composite and the copper foil was measured. The surface nature of a resin surface exposed by etching out the copper foil was also evaluated. Thereafter, the fine wiring formability with which wires were formed by a subtractive method of performing etching after having formed a resist was evaluated. The evaluation results are shown in Table 10. Note that the unevenness of thickness of the copper-clad laminate was 12 μm.

### Comparative Example 7

90 g of 2,2-bis(4-cyanatephenyl)propane and 10 g of bis(4-maleimidephenyl)methane were brought into a preparatory reaction with each other at 150° C. for 100 minutes, and the resulting product was dissolved in a mixed solvent of methyl ethyl ketone and DMF. Furthermore, 1.8 parts of zinc octylate were added to the mixture, and the resulting mixture was stirred to combine, with the result that a resin solution was obtained. Glass woven fabric having a thickness of 40 μm was impregnated with the resin solution, and then was dried at 160° C. for 10 minutes and at 170° C. for 90 minutes, with the result that a fiber-resin composite was obtained. The fiber-resin composite thus obtained was evaluated in accordance with procedures for evaluating various evaluation items. The evaluation results are shown in Table 10. Note that the unevenness of thickness of the copper-clad laminate was 8 μm.

As evidenced by Table 10, a normal copper-clad laminate exhibits good adhesiveness between copper foil and a composite. However, the copper foil causes great irregularities to be formed on a surface of the composite. Therefore, in cases where wires are formed by a subtractive method, there occur wire tilt and wire collapse. This makes it impossible to satisfactorily form fine wires. Further, even when electroless plating is formed on a flat and smooth surface of a normal prepreg that has been cured, such a prepreg has such low adhesive properties with respect to plated copper that wires are not able to be formed. Furthermore, Comparative Examples exhibited great unevenness of thickness.

TABLE 9

| | Example | Example | Example | Example | Example | Example |
|---|---|---|---|---|---|---|
| | 21 | 22 | 23 | 24 | 25 | 26 |
| Resin composition solution | (e4) | (e4) | (a4) + (g4) | (f4) | (e4) | (a4) + (g4) |
| How layers are layered at the time of | Sheet/Glass | Sheet/Glass | Sheet/Glass | Sheet/Glass | Sheet/Aramid | Sheet/Glass woven |
| integration | woven fabric | woven | woven | woven | unwoven | fabric/Sheet |
| | | fabric/Sheet | fabric/Sheet | fabric/Sheet | fabric/Sheet | |
| Arrangement | Resin-glass | Resin-glass | Resin-glass | Resin-glass | Resin-aramid | Resin-glass woven fabric |
| | woven fabric | woven fabric | woven fabric | woven fabric | unwoven | composite/Double-sided |
| | composite | composite | composite | composite | fabric | wiring board/Resin-glass |
| | | | | | composite | woven fabric composite |
| Adhesive strength under normal | 11 N/cm | 11 N/cm | 10 N/cm | 12 N/cm | 10 N/cm | 10 N/cm |
| conditions | | | | | | |
| Adhesive strength after PCT | 7 N/cm | 7 N/cm | 6 N/cm | 8 N/cm | 7 N/cm | 7 N/cm |
| Surface roughness Ra | 0.02 μm | 0.02 μm | 0.02 μm | 0.01 μm | 0.02 μm | 0.02 μm |
| Fine wiring formability | ∘ | ∘ | ∘ | ∘ | ∘ | ∘ |
| L/S = 10 μm/10 μm | | | | | | |

TABLE 10

| | Comparative | Comparative |
|---|---|---|
| | Example 6 | Example 7 |
| Resin composition solution | — | — |
| How layers are layered at the | — | — |
| time of integration | | |
| Arrangement | Copper-clad | Resin-glass |
| | laminate | woven fabric |
| | | composite |
| Adhesive strength under normal conditions | 17 N/cm | 0.2 N/cm |
| Adhesive strength after PCT | 12 N/cm | 0.1 N/cm |
| Surface roughness Ra | 0.82 μm | 0.02 μm |
| Fine wiring formability | x | x |
| L/S = 10 μm/10 μm | | |

### Embodiment 5

<5-1. Method of the Present Embodiment for Manufacturing a Multilayer Printed Wiring Board>

A method of the present embodiment for manufacturing a multilayer printed wiring board (such a method being hereinafter referred to as “manufacturing method of the present embodiment”) is a method for manufacturing a multilayer printed wiring board with used of a fiber-resin composite (a) having a resin layer (b) on which metal plating is to be formed, the method being characterized by including the following steps (A) to (C) of:

(A) laminating a laminate on a core wiring substrate by heat and pressure, the core wiring substrate having a surface that has a wire including a connection pad, the laminate having a resin layer (b), provided on at least one surface of a fiber-resin composite (a), on which metal plating is to be formed;

(B) exposing the connection pad by making via holes in respective parts of the fiber-resin composite (a) and the resin layer (b) on which metal plating is to be formed, the parts corresponding to the connection pad; and

(C) making an electrical connection between (i) a surface of the resin layer (b) on which metal plating is to be formed and (ii) the connection pad by forming metal plating on the surface of the resin layer (b) on which metal plating is to be formed and in the via holes.

(5-1-1. Fiber-Resin Composite (a))

The following explains a fiber-resin composite (a) that is used for the manufacturing method of the present embodiment. The fiber-resin composite (a) has a resin layer (b) on which metal plating is to be formed. The fiber-resin composite (a) may be for example a composite of a fiber and a resin composition for forming the resin layer (b) on which metal layer is to be formed. Further, the fiber-resin composite (a) may be obtained by integrally laminating a film-like resin layer (b) on which metal plating is to be formed, a fiber-resin composite, and a core wiring substrate, and may be arranged such that the resin layer (b) on which metal plating is to be formed serves as a surface layer.

The fiber-resin composite (a) that is used for the manufacturing method of the present embodiment bears the function of causing wires of the core wiring board to be satisfactorily embedded and to firmly adhere. Therefore, it is preferable that the resin that is used for the fiber-resin composite (a) be a thermoplastic resin that excels in resin flow properties or a resin composition containing a thermosetting component. In cases where the fiber-resin composite contains a thermosetting component, it is necessary that the fiber-resin composite be in a B stage.

The fiber that is used for the fiber-resin composite (a) is not particularly limited. However, in consideration of the application of the fiber-resin composite to a printed wiring board, it is preferable that the fiber be at least one type selected from the group consisting of paper, glass woven fabric, glass unwoven fabric, aramid woven fabric, aramid unwoven fabric, and polytetrafluoroethylene.

Examples of the paper include paper made from pulp such as paper pulp, dissolving pulp, and synthetic pulp prepared from raw material such as wood, bark, cotton, hemp, and synthetic resin. Examples of the glass woven fabric and glass unwoven fabric include glass woven fabric and glass unwoven fabric formed from E glass, D glass, or other types of glass. Examples of the aramid woven fabric and aramid unwoven fabric include unwoven fabric each formed from aromatic polyamide or aromatic polyamide imide. The term “aromatic polyamide” used herein refers to conventionally publicly-known meta-aromatic polyamide, para-aromatic polyaimide, or copolymer aromatic polyamide thereof. Preferable examples of the polytetrafluoroethylene include polytetrafluoroethylene that has been drawn so as to have a fine continuous porous structure.

The following explains a resin of the fiber-resin composite (a) that is used for the present embodiment. The resin is not particularly limited, and may be a resin formed solely from a thermoplastic resin or a resin formed solely from a thermosetting component. Further, the resin may be a resin formed from both a thermoplastic resin and a thermosetting component. However, it is necessary that the resin have resin flow properties to the extent that spaces between the wires of the core wiring board can be sufficiently filled. Examples of the thermoplastic resin include a polysulfone resin, a polyethersulfone resin, a thermoplastic polyimide resin, a polyphenylene ether resin, a polyolefin resin, a polycarbonate resin, and a polyester resin. Examples of the thermosetting component include an epoxy resin, a thermosetting polyimide resin, a cyanate ester resin, a hydrosilyl cured resin, a bismaleimide resin, a bisallylnadiimide resin, an acrylic resin, a methacrylic resin, an allyl resin, and an unsaturated polyester resin. Further, the thermoplastic resin and the thermosetting component can be used together with each other. Furthermore, the resin may be a resin composition for forming the undermentioned resin layer (b) on which metal plating is to be formed.

Since the fiber-resin composite (a) that is used for the present embodiment contains a fiber, the fiber-resin composite (a) has such an advantage that a low coefficient of thermal expansion is obtained. However, in terms of obtaining a lower coefficient of thermal expansion, various organic and inorganic fillers may be added.

(5-1-2. Resin Layer (b) on which Metal Plating is to be Formed)

The fiber-resin composite that is used for the present embodiment has a resin layer (b) on which metal plating is to be formed. It is necessary that metal plating be formed firmly on a flat and smooth surface of the resin layer (b) on which metal plating is to be formed. Therefore, it is preferable that the resin layer (b) contain a polyimide resin having one or more structures represented by any one of general formulae (1) to (6):

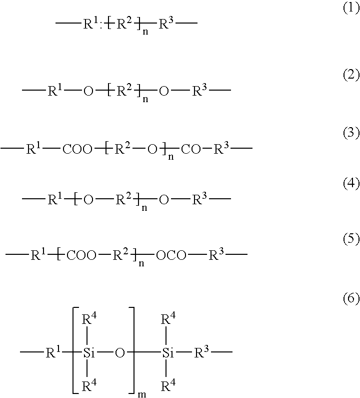

(where R¹ and R³ are a bivalent alkylene represented by C_{X}H_{2X} group or a bivalent aromatic group; R⁴ is an alkyl group, a phenyl group, alkoxy group, or a phenoxy group; is a bivalent alkylene group represented by C_{X}H_{2X} or a bivalent phenylene group; n is an integer of 3 to 100; and m is an integer of not less than 1.)

The polyimide resin having one or more structures represented by any one of general formulae (1) to (6) may be any polyimide resin as long as it has one or more structures represented by any one of general formulae (1) to (6). For example, examples of a method for manufacturing such a polyimide resin include the following methods (1) to (3). According to method (1), polyamic acid serving as a polyimide resin precursor is manufactured with use of an acid dianhydride component having one or more structures represented by any one of general formulae (1) to (6) or a diamine component having one or more structures represented by any one of general formulae (1) to (6). Then, the polyamic acid thus manufactured is imidized, with the result that a polyimide resin is obtained. According to method (2), polyamic acid having a functional group is manufactured with use of an acid dianhydride component having a functional group or a diamine component having a functional group. Next, the polyamic acid thus manufactured is allowed to react with a compound having (i) a functional group capable of reacting with the functional group of the polyamic acid and (ii) one or more structures represented by any one of general formulae (1) to (6), with the result that polyamic acid into which a structure represented by any one of general formulae (1) to (6) has been introduced is obtained. Then, the polyamic acid thus manufactured is imidized, with the result that a polyimide resin is obtained. According to method (3), polyamic acid having a functional group is manufactured with use of an acid dianhydride component having a functional group or a diamine component having a functional group. Then, the polyamic acid thus manufactured is imidized, with the result that a polyimide having a functional group is obtained. Next, the polyimide thus obtained is allowed to react with a compound having (a) a functional group capable of reacting with the functional group of the polyimide and (b) one or more structures represented by any one of general formulae (1) to (6), with the result that a polyimide resin into which a structure represented by any one of general formulae (1) to (6) has been introduced is obtained.

Note that it is relatively easy to obtain a diamine having one or more structures represented by any one of general formulae (1) to (6). Therefore, among the methods thus described, it is preferable that the target polyimide resin be manufactured by a reaction between an acid dianhydride component and a diamine component having one or more structures represented by any one of general formulae (1) to (6).

The following explains an example of how the polyimide resin that is used for the present embodiment is manufactured with use of an acid dianhydride component and a diamine component having one or more structures represented by any one of general formulae (1) to (6).

The acid dianhydride is not particularly limited. Examples of the acid dianhydride component include: aromatic tetracarboxylic acid dianhydride such as pyromellitic acid dianhydride, 3,3′,4,4′-benzophenone tetracarboxylic acid dianhydride, 3,3′,4,4′-diphenylsulfone tetracarboxylic acid dianhydride, 1,4,5,8-naphthalene tetracarboxylic acid dianhydride, 2,3,6,7-naphthalene tetracarboxylic acid dianhydride, 3,3′,4,4′-dimethyldiphenylsilane tetracarboxylic acid dianhydride, 1,2,3,4-furan tetracarboxylic acid dianhydride, 4,4′-bis(3,4-dicarboxyphenoxy) diphenylpropanoic acid dianhydride, 3,3′,4,4′-biphenyl tetracarboxylic acid dianhydride, 2,3,3′,4′-biphenyl tetracarboxylic acid dianhydride, and p-phenylenediphthalic acid anhydride; 4,4′-hexafluoroisopropylidene diphthalic acid anhydride; 4,4′-oxydiphthalic acid anhydride, 3,4′-oxydiphthalic acid anhydride; 3,3′-oxydiphthalic acid anhydride, 4,4′-(4,4′-isopropylidenediphenoxy)bis(phthalic anhydride); 4,4′-hydroquinonebis(phthalic anhydride); 2,2-bis(4-hydroxyphenyl)propanedibenzoate-3,3′4,4′-tetracarboxylic acid dianhydride; 1,2-ethylenebis(trimellitic acid monoester anhydride); and p-phenylenebis(trimellitic acid monoester anhydride). These acid dianhydride components may be used separately. Alternatively, a combination of two or more of them can be used.

The following explains the diamine component. It is preferable to contain, as the diamine component of the present embodiment, a diamine component having one or more structures represented by any one of general formulae (1) to (6):

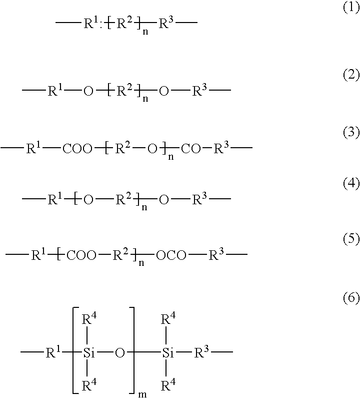

(where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group or a bivalent phenylene represented by C_{X}H_{2X} group; n is an integer of 3 to 100; and m is an integer of not less than 1.)

The use of a diamine component having one or more structures represented by any one of general formulae (1) to (6) causes the resulting polyimide resin to have a feature of adhering firmly to a metal plating layer.

Examples of a diamine having a structure represented by general formula (2) include hexamethylene diamine and octamethylene diamine. Examples of a diamine having a structure represented by general formula (3) include 1,3-bis(4-aminophenoxy)propane, 1,4-bis(4-aminophenoxy)butane, 1,5-bis(4-aminophenoxy)pentane. Examples of a diamine having a structure represented by general formula (4) include Elasmer-1000P, Elasmer-650P, and Elasmer-250P (manufactured by Ihara Chemical Industry, Co., Ltd.). Further, examples of a diamine having a structure represented by general formula (5) include polyetherpolyamines and polyoxyalkylenepolyamines such as JEFFAMINE D-2000 and JEFFAMINE D-400 (manufactured by Huntsman Corporation). Furthermore, examples of a diamine having a structure represented by general formula (1) include 1,1,3,3-tetramethyl-1,3-bis(4-aminophenyl)disiloxane, 1,1,3,3-tetraphenoxy-1,3-bis(4-aminoethyl)disiloxane, 1,1,3,3,5,5-hexamethyl-1,5-bis(4-aminophenyl)trisiloxane, 1,1,3,3-tetraphenyl-1,3-bis(2-aminophenyl)disiloxane, 1,1,3,3-tetraphenyl-1,3-bis(3-aminopropyl)disiloxane, 1,1,5,5-tetraphenyl-3,3-dimethyl-1,5-bis(3-aminopropyl)tri siloxane, 1,1,5,5-tetraphenyl-3,3-dimethoxy-1,5-bis(3-aminobutyl)trisiloxane, 1,1,5,5-tetraphenyl-3,3-dimethoxy-1,5-bis(3-aminopentyl)trisiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(4-aminobutyl)disiloxane, 1,3-dimethyl-1,3-dimethoxy-1,3-bis(4-aminobutyl)disiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, and 1,1,3,3,5,5-hexapropyl-1,5-bis(3-aminopropyl)trisiloxane. Note that examples of a relatively easily-obtainable diamine having a structure represented by general formula (1) include KF-8010, X-22-161A, X-22-161B, X-22-1660B-3, KF-8008, KF-8012, and X-22-9362 (manufactured by Shin-Etsu Chemical Co., Ltd.). The diamines respectively having structures respectively represented by general formulae (1) to (6) may be used separately. Alternatively, a combination of two or more of them may be used.

For the purpose of, for example, improving the heat resistance of the resin layer (b) on which metal plating is to be formed, it is preferable that a diamine having one or more structures represented by any one of general formulae (1) to (6) be used in combination with another diamine. As such another diamine, all types of diamine can be used. Examples of such another diamine include m-phenylenediamine, o-phenylenediamine, p-phenylenediamine, m-aminobenzylamine, p-aminobenzylamine, bis(3-aminophenyl)sulfide, (3-aminophenyl) (4-aminophenyl) sulfide, bis(4-aminophenyl) sulfide, bis(3-aminophenyl) sulfoxide, (3-aminophenyl) (4-aminophenyl) sulfoxide, bis(3-aminophenyl)sulfone, (3-aminophenyl)(4-aminophenyl)sulfone, bis(4-aminophenyl)sulfone, 3,4′-diaminobenzophenone, 4,4′-diaminobenzophenone, 3,3′-diaminodiphenylmethane, 3,4′-diaminodiphenylmethane, 4,4′-diaminodiphenylmethane, 4,4′-diaminodiphenylether, 3,3′-diaminodiphenylether, 3,4′-diaminodiphenylether, bis[4-(3-aminophenoxy)phenyl]sulfoxide, bis[4-(aminophenoxy)phenyl]sulfoxide, 4,4′-diaminodiphenylether, 3,4′-diaminodiphenylether, 3,3′-diaminodiphenylether, 4,4′-diaminodiphenylthioether, 3,4′-diaminodiphenylthioether, 3,3′-diaminodiphenylthioether, 3,3′-diaminodiphenylmethane, 3,4′-diaminodiphenylmethane, 4,4′-diaminodiphenylmethane, 4,4′-diaminodiphenylsulfone, 3,4′-diaminodiphenylsulfone, 3,3′-diaminodiphenylsulfone, 4,4′-diaminobenzanilide, 3,4′-diaminobenzanilide, 3,3′-diaminobenzanilide, 4,4′-diaminobenzophenone, 3,4′-diaminobenzophenone, 3,3′-diaminobenzophenone, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[3-(3-aminophenoxy)phenyl]-1,1,1,3,3,3-hexafluoro propane, 2,2-bis[4-(4-aminophenoxy)phenyl]-1,1,1,3,3,3-hexafluoro propane, 1,3-bis(3-aminophenoxy)benzene, 1,4-bis(3-aminophenoxy)benzene, 1,4′-bis(4-aminophenoxy)benzene, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 1,4-bis[4-(3-aminophenoxy)benzoyl]benzen, 1,3-bis[4-(3-aminophenoxy)benzoyl]benzen, 4,4′-bis[3-(4-aminophenoxy)benzoyl]diphenylether, 4,4′-bis[3-(3-aminophenoxy)benzoyl]diphenylether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl]benzene, 1,3-bis[4-(4-aminophenoxy)-α,α-dimethylbenzyl]benzene, and 3,3′-dihydroxy-4,4′-diaminobiphenyl.

It is preferable that a diamine having one or more structures represented by any one of general formulae (1) to (6) be contained by 2 mol % to 100 mol %, or more preferably 5 mol % to 100 mol %, with respect to the whole diamine component. In cases where the diamine is contained by less than 2 mol % with respect to the whole diamine component, there may be a decrease in strength of adhesiveness between the resin layer (b) on which metal plating is to be formed and the metal plating layer.

The method for manufacturing a polyimide resin can be explained appropriately with the aid of the description of (1-1-2. Resin Layer).

The polyimide resin, having one or more structures represented by any one of general formulae (1) to (6), which constitutes the resin layer (b) on which metal plating is to be formed is preferably a thermoplastic polyimide because a thermoplastic polyimide exhibits excellent adhesive properties with respect to a metal plating layer. The “thermoplastic polyimide” used in the present embodiment is permanently compressively deformed in a temperature range of 10° C. to 400° C. (warm-up speed: 10° C./min) when subjected to a compress-mode (probe diameter: 3 mm in diameter; load: 5 g) thermo mechanical analysis (TMA).

The resin layer (b) on which metal plating is to be formed can be blended with other components for the purpose of improving resin flow properties, heat resistance, and the like. Examples of the other components include resins such as a thermoplastic resin and a thermosetting resin. In order to obtain properties well balanced between heat resistance and adhesive properties, it is preferable that 3 to 100 parts by weight of thermosetting resin be contained with respect to 100 parts by weight of polyimide resin having one or more structures represented by any one of general formulae (1) to (6).

Examples of the thermoplastic resin include a polysulfone resin, a polyethersulfone resin, a polyphenylene ether resin, a phenoxy resin, and a thermoplastic polyimide resin different in structure from a thermoplastic resin composed of an acid dianhydride component and a diamine component containing a diamine having a structure represented by general formula (2). These thermosetting resins can be used separately or in combination.

Further, examples of the thermosetting resin include a bismaleimide resin, a bisallylnadiimide resin, a phenol resin, a cyanate resin, an epoxy resin, an acrylic resin, a methacrylic resin, a triazine resin, a hydrosilyl cured resin, an allyl cured resin, and an unsaturated polyester resin. These thermosetting resins can be used separately or in combination. In addition to the aforementioned thermosetting resins, thermosetting polymers containing a reactive group in side chains can also be used. The thermosetting polymers containing a reactive group in side chains are those thermosetting polymers which have a reactive group such as an epoxy group, an allyl group, a vinyl group, an alkoxysilyl group or a hydrosilyl group in the side chains or terminals of polymer chains.

Further, for the purpose of improving adhesive properties with respect to metal plating, it is possible that the resin layer (b) on which metal plating is to be formed is allowed to contain various additives through the addition of the additives to the resin layer (b) on which metal plating is to be formed, the application of the additives to a surface of the resin layer (b) on which metal plating is to be formed, or the like. Specific examples of the additives include, but are not limited to, organic thiol compounds. Further, various organic fillers and inorganic fillers can be added.

It should be noted that it is important that the other components such as additives be combined so that the surface roughness of the resin layer (b) on which metal plating is to be formed is not increased to such an extent that the formation of fine wires is adversely affected.

In order to achieve an excellent balance between surface roughness and adhesive properties with respect to a metal plating layer, it is preferable that the proportion of a polyimide resin, contained in the resin layer (b) on which metal plating is to be formed, which has one or more structures represented by any one of general formulae (1) to (6) fall within a range of 30 wt % to 100 wt %.

In the present embodiment, the resin layer (b) on which metal plating is to be formed refers to a layer having a thickness of not less than 10 Å.

In the present embodiment, the resin layer (b) on which metal plating is to be formed has such an advantage as to have a high adhesive strength with respect a metal plating layer even when having a small surface roughness. The “surface roughness” used here in the present invention can be expressed in terms of arithmetic mean roughness Ra as measured at a cutoff value of 0.002 mm. It is preferable that the surface roughness of the resin layer (b) on which metal plating is to be formed be less than 0.5 μm in terms of arithmetic mean roughness Ra as measured at a cutoff value of 0.002 mm. Therefore, in the present embodiment, the resin layer (b) on which metal plating is to be formed can be said to have a very flat and smooth surface in cases where the surface roughness of a microscopic range is observed. Therefore, even in cases where fine wires having a line-and-space of 10 μm/10 μm are formed, no bad influence is exerted.

In cases where the resin layer (b) on which metal plating is to be formed satisfies the above conditions, good fine wiring formability is achieved. A resin layer (b) having such a surface can be obtained, for example, by appropriately combining methods such as those listed below:

(1) Do not perform surface treatment;

(2) Appropriately select the surface roughness of that surface of a material for a support, a slip sheet, or the like which makes contact with the resin layer (b) on which metal layer is to be formed; and

(3) Appropriately select (i) the composition of a polyimide resin that is to be contained in the resin layer (b) on which metal plating is to be formed and (ii) drying conditions for forming the resin layer (b) on which metal layer is to be formed.

Thus explained is the resin layer (b), on which metal plating is to be formed, of the fiber-resin composite (a) of the present embodiment. The resin layer (b) on which metal plating is to be formed may be arranged and formed in any manner as long as it is exposed as a surface on which a conductor layer is formed after the fiber-resin composite (a) has been integrally laminated on a core wiring substrate.

According to the present invention, in cases where the fiber-resin composite (a) of the present embodiment includes a resin layer (b) on which metal plating is to be formed and a fiber-resin composite, another resin layer can be provided for the purpose of improving the adhesiveness between the fiber-resin composite and the resin layer (b) on which metal plating is to be formed. In order to express good adhesive properties with respect to each of the fiber-resin composite and the resin layer (b), it is preferable that such another resin layer contain a thermosetting component.

The fiber-resin composite (a) of the present embodiment is not particularly limited in terms of thickness. However, in order to thin the resulting multilayer printed wiring board, it is preferable that the fiber-resin composite (a) be as thin as possible and have a resin content sufficient for an inner-layer circuit to be embedded. The thinnest glass woven fabric in existence has a thickness of 40 μm, and the use of such glass woven fabric makes it possible to thin the fiber-resin composite (a) of the present embodiment. Further, if technological advances bring about a fiber such as thinner glass woven fabric, the use of such a fiber makes it possible to further thin the fiber-resin composite (a) according to the present invention.

(5-1-3. Method for Manufacturing the Fiber-Resin Composite (a))

The following explains a method for manufacturing the fiber-resin composite (a) of the present embodiment.

In cases where the resin of the fiber-resin composite (a) of the present embodiment is formed from a resin composition for forming the resin layer (b) on which metal plating is to be formed, the fiber-resin composite (a) is obtained by preparing a resin composition solution through dissolution of the resin composition in an appropriate solvent, impregnating the aforementioned fiber with the resin composition solution, and then drying the fiber by heating. In cases where a thermosetting component is contained, it is necessary that the drying by heating be stopped in a B stage.

Further, examples of another method for manufacturing the fiber-resin composite (a) include: a method for manufacturing the fiber-resin composite by sequentially layering a film-like resin layer (b) on which metal plating is to be formed, a fiber, and a core wiring substrate; and a method for manufacturing the fiber-resin composite (a) by sequentially layering a film-like resin layer (b) on which metal plating is to be formed, a fiber, a film-like resin layer (b) on which metal plating is to be formed, and a core wiring substrate. In either case, the lamination is performed such that the resin layer (b) on which metal plating is to be formed flows so as to cover the fiber and to fill a space between wires of the core wiring substrate. This results in a fiber-resin composite (a) whose surface layer is a resin layer (b) on which metal plating is to be formed.

The following explains a case where the fiber-resin composite (a) of the present embodiment includes a resin layer (b) on which metal plating is to be formed and a fiber-resin composite. In this case, a commercially available prepreg (a B-staged fiber-resin composite) can be used as the fiber-resin composite, and the fiber-resin composite (a) can be obtained by applying, onto the fiber-resin composite of the commercially available prepreg, a resin composition solution for forming a resin layer (b) and then by drying the fiber-resin composite by heating. In this case, it is necessary that the drying by heating be performed under such conditions that the prepreg is maintained in a B stage. Further, the fiber-resin composite (a) can be obtained by laminating a film-like resin layer (b) on a prepreg. Furthermore, the fiber-resin composite (a) can also be obtained by sequentially layering a film-like resin layer (b) on which metal plating is to be formed, a commercially available prepreg, and a core wiring substrate in a laminating step in manufacture of a multilayer printed wiring board. This case also results in an arrangement including a resin layer (b) on which metal plating is to be formed and a fiber-resin composite. Therefore, such a manufacturing method can also be suitably applied as a method for manufacturing the fiber-resin composite (a).

(5-1-4. Metal Plating Layer)

The metal plating layer can be formed by various types of dry plating such as vapor deposition, sputtering, and CVD, or by wet plating such as electroless plating. However, in consideration of productivity and adhesive properties with respect to the resin layer (b) on which metal plating is to be formed, it is preferable that the metal plating layer be a layer formed by electroless plating. Examples of the type of electroless plating include electroless copper plating, electroless nickel plating, electroless gold plating, electroless silver plating, and electroless tin plating. However, from an industrial point of view and in terms of electrical characteristics such as migration resistance, electroless copper plating and electroless nickel plating are preferred, or electroless copper plating is preferred in particular. The metal plating layer is not particularly limited in terms of thickness. However, in consideration of fine wiring formability, it is preferable that the metal plating layer have a thickness of not more than 5 μm, or more preferably not more than 3 μm.

(5-1-5. Method for Manufacturing a Multilayer Printed Wiring Board)

The method of the present embodiment for manufacturing a multilayer printed wiring board is characterized by including the following steps (A) to (C) of:

(A) laminating a laminate on a core wiring substrate by heat and pressure, the core wiring substrate having a surface that has a wire including a connection pad, the laminate having a resin layer (b), provided on at least one surface of a fiber-resin composite (a), on which metal plating is to be formed;

(B) exposing the connection pad by making via holes in respective parts of the fiber-resin composite (a) and the resin layer (b) which parts correspond to the connection pad; and

(C) making an electrical connection between a surface of the resin layer (b) and the connection pad by forming metal plating on the surface of the resin layer (b) and in the via holes.

The method of the present invention for manufacturing a multilayer printed wiring board makes it possible to provide a multilayer printed wiring board that has a resin layer (b), exhibiting excellent adhesive properties with respect to metal plating, on which metal plating is to be formed and therefore enables formation of fine wires.

The following fully explains each of the steps.

(Step (A))

Examples of the core wiring substrate whose surface has a wire including a connection pad include, but is not particularly limited to, all types of wiring board such as a commercially available glass epoxy resin wiring substrate and a bismaleimide/triazine resin wiring substrate. Further, in cases where the core wiring substrate is also required to have fine wiring formability, a wiring substrate manufactured with use of a fiber-resin composite (a) of the present embodiment can be suitably applied.

On the aforementioned core wiring substrate, a B-staged fiber-resin composite (a) is integrally laminated by heat and pressure. The fiber-resin composite (a) only needs to be formed at the time of the lamination, and can be integrally laminated in various manners as described below.

According to one method, (i) a composite (a) of a fiber and a resin composition for forming a resin layer (b) on which metal plating is to be formed and (ii) a core wiring board are layered in this order, and then are integrally laminated.

According to another method, a resin layer (b) on which metal plating is to be formed, a fiber, and a core wiring substrate are layered in this order, and then are integrally laminated. Similarly, it is possible that a resin layer (b) on which metal plating is to be formed, a fiber, a resin layer (b) on which metal plating is to be formed, and a core wiring substrate are layered in this order, and then are integrally laminated.

According to still another method, a B-staged resin film (b) on which metal plating is to be formed, a fiber-resin composite, and a core wiring substrate are layered in this order, and then are integrally laminated. In order to improve the adhesiveness between the resin layer (b) on which metal plating is to be formed and the fiber-resin composite, another resin layer may be provided therebetween.

In cases where the fiber-resin composite is constituted by a resin containing a thermosetting component, it is necessary, in order to secure resin flow properties, that the fiber-resin composite be in a B stage.

In order that the surface roughness of a resin layer (b) on which metal plating is to be formed is less than 0.5 μm in terms of arithmetic mean roughness Ra as measured at a cutoff value of 0.002 mm, it is preferable that the surface roughness of a slip sheet that makes contact with the resin layer (b) on which metal plating is to be formed be also less than 0.5 μm in terms of arithmetic mean roughness Ra as measured at a cutoff value of 0.002 mm. Examples of such a slip sheet include a resin film that has not been subjected to a process such as embossing.

The lamination can be performed by various thermocompression bonding methods such as heat pressing, vacuum pressing, lamination (heat lamination), vacuum lamination, heat roller lamination, and vacuum heat roller lamination. Among these methods, processing under vacuum, i.e., vacuum pressing, vacuum lamination, or vacuum heat roller lamination is preferred because a space between circuits can be more satisfactorily filled without void. For the purpose of allowing the resin layer (b) on which metal plating is to be formed to be cured to be in a C stage, drying by heating can be performed with a hot-air oven or the like after the lamination has been completed.

The lamination conditions vary in properness depending on the resin layer (b) used on which metal plating is to be formed and the fiber-resin composite used. Therefore, it is preferable that the lamination conditions be appropriately optimized.

(Step (B))

The via hole can be formed by a publicly-known drill machine, dry plasma apparatus, carbon dioxide gas laser, UV laser, excimer laser, or the like. Further, for the purpose of removing smears having occurred after the formation of the via hole, it is preferable to perform a desmear process by a publicly-known technique such as a wet process in which permanganate is used or dry desmear (e.g., plasma).

(Step (C))

The metal plating layer can be formed by various types of dry plating such as vapor deposition, sputtering, and CVD, or by wet plating such as electroless plating. However, in consideration of productivity and adhesive properties with respect to the resin layer (b) on which metal plating is to be formed, it is preferable that the metal plating layer be a layer formed by electroless plating. Examples of the type of electroless plating include electroless copper plating, electroless nickel plating, electroless gold plating, electroless silver plating, and electroless tin plating. Any one of the types of electroless plating can be used for the present invention. However, from an industrial point of view and in terms of electrical characteristics such as migration resistance, electroless copper plating and electroless nickel plating are preferred, or electroless copper plating is preferred in particular. The metal plating layer is not particularly limited in terms of thickness. However, in consideration of fine wiring formability, it is preferable that the metal plating layer have a thickness of not more than 5 μm, or more preferably not more than 3 μm.

The foregoing has explained the steps (A) to (C). The following explains the subsequent steps.

(D) Performing Electrolytic Plating

The metal plating layer is formed by electrolytic plating so as to have a desired thickness. Examples of the electrolytic plating include a large number of publicly-known methods. Specific examples of such electrolytic plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(E) Forming a Plating Resist

The photosensitive plating resist can be made of a publicly-known material that is widely commercially available. According to a method of the present embodiment for manufacturing a multilayer printed wiring board, it is preferable that a photosensitive plating resist having a resolution pitch of not more than 50 μm be used so that finer wires can be formed. Note that a printed wiring board of the present embodiment may contain both a circuit having a wiring pitch of not more than 50 μm and a circuit having a wiring pitch of not less than 50 μm.

(F) Forming Wires by Etching

The etching can be performed by using a publicly-known etchant. Examples of such an etchant include a ferric chloride etchant, a cupric chloride etchant, a sulfuric acid/hydrogen peroxide etchant, an ammonium persulfate etchant, and a sodium persulfate etchant.

(G) Peeling Away the Resist

The resist can be peeled away by appropriately using a material suitable for peeling the plating resist thus used, and the material is not particularly limited. Examples of the material include an aqueous solution of sodium hydroxide and an aqueous solution of potassium hydroxide.

As described above, a multilayer printed wiring board can be obtained by forming wires by a so-called subtractive method, integrally laminating a fiber-resin composite (a), and then repeating the steps (B) to (G). Further, a heating step can be incorporated in any one of the steps for the purpose of sufficient curing, improvement of adhesive properties with respect to plated copper, and the like.

Meanwhile, after the steps (A) to (C) have been carried out, wires can be suitably formed by a semi-additive method that is better in terms of fine wiring formability. This is explained in the following.

(D′) Forming a Plating Resist

The photosensitive plating resist can be made of a publicly-known material that is widely commercially available. According to a method of the present embodiment for manufacturing a multilayer printed wiring board, it is preferable that a photosensitive plating resist having a resolution pitch of not more than 50 μm be used so that finer wires can be formed. Note that a printed wiring board of the present embodiment may contain both a circuit having a wiring pitch of not more than 50 μm and a circuit having a wiring pitch of not less than 50 μm.

(E′) Performing Electrolytic Plating

The metal plating layer is formed by electrolytic plating so as to have a desired thickness. Examples of the electrolytic plating include a large number of publicly-known methods. Specific examples of such electrolytic plating include electrolytic copper plating, electrolytic solder plating, electrolytic tin plating, electrolytic nickel plating, and electrolytic gold plating. However, from an industrial point of view and in terms of electrical characteristics such as migration resistance, electrolytic copper plating and electrolytic nickel plating are preferred, or electrolytic copper plating is preferred in particular.

(F′) Peeling Away the Resist

The resist can be peeled away by appropriately using a material suitable for peeling the plating resist thus used, and the material is not particularly limited. Examples of the material include an aqueous solution of sodium hydroxide and an aqueous solution of potassium hydroxide.

(G′) Forming Wires by Quick Etching

The etching can be performed by using a publicly-known etchant. Examples of such an etchant include a diluted ferric chloride etchant, a diluted cupric chloride etchant, a sulfuric acid/hydrogen peroxide etchant, an ammonium persulfate etchant, and a sodium persulfate etchant.

As described above, a multilayer printed wiring board can be obtained by forming wires by a so-called semi-additive method, integrally laminating a fiber-resin composite (a), and then repeating the steps (B) to (G′). Further, a heating step can be incorporated in any one of the steps for the purpose of sufficient curing, improvement of adhesive properties with respect to plated copper, and the like.

### Examples

The invention of the present embodiment will be described more in detail in accordance with Examples. However, the present invention is not limited to these. A person skilled in the art can make various changes, modifications, and alterations within the scope of the present invention. Note that such properties of laminates of Examples and Comparative Examples as adhesive properties with respect to electroless plated copper, surface roughness Ra, and wiring formability were evaluated or calculated in the following manner.

[Measurement of Surface Roughness Ra]

The surface roughness of an exposed resin surface of the multilayer printed wiring board thus obtained was measured. The measurement was carried out in accordance with a method described in “Examples of Embodiment 1”.

[Wiring Formability]

The wiring formability of the multilayer printed wiring board thus obtained was evaluated. The evaluation was carried out in accordance with a method described in “Examples of Embodiment 1”.

### Example of how a Polyimide Resin is Synthesized 9

37 g (0.045 mol) of KF-8010 manufactured by Shin-Etsu Chemical Co., Ltd., 21 g (0.105 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 10 was obtained.

### Example of how a Polyimide Resin is Synthesized 10

92 g (0.075 mol) of Elasmer-1000P (manufactured by Ihara Chemical Industry, Co., Ltd.), 15 g (0.075 mol) of 4,4′-diaminodiphenylether, and N,N-dimethylformamide (hereinafter referred to as “DMF”) were poured into a glass flask having a capacity of 2000 ml, and then were stirred for dissolution. Then, 78 g (0.15 mol) of 4,4-(4,4′-isopropylidendiphenoxy)bis(phthalic anhydride) was added, and the resulting mixture was stirred for approximately one hour. As a result, a DMF solution of polyamic acid was obtained with a solid content concentration of 30%. The polyamic acid solution was collected in a butt coated with Teflon®, and then was heated under a reduced pressure of 665 Pa at 200° C. for 120 minutes with a vacuum oven. As a result, Polyimide Resin 11 was obtained.

### Example 27

Polyimide Resin 10 was dissolved in dioxolan, with the result that Solution (A5) for forming a resin layer (b) on which metal plating is to be formed was obtained with a solid content concentration of 5 wt %. Resin Solution (A5) was applied onto a resin film (T-1(s); having a thickness of 38 μm; manufactured by Panac Co., Ltd.) by a casting method, and then the resin film was dried at 60° C. As a result, a 2-μm-thick film-like resin layer (b) on which metal plating is to be formed was obtained with a resin film attached thereto.

The film-like resin layer (b), having a resin film attached thereto, on which metal plating is to be formed, a prepreg (ES-3306S; manufactured by Risho Kogyo Co., Ltd.) having a thickness of 50 μm, a core substrate (Product Number: MCL-E-67; manufactured by Hitachi Chemical Co., Ltd.; copper foil thickness: 18 μm) on which wires had been formed, a prepreg having a thickness of 50 μm, and a film-like resin layer (b) on which metal plating is to be formed were layered in this order, and then were integrally laminated at 170° C. under 4 MPa for 2 hours. Note that the prepregs and the resin layers (b) on which metal plating is to be formed were layered so as to make contact with each other.

Thereafter, the resin film is peeled away from the resin layer (b) on which metal plating is to be formed, and then a via hole was formed with a carbon dioxide gas laser in that part of the core substrate which corresponds to a connection pad.

Furthermore, desmear and electroless copper plating were performed under conditions shown in Tables 1 and 2.

A resist pattern was formed on the electroless plated copper layer, and then electrolytic copper pattern plating was performed so that pattern copper had a thickness of 8 μm. Thereafter, the resist pattern was peeled away, and then the exposed electroless plated copper was removed by a sulfuric acid/hydrogen peroxide etchant. As a result, a multilayer printed wiring board having wires with a line-and-space (L/S) of 10 μm/10 μm was obtained.

The wiring board thus obtained was evaluated in accordance with procedures for evaluating various evaluation items. The evaluation results are shown in Table 11.

### Example 28

Polyimide Resin 10 was dissolved in dioxolan, with the result that Solution (B5) for forming a resin layer (b) on which metal plating is to be formed was obtained with a solid content concentration of 30 wt %. Resin Solution (B5) was applied onto a resin film (T-1(s); having a thickness of 38 μm; manufactured by Panac Co., Ltd.) by a casting method, and then the resin film was dried at 60° C. As a result, a 35 μm-thick film-like resin layer (b) on which metal plating is to be formed was obtained with a resin film attached thereto.

A film-like resin layer (b), having a resin film attached thereto, on which metal plating is to be formed; glass unwoven fabric having a thickness of 40 μm; a film-like resin layer (b), having a resin film attached thereto, on which metal plating is to be formed; a core substrate (Product Number: MCL-E-67; manufactured by Hitachi Chemical Co., Ltd.; copper foil thickness: 18 μm) on which wires had been formed; a film-like resin layer (b), having a resin film attached thereto, on which metal plating is to be formed; glass unwoven fabric having a thickness of 40 μm; and a film-like resin layer (b), having a resin film attached thereto, on which metal plating is to be formed were layered in this order, and then were integrally laminated at 170° C. under 4 MPa for 2 hours. Then, a multilayer printed wiring board was manufactured in the same manner as in Example 27.

The wiring board thus obtained was evaluated in accordance with procedures for evaluating various evaluation items. The evaluation results are shown in Table 3.

### Example 29

Polyimide Resin 10 was dissolved in dioxolan, with the result that Solution (B5) for forming a resin layer (b) on which metal plating is to be formed was obtained with a solid content concentration of 30 wt %. Glass unwoven fabric having a thickness of 40 μm was impregnated with Solution (B5), and then was dried at 100° C. As a result, a fiber-resin composite was obtained.

A resin film (T-1(s); having a thickness of 38 μm; manufactured by Panac Co., Ltd.), a fiber-resin composite, a core substrate (Product Number: MCL-E-67; manufactured by Hitachi Chemical Co., Ltd.; copper foil thickness: 18 μm) on which wires had been formed, a fiber-resin composite, and a resin film (T-1(s); having a thickness of 38 μm; manufactured by Panac Co., Ltd.) were layered in this order, and then were integrally laminated at 180° C. under 4 MPa for one hour. Thereafter, a multilayer printed wiring board was manufactured in the same manner as in Example 27.

The wiring board thus obtained was evaluated in accordance with procedures for evaluating various evaluation items. The evaluation results are shown in Table 11.

### Example 30

Polyimide Resin 11 was dissolved in dioxolan, with the result that Solution (C5) for forming a resin layer (b) on which metal plating is to be formed was obtained with a solid content concentration of 5 wt %. A multilayer printed wiring board was manufactured in the same manner as in Example 27 except that Solution (C5) was used.

The wiring board thus obtained was evaluated in accordance with procedures for evaluating various evaluation items. The evaluation results are shown in Table 11.

### Comparative Example 8

Electrolytic copper foil having a thickness of 18 μm, a prepreg (ES-3306S; manufactured by Risho Kogyo Co., Ltd.) having a thickness of 50 μm, a core substrate (Product Number: MCL-E-67; manufactured by Hitachi Chemical Co., Ltd.; copper foil thickness: 18 μm) on which wires had been formed, a prepreg having a thickness of 50 μm, and electrolytic copper foil having a thickness of 18 μm were layered in this order, and then were integrally laminated at 170° C. under 4 MPa for 2 hours.

Thereafter, the copper was etched so as to have a thickness of 2 μm, and a via hole was formed with a carbon dioxide gas laser in that part of the core substrate which corresponds to a connection pad.

Furthermore, desmear and electroless copper plating were performed under the same conditions as in Example 27.

A resist pattern was formed on the electroless plated copper layer, and then electrolytic copper pattern plating was performed so that pattern copper had a thickness of 10 μm. Thereafter, the resist pattern was peeled away, and then the exposed electroless plated copper was removed with a ferric chloride etchant. As a result, a multilayer printed wiring board having wires with a line-and-space (L/S) of 10 μm/10 μm was obtained.

The wiring board thus obtained was evaluated in accordance with procedures for evaluating various evaluation items. The evaluation results are shown in Table 4. As evidenced by Table 12, the copper layer formed by laminating the electrolytic copper foil causes great irregularities to be formed on a surface of the resin layer. Therefore, sufficient etching needs to be performed, which causes wires to thin or collapse. This makes it impossible to satisfactorily form fine wires.

TABLE 11

| | Example | Example | Example | Example |
|---|---|---|---|---|
| | 27 | 28 | 29 | 30 |
| Adhesive strength under | 10 N/cm | 13 N/cm | 12 N/cm | 8 N/cm |
| normal conditions | | | | |
| Adhesive strength | 7 N/cm | 9 N/cm | 7 N/cm | 4 N/cm |
| after PCT | | | | |
| Surface roughness Ra | 0.02 μm | 0.01 μm | 0.02 μm | 0.01 μm |
| Fine wiring formability | ∘* | ∘* | ∘* | ∘* |
| L/S = 10 μm/10 μm | | | | |

*The symbol “∘” means that a printed wiring board having wires with a line-and-space (L/S) of 10 μm/10 μm was formed satisfactorily.

TABLE 12

| | Comparative |
|---|---|
| | Example 8 |
| Adhesive strength under normal conditions | 14 N/cm |
| Adhesive strength after PCT | 9 N/cm |
| Surface roughness Ra | 0.89 μm |
| Fine wiring formability | x* |
| L/S = 10 μm/10 μm | |

*The symbol “x” means that a printed wiring board having wires with a line-and-space (L/S) of 10 μm/10 μm was formed with a small wiring width and some peeling wires.

The present invention is not limited to the description of the embodiments above, but may be altered by a skilled person within the scope of the claims. An embodiment based on a proper combination of technical means disclosed in different embodiments and examples is encompassed in the technical scope of the present invention.

### INDUSTRIAL APPLICABILITY

A copper-clad laminate according to the present invention is such that a resin layer having good adhesive properties with respect to copper foil and a plated copper layer are laminated so as to make contact with each other; therefore, electroless plated copper is formed firmly even on a flat and smooth surface. For this reason, the copper-clad laminated according to the present invention can be used especially for a printed wiring board on which fine wires need to be formed and the like.

Further, a laminate according to the present invention is such that electroless plated copper is formed firmly even on a flat and smooth surface, and therefore can be used especially for a printed wiring board on which fine wires need to be formed.

Further, an electroless plating material according to the present invention is such that electroless plated copper is formed firmly even on a flat and smooth surface, and therefore can be used especially for a printed wiring board on which fine wires need to be formed.

Further, a fiber-resin composite according to the present invention is such that electroless plated copper is formed firmly even on a flat and smooth surface, and makes it possible to obtain a fiber-resin composite with high thickness accuracy. Therefore, the fiber-resin composite according to the present invention can be used especially for a printed wiring board on which fine wires need to be formed.

Further, a method according to the present invention for manufacturing a multilayer printed wiring board makes it unnecessary to carry out a step of etching copper foil and makes it possible to manufacture a multilayer printed wiring board on which highly fine wires can be formed, and therefore can be preferably used especially for manufacturing a multilayer printed wiring board on which fine wires need to be formed.

Therefore, the present invention can be suitably used in the industrial field of various electronic parts.

1. A laminate comprising a resin layer (b), provided on at least one surface of a fiber-resin composite (a), on which a metal plating layer is to be formed.

2. The laminate as set forth in claim 1, comprising a resin layer (c) provided between the fiber-resin composite (a) and the resin layer (b) on which a metal plating layer is to be formed.

3. The laminate as set forth in claim 1, wherein the fiber-resin composite (a) is in a B stage.

4. The laminate as set forth in claim 1, wherein the fiber-resin composite (a) is in a C stage.

5. The laminate as set forth in claim 1, wherein the resin layer (b) on which a metal plating layer is to be formed contains a polyimide resin having one or more structures represented by any one of general formulae (1) to (6): 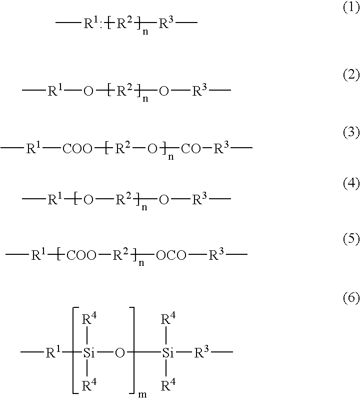
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

6. The laminate as set forth in claim 1, wherein the resin layer (b) on which a metal plating layer is to be formed contains a polyimide resin having a siloxane structure.

7. The laminate as set forth in claim 1, wherein the resin layer (b) on which a metal plating layer is to be formed contains a polyimide resin that is obtained by a reaction between an acid dianhydride component and a diamine component containing a diamine represented by general formula (7): 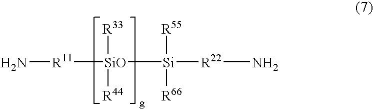
where g is an integer of not less than 1; R¹¹ and R²² are each independently an alkylene group or a phenylene group; and R³³ to R⁶⁶ are each independently an alkyl group, a phenyl group, or a phenoxy group.

8. The laminate as set forth in claim 1, wherein the resin layer (b) has a metal plating layer formed thereon.

9. The laminate as set forth in claim 8, wherein the metal plating layer is a plated copper layer.

10. The laminate as set forth in claim 9, wherein the plated copper layer contains an electroless plated copper layer.

11. The laminate as set forth in claim 1, wherein the surface roughness of the resin layer (b) on which a metal plating layer is to be formed is less than 0.5 μm in terms of arithmetic mean roughness Ra as measured at a cutoff value of 0.002 mm.

12. The laminate as set forth in claim 1, wherein the fiber-resin composite (a) is formed from at least one type of resin selected from the group consisting of an epoxy resin, a thermosetting polyimide resin, a cyanate ester resin, a hydrosilyl cured resin, a bismaleimide resin, a bisallylnadiimide resin, an acrylic resin, a methacrylic resin, an allyl resin, an unsaturated polyester resin, a polysulfone resin, a polyether sulfone resin, a thermoplastic polyimide resin, a polyphenylene ether resin, a polyolefin resin, a polycarbonate resin, and a polyester resin.

13. A printed wiring board obtained with use of a laminate as set forth in claim 1.

14. An electroless plating material having a surface that is subjected to electroless plating, comprising a resin composition that contains a composite of a fiber and a polyimide resin having one or more structures represented by any one of general formulae (1) to (6): 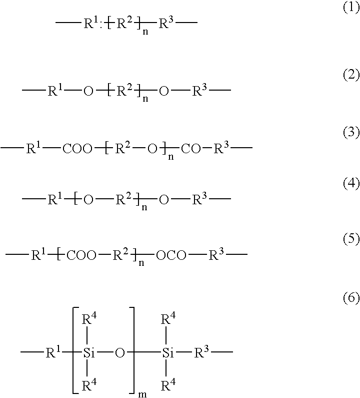
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100, and m is an integer of not less than 1.

15. An electroless plating material having a surface that is subjected to electroless plating, comprising a resin composition that contains a composite of a fiber and a polyimide resin having a siloxane structure.

16. The electroless plating material as set forth in claim 15, wherein the polyimide resin having a siloxane structure is made from an acid dianhydride component and a diamine component containing a diamine represented by general formula (7) 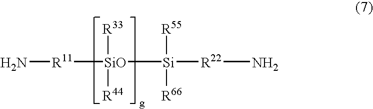
where g is an integer of not less than 1; R¹¹ and R²² are each independently an alkylene group or a phenylene group; and R³³ to R⁶⁶ are each independently an alkyl group, a phenyl group, or a phenoxy group.

17. The electroless plating material as set forth in claim 14, wherein the fiber is made from at least one type selected from the group consisting of paper, glass, polyimide, aramid, polyarylate, and tetrafluoroethylene.

18. The electroless plating material as set forth in claim 14, wherein the electroless plating is electroless copper plating.

19. The electroless plating material as set forth in claim 15, wherein the composite is obtained by impregnating the fiber with a resin composition solution containing (i) the polyimide resin having a siloxane structure and (ii) a solvent.

20. The electroless plating material as set forth in claim 15, wherein the composite is obtained by impregnating the fiber with a resin composition solution containing (i) polyamic acid having a siloxane structure and (ii) a solvent.

21. A laminate obtained by subjecting a surface of an electroless plating material as set forth in claim 14 directly to electroless plating.

22. A printed wiring board obtained with use of an electroless plating material as set forth in claim 14.

23. A method for manufacturing an electroless plating material, comprising forming, by impregnating a fiber with a resin composition solution containing (i) a polyimide resin having a siloxane structure and (ii) a solvent, a layer whose surface is to be subjected to electroless plating.

24. A method for manufacturing an electroless plating material, comprising forming, by impregnating a fiber with a resin composition solution containing (i) a polyimide resin having one or more structures represented by any one of general formulae (1) to (6) and (ii) a solvent, a layer whose surface is to be subjected to electroless plating: 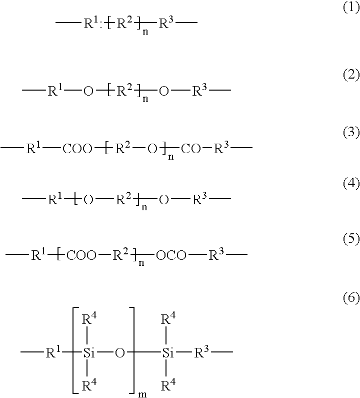
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

25. A fiber-resin composite obtained by integrating (i) a sheet having a layer formed from a resin composition containing a thermoplastic resin with (ii) a fiber by thermocompression bonding.

26. The fiber-resin composite as set forth in claim 25, wherein the sheet formed from a resin composition containing a thermoplastic resin is a single-layer sheet containing a polyimide resin having one or more structures represented by any one of general formulae (1) to (6): 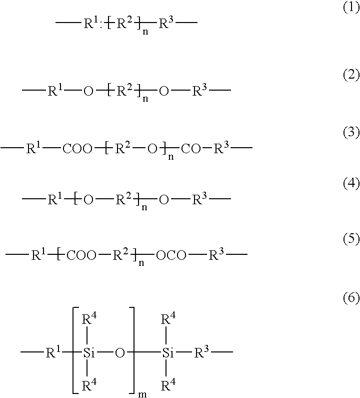
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

27. The fiber-resin composite as set forth in claim 25, wherein the sheet formed from a resin composition containing a thermoplastic resin is a single-layer sheet containing a polyimide resin having a siloxane structure.

28. The fiber-resin composite as set forth in claim 25, wherein the sheet formed from a resin composition containing a thermoplastic resin is a plural-layer sheet having two or more different resin layers and has a layer containing a polyimide resin having one or more structures represented by any one of general formulae (1) to (6): 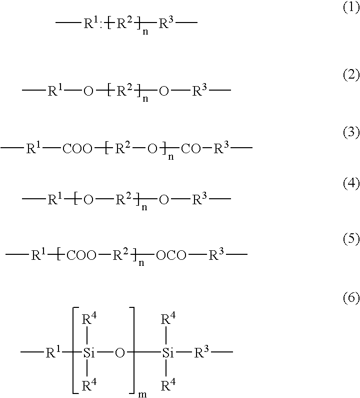
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

29. The fiber-resin composite as set forth in claim 25, wherein the sheet formed from a resin composition containing a thermoplastic resin is a plural-layer sheet having two or more different resin layers and has a layer containing a polyimide layer having a siloxane structure.

30. The fiber-resin composite as set forth in claim 28, wherein the sheet formed from a resin composition containing a thermoplastic resin has (i) a layer containing a polyimide resin having one or more structures represented by any one of general formulae (1) to (6) and (ii) a resin layer containing a thermosetting component.

31. A fiber-resin composite obtained by placing a fiber between sheets each having a layer formed from a resin composition containing a thermoplastic resin and then by integrating the sheets with the fiber by thermocompression bonding.

32. A fiber-resin composite obtained by placing a fiber between resin sheets each having a surface on which a metal plating layer is to be formed and then by integrating the resin sheets with the fiber by thermocompression bonding.

33. A fiber-resin composite obtained by placing a fiber between a resin sheet having a surface on which a metal plating layer is to be formed and a resin sheet in which a circuit is to be embedded and then by integrating the resin sheets with the fiber by thermocompression bonding.

34. The fiber-resin composite as set forth in claim 25, having an uppermost surface where there exists a polyimide resin having one or more structures represented by general any one of formulae (1) to (6): 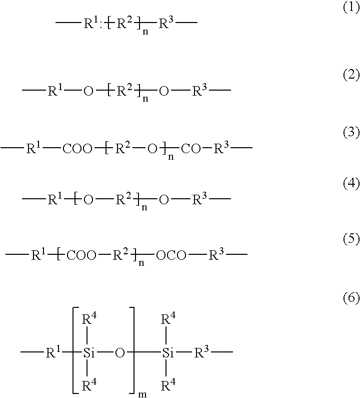
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

35. The fiber-resin composite as set forth in claim 25, wherein the thermocompression bonding is performed at a temperature of 70° C. to 300° C. under a pressure of 0.1 MPa to 10 MPa for a period of 1 second to 3 hours with at least one type of apparatus selected from the group consisting of a heat press, a vacuum press, a laminator, a vacuum laminator, a heat roller laminator, and a vacuum heat roller laminator.

36. The fiber-resin composite as set forth in claim 25, having an uppermost surface that is to be subjected to electroless plating.

37. A laminate obtained by subjecting, to electroless plating, an uppermost surface of a fiber-resin composite as set forth in claim 25.

38. A printed wiring board obtained with use of a fiber-resin composite as set forth in claim 25.

39. A method for manufacturing a fiber-resin composite, comprising obtaining the fiber-resin composite by integrating (i) a sheet having a layer formed from a resin composition containing a thermoplastic resin with (ii) a fiber by thermocompression bonding.

40. A method for manufacturing a multilayer printed wiring board with use of a fiber-resin composite (a), comprising the steps (A) to (C) of:
(A) integrally laminating a laminate on a core wiring substrate by heat and pressure, the core wiring substrate having a surface that has a wire including a connection pad, the laminate having a resin layer (b), provided on at least one surface of a fiber-resin composite (a), on which metal plating is to be formed;
(B) exposing the connection pad by making via holes in respective parts of the fiber-resin composite (a) and the resin layer (b) on which metal plating is to be formed, the parts corresponding to the connection pad; and
(C) making an electrical connection between (i) a surface of the resin layer (b) on which metal plating is to be formed and (ii) the connection pad by forming metal plating on the surface of the resin layer (b) on which metal plating is to be formed and in the via holes.

41. A method for manufacturing a multilayer printed wiring board with use of a fiber-resin composite (a), comprising the steps (A) to (C) of:
(A) integrally laminating a fiber-resin composite (a) and a resin layer (b) on which metal plating is to be formed on a core wiring substrate by heat and pressure so that the resin layer (b) serves as an outermost layer, the core wiring substrate having a surface that has a wire including a connection pad;
(B) exposing the connection pad by making via holes in respective parts of the fiber-resin composite (a) and the resin layer (b) on which metal plating is to be formed, the parts corresponding to the connection pad; and
(C) making an electrical connection between a surface of the resin layer (b) on which metal plating is to be formed and the connection pad by forming metal plating on the surface of the resin layer (b) on which metal plating is to be formed and in the via holes.

42. The method as set forth in claim 40, wherein the resin layer (b) contains a polyimide resin having one or more structures represented by any one of general formulae (1) to (6): 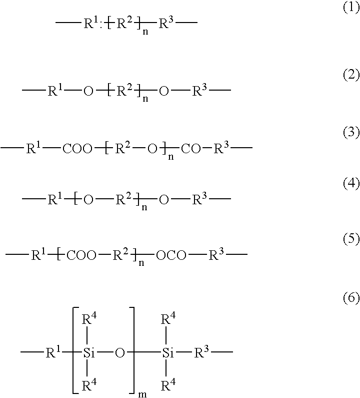
where R¹ and R³ are a bivalent alkylene group represented by C_{X}H_{2X} or a bivalent aromatic group; R⁴ is an alkyl group, a phenyl group, alkoxy group, or a phenoxy group; R² is a bivalent alkylene group represented by C_{X}H_{2X} or a bivalent phenylene group; n is an integer of 3 to 100; and m is an integer of not less than 1.

43. The method as set forth in claim 40, comprising forming a wire by a subtractive method after the steps (A) to (C).

44. The method as set forth in claim 40, comprising forming a wire by an additive method after the steps (A) to (C).

45. A multilayer printed wiring board manufactured by a method as set forth in claim 40, the surface roughness of a resin layer exposed after the wire has been formed being less than 0.5 μm in terms of arithmetic mean roughness Ra as measured at a cutoff value of 0.002 mm.
